(19) United States
(12) Patent Application Publication
(10) Pub. No.: US 2025/0231482 A1
(43) Pub. Date: Jul. 17, 2025

(54) POSITIVE RESIST MATERIAL AND PATTERNING PROCESS

(71) Applicant: SHIN-ETSU CHEMICAL CO., LTD., Tokyo (JP)

(72) Inventors: Yutaro OTOMO, Joetsu-shi (JP); Jun HATAKEYAMA, Joetsu-shi (JP)

(73) Assignee: SHIN-ETSU CHEMICAL CO., LTD., Tokyo (JP)

(21) Appl. No.: 19/018,095

(22) Filed: Jan. 13, 2025

(30) Foreign Application Priority Data
Jan. 17, 2024 (JP) 2024-005628

(51) Int. Cl. G03F 7/039; C08F 220/18; C08F 220/22; G03F 7/00

(52) U.S. Cl. CPC G03F 7/0392; C08F 220/1806; C08F 220/1807; C08F 220/22; G03F 7/70033; C08F 2800/10

(57) ABSTRACT

The present invention is a positive resist material includes a base polymer with a sulfonium salt or an iodonium salt of carboxylic acid as a pendant group attached to a polymer backbone, wherein the base polymer contains a repeating unit (a) containing one or more iodine atoms between the polymer backbone and carboxylate, the repeating unit (a) containing one or both of a repeating unit represented by the following general formula (a)-1 and a repeating unit represented by the following general formula (a)-2. This provides: a positive resist material that enables high sensitivity superior to conventional positive resist materials, less dimensional variation, and a favorable pattern profile after exposure; a positive resist composition containing the material and a patterning process using the composition; and a polymer compound that yields the positive resist material are to be provided.

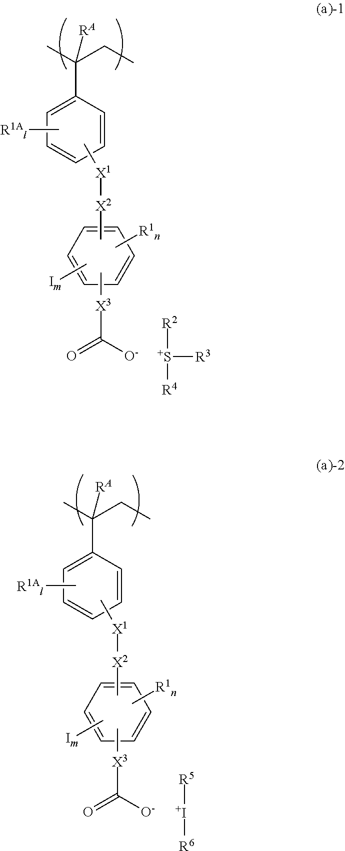

### TECHNICAL FIELD

The present invention relates to a positive resist material and a patterning process.

### BACKGROUND ART

As higher integration and speed are achieved in LSI, miniaturization of a pattern rule progresses rapidly. This is because 5G high-speed communication and artificial intelligence (AI) become more widespread, and high-performance devices are needed for their processing. As the state-of-the-art miniaturization technology, 5-nm node devices are produced in large quantities using extreme ultraviolet (EUV) lithography with a wavelength of 13.5 nm. Furthermore, there are also ongoing studies on next generation 3-nm node and next-next generation 2-nm node devices using EUV lithography.

Along with the progressing miniaturization, image blurs due to acid diffusion become a problem. To ensure resolution for finer patterns than 45 nm size dimension, it has been proposed that not only improvement in dissolution contrast as conventionally proposed, but also control of acid diffusion are important (Non-Patent Document 1). However, sensitivity and contrast are enhanced by acid diffusion in chemically amplified resist materials. Accordingly, when temperature and time of post exposure bake (PEB) are decreased to suppress the acid diffusion as much as possible, the sensitivity and the contrast are significantly reduced.

A trade-off triangle relationship among sensitivity, resolution, and edge roughness has been pointed out. It is necessary to suppress acid diffusion to enhance the resolution, but a short acid diffusion distance leads to the reduced sensitivity.

It is effective to add an acid generator capable of generating bulky acid to suppress acid diffusion. Hence, it has been proposed to incorporate a repeating unit derived from an onium salt having a polymerizable unsaturated bond in a polymer. In this case, the polymer also functions as an acid generator (polymer-bound acid generator). Patent Document 1 has proposed a sulfonium salt or an iodonium salt having a polymerizable unsaturated bond, capable of generating a specific sulfonic acid. Patent Document 2 has proposed a sulfonium salt having a sulfonic acid directly attached to a backbone.

To suppress acid diffusion, a resist material containing a polymer-bound quencher has been proposed, that uses, as a base polymer, a sulfonium salt of weak acid having a pKa value of −0.8 or more and containing a polymerizable group (Patent Documents 3 to 5). Exemplary weak acids in Patent Document 3 include carboxylic acids, sulfonamides, phenols, hexafluoroalcohols, and the like.

### CITATION LIST

### Patent Literature

Patent Document 1: JP 2006-045311 A
Patent Document 2: JP 2006-178317 A
Patent Document 3: WO 2019/167737 A1
Patent Document 4: WO 2022/264845 A1
Patent Document 5: JP 2022-115072 A

### Non Patent Literature

Non Patent Document 1: SPIE Vol. 6520 65203L-1 (2007)

### SUMMARY OF INVENTION

### Technical Problem

In view of the above circumstances, the present invention aims to provide: a positive resist material that enables high sensitivity superior to conventional positive resist materials, less dimensional variation, and a favorable pattern profile after exposure; a positive resist composition containing the resist material and a patterning process using the composition; and a polymer compound that yields the positive resist material.

### Solution to Problem

To achieve the object, the present invention provides a positive resist material including a base polymer with a sulfonium salt or an iodonium salt of carboxylic acid as a pendant group attached to a polymer backbone, wherein the base polymer includes a repeating unit (a) containing one or more iodine atoms between the polymer backbone and carboxylate, the repeating unit (a) containing one or both of a repeating unit represented by the following general formula (a)-1 and a repeating unit represented by the following general formula (a)-2,

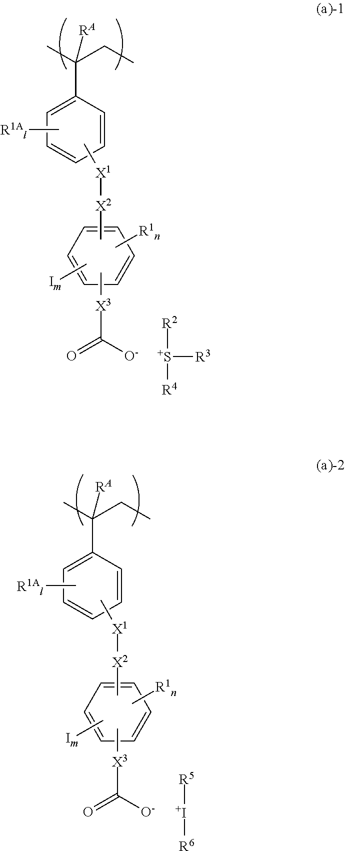

wherein R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{1A} each independently represents a halogen atom, a hydroxy group, or a linear or branched alkoxy group or acyloxy group each having 1 to 6 carbon atoms; “l” represents an integer of 0 to 3; “m” represents an integer of 0 to 4; “n” represents an integer of 0 to 4, provided that an anion moiety of the pendant group contains one or more iodine atoms; and R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto.

The positive resist material including such base polymer enables high sensitivity superior to conventional resist materials, less dimensional variation, and a favorable pattern profile after exposure.

Additionally, in the present invention, it is preferable to further contain at least one selected from repeating units represented by the following formulae (b1) to (b4),

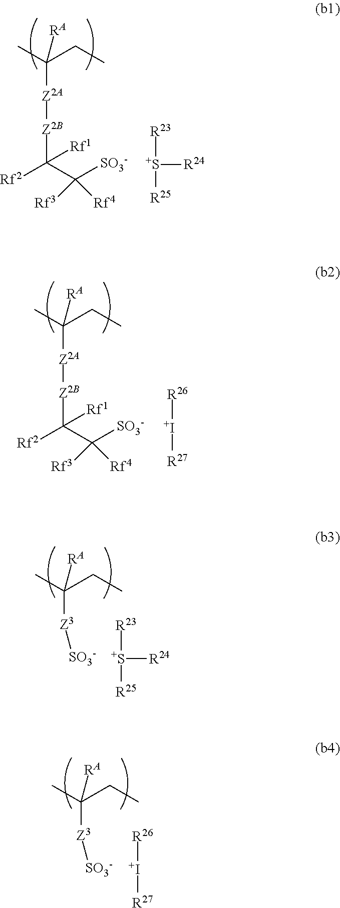

wherein R^{A} each independently represents a hydrogen atom or a methyl group; Z^{2A} represents a single bond or an ester bond; Z^{2B} represents a single bond or a divalent group having 1 to 12 carbon atoms, optionally containing an ester bond, an ether bond, a lactone ring, a bromine atom, or an iodine atom; Z³ represents a single bond, a methylene group, an ethylene group, a phenylene group, a fluorinated phenylene group, —O—Z³¹—, —C(═O)—O—Z³¹—, or —C(═O)—NH—Z³¹—, wherein Z³¹ represents an alkanediyl group having 1 to 6 carbon atoms, an alkenediyl group having 2 to 6 carbon atoms, or a phenylene group, optionally containing a carbonyl group, an ester bond, an ether bond, a halogen atom, or a hydroxy group; each of Rf¹ to Rf⁴ independently represents a hydrogen atom, a fluorine atom, or a trifluoromethyl group, provided that at least one of Rf¹ to Rf⁴ represents a fluorine atom; and each of R²³ to R²⁷ independently represents a monovalent hydrocarbon group having 1 to 20 carbon atoms and optionally having a heteroatom, and optionally any two of R²³, R²⁴, and R²⁵ bond together to form a ring with a sulfur atom attached thereto.

According to the present invention, the above repeating units (b1) to (b4) have a function as an acid generator. Therefore, attachment of the acid generator to the polymer backbone can reduce acid diffusion and prevent decrease in resolution resulting from blurs due to the acid diffusion, and homogenous distribution of the acid generator can improve LWR. Furthermore, by using the base polymer containing the above repeating units, blending of an addition-type acid generator can be omitted.

In this case, the Z^{2B} preferably contains one or more iodine atoms.

When an anion moiety of the acid generator attached to the polymer backbone contains an iodine atom, the increased number of photons to be absorbed enhances contrast in acid generation, thereby further improving edge roughness. The above effects can be exerted by using the base polymer having, in the polymer backbone, the repeating unit (b1) and/or (b2) containing one or more iodine atoms in the Z^{2B}, thereby allowing more enhanced sensitivity and more improved LWR and CDU.

Additionally, in the present invention, it is preferable to further contain a repeating unit (c) in which a hydrogen atom of one or both of a carboxy group and a phenolic hydroxy group is substituted with an acid labile group.

Such positive resist material enables higher sensitivity and less dimensional variation.

In this case, the repeating unit (c) is preferably at least one selected from a repeating unit (c1) represented by the following formula (c1) and a repeating unit (c2) represented by the following formula (c2),

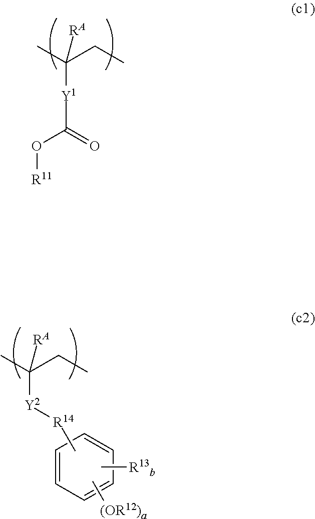

wherein R^{A} each independently represents a hydrogen atom or a methyl group; Y¹ represents a single bond, a phenylene group, a naphthylene group, or a linking group having 1 to 12 carbon atoms and having an ester bond, an ether bond, or a lactone ring; Y² represents a single bond, an ester bond, or an amide bond; R¹¹ and R¹² represent an acid labile group; R¹³ represents a fluorine atom, a trifluoromethyl group, a cyano group, or an alkyl group having 1 to 6 carbon atoms; R¹⁴ represents a single bond, or a linear or branched alkanediyl group having 1 to 6 carbon atoms, in which some of carbon atoms thereof are optionally substituted with an ether bond or an ester bond; “a” represents 1 or 2; and “b” represents an integer of 0 to 4.

Such positive resist material enables more increased dissolution contrast and less dimensional variation.

Additionally, in the present invention, the base polymer preferably further contains a repeating unit (d) containing an adhesive group selected from a hydroxy group, a carboxy group, a lactone ring, a carbonate group, a thiocarbonate group, a carbonyl group, a cyclic acetal group, an ether bond, an ester bond, a sulfonic acid ester bond, a cyano group, an amide group, —O—C(═O)—S—, and —O—C(═O)—NH—.

Such positive resist material will be excellent in adhesion to a substrate.

Additionally, in the present invention, the base polymer preferably has a weight average molecular weight in a range of 1000 to 100000.

Such positive resist material enables excellent heat resistance, maintained alkali solubility, and no occurrence of a footing phenomenon after patterning.

The present invention further provides a positive resist composition containing the above positive resist material.

Such positive resist composition enables high sensitivity superior to conventional ones, less dimensional variation, and a favorable pattern profile after exposure.

Additionally, in the present invention, it is preferable to further contain one or more selected from an acid generator, an organic solvent, a quencher, and a surfactant.

These can be added to the positive resist composition of the present invention.

The present invention further provides a patterning process including steps of: forming a resist film on a substrate using the above positive resist composition; exposing the resist film to a high-energy beam; and developing the exposed resist film using a developer.

Such patterning process can form a pattern having a favorable pattern profile.

In this case, it is preferable to use a beam at i-line, a KrF excimer laser beam, an ArF excimer laser beam, an electron beam, or extreme ultraviolet having a wavelength of 3 to 15 nm as the high-energy beam.

These high-energy beams can be used for the patterning process of the present invention.

The present invention further provides a polymer compound having a weight average molecular weight in a range of 1000 to 100000, including a copolymer containing one or both of a repeating unit represented by the following general formula (a)-1 and a repeating unit represented by the following general formula (a)-2, and one or more repeating units selected from the following general formulae (b1) to (b4),

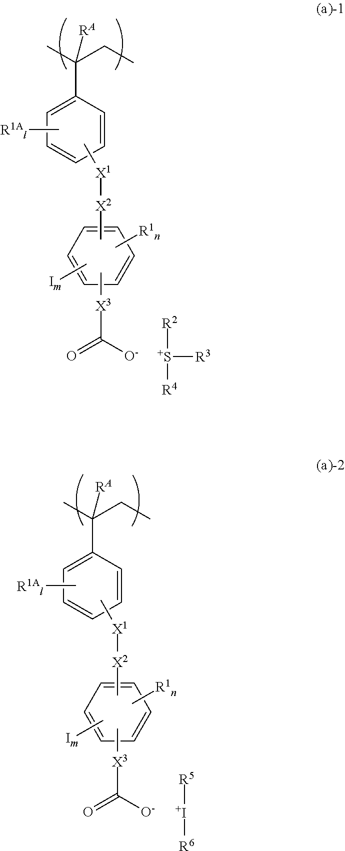

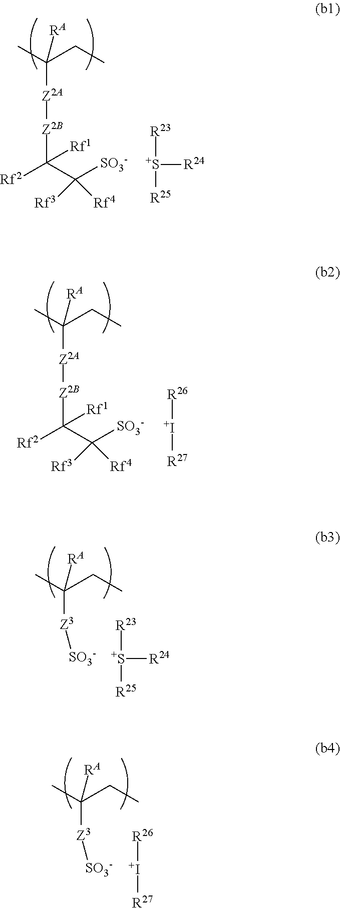

wherein R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{2A} each independently represents a halogen atom, a hydroxy group, or a linear or branched alkoxy group or acyloxy group each having 1 to 6 carbon atoms; “l” represents an integer of 0 to 3; “m” represents an integer of 0 to 4; “n” represents an integer of 0 to 4, provided that an anion moiety of the pendant group contains one or more iodine atoms; R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto; Z^{2A} represents a single bond or an ester bond; Z^{2B} represents a single bond or a divalent group having 1 to 12 carbon atoms, optionally containing an ester bond, an ether bond, a lactone ring, a bromine atom, or an iodine atom; Z³ represents a single bond, a methylene group, an ethylene group, a phenylene group, a fluorinated phenylene group, —O—Z³¹—, —C(═O)—O—Z³¹—, or —C(═O)—NH—Z³¹—, wherein Z³¹ represents an alkanediyl group having 1 to 6 carbon atoms, an alkenediyl group having 2 to 6 carbon atoms, or a phenylene group, optionally containing a carbonyl group, an ester bond, an ether bond, a halogen atom, or a hydroxy group; each of Rf¹ to Rf⁴ independently represents a hydrogen atom, a fluorine atom, or a trifluoromethyl group, provided that at least one of Rf¹ to Rf⁴ represents a fluorine atom; and each of R²³ to R²⁷ independently represents a monovalent hydrocarbon group having 1 to 20 carbon atoms and optionally having a heteroatom, and optionally any two of R²³, R²⁴, and R²⁵ bond together to form a ring with a sulfur atom attached thereto.

Such polymer compound is useful as a base polymer that yields a positive resist material having sensitivity superior to conventional positive resist materials, less dimensional variation, and a favorable pattern profile after exposure.

### Advantageous Effects of Invention

As described above, the positive resist material, the positive resist composition, and the patterning process using the composition according to the present invention can provide: a resist material that enables high sensitivity and high resolution superior to conventional positive resist materials, less edge roughness and dimensional variation, and a favorable pattern profile after exposure; a resist composition using the resist material; and a patterning process.

### DESCRIPTION OF EMBODIMENTS

As described above, it has been demanded to develop a resist material that enables high sensitivity and resolution superior to conventional positive resist materials, less edge roughness and dimensional variation, and a favorable pattern profile after exposure; a resist composition using the resist material; and a patterning process.

As a result of an intensive investigation to obtain a positive resist material with high resolution as well as less edge roughness (LWR) and dimensional variation (CDU), as recently demanded, the present inventor has found that a minimized acid diffusion distance and a uniform acid concentration in a resist film of an exposed area are necessary, and it is effective for these purposes to use, as a base polymer, a polymer containing a repeating unit of a sulfonium salt or an iodonium salt of carboxylic acid containing an iodine atom, and has completed the present invention.

Thus, the present invention is a positive resist material including a base polymer with a sulfonium salt or an iodonium salt of carboxylic acid as a pendant group attached to a polymer backbone, wherein the base polymer contains a repeating unit (a) containing one or more iodine atoms between the polymer backbone and carboxylate, the repeating unit (a) containing one or both of a repeating unit represented by the following general formula (a)-1 and a repeating unit represented by the following general formula (a)-2,

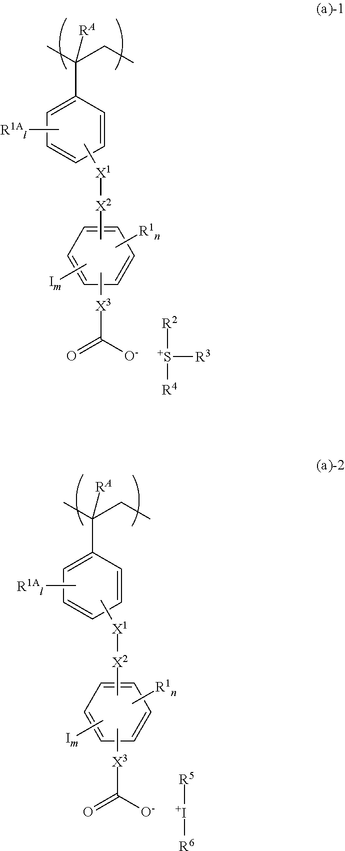

wherein R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{1A} each independently represents a halogen atom, a hydroxy group, or a linear or branched alkoxy group or acyloxy group each having 1 to 6 carbon atoms; “l” represents an integer of 0 to 3; “m” represents an integer of 0 to 4; “n” represents an integer of 0 to 4, provided that an anion moiety of the pendant group contains one or more iodine atoms; and R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto.

Hereinafter, the present invention will be described in detail. However, the present invention is not limited thereto.

### Positive Resist Material

A positive resist material of the present invention is a positive resist material including a base polymer with a sulfonium salt or an iodonium salt of carboxylic acid as a pendant group attached to a polymer backbone, wherein the base polymer contains a repeating unit (a) containing one or more iodine atoms between the polymer backbone and carboxylate, the repeating unit (a) containing one or both of a repeating unit represented by the following general formula (a)-1 (also referred to as the repeating unit (a1), the same applies hereinafter) and a repeating unit represented by the following general formula (a)-2 (repeating unit (a2)). The base polymer is characterized in that the pendant group attached to the backbone thereof has a sulfonium salt or an iodonium salt structure of carboxylic acid, containing one or more iodine atoms in an anion moiety of the pendant group.

Then, the above base polymer can further contain a repeating unit of a sulfonium salt or an iodonium salt of sulfonic acid.

Moreover, to increase dissolution contrast, a repeating unit in which a hydrogen atom of a carboxy group or a phenolic hydroxy group is substituted with an acid labile group is introduced, thereby obtaining a resist material that has high sensitivity, significantly high contrast of alkali dissolution rates before and after exposure, high sensitivity and effect on suppressing acid diffusion, high resolution, a favorable pattern profile after exposure, and small edge roughness and dimensional variation. The resist material is particularly suitable as a material for producing Very LSI or fine patterning of a photomask.

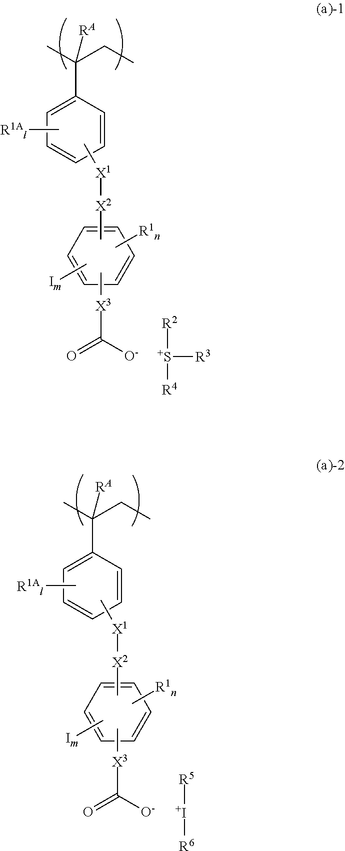

In the formulae, R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{1A} each independently represents a halogen atom, a hydroxy group, or a linear or branched alkoxy group or acyloxy group each having 1 to 6 carbon atoms; “l” represents an integer of 0 to 3; “m” represents an integer of 0 to 4; “n” represents an integer of 0 to 4, provided that an anion moiety of the pendant group contains one or more iodine atoms; and R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto.

In the formulae, R^{A} represents a hydrogen atom or a methyl group, preferably a hydrogen atom. X¹ represents a single bond, an ester group, an ether group, or a sulfonic acid ester group, preferably an ester group. X² represents a single bond, or a linear, branched, or cyclic alkyl group having 1 to 12 carbon atoms and optionally containing one or more selected from an ester group, an ether group, an amide group, a lactone ring, a sultone ring, and a halogen atom, preferably containing an ether group. X³ represents a linear or branched alkylene group having 1 to 10 carbon atoms, optionally containing one or more selected from an ether group, an ester group, an aromatic group, a double bond, and a triple bond, and having 1 to 4 fluorine atoms, preferably two or more fluorine atoms. R¹ each independently represents a hydroxy group, a linear or branched alkyl group, alkoxy group, or acyloxy group each having 1 to 4 carbon atoms, or a halogen atom other than iodine, preferably a fluorine atom. R^{1A} each independently represents a halogen atom, a hydroxy group, or a linear or branched alkoxy group or acyloxy group each having 1 to 6 carbon atoms, preferably a halogen atom (selected from fluorine, chlorine, bromine, and iodine) or a hydroxy group. “l” represents an integer of 0 to 3, “m” represents an integer of 0 to 4, and “n” represents an integer of 0 to 4, preferably 1=0 to 1, m=1 to 2, and n=0 to 1. Note that an anion moiety of the pendant group contains one or more iodine atoms. R² to R⁶ each independently represents a monovalent hydrocarbon group having 1 to 25 carbon atoms, preferably 1 to 20 carbon atoms, and optionally having a heteroatom, preferably an aromatic hydrocarbon group. The aromatic group can be a substituted or unsubstituted aryl group, or a substituted or unsubstituted heteroaryl group.

The repeating unit (a) is a quencher containing at least one or more iodine atoms between the polymer backbone and carboxylate at the end of the pendant group, and the base polymer is a quencher-bound polymer. The repeating unit (a) preferably has a structure of a sulfonium salt or an iodonium salt of carboxylic acid, having an iodized benzene ring skeleton and a fluorine atom. The quencher-bound polymer is characterized by high suppression effect on acid diffusion and excellent resolution as described above. This enables to achieve high resolution, low LWR, and low CDU. Furthermore, by including the skeleton where the polymer backbone is directly bonded to the benzene ring, it is possible to enhance etching resistance.

Examples of an anion moiety of a monomer providing the repeating units (a1) and (a2) are shown below, but not limited thereto. Note that in the following formulae, R^{A} is as defined above.

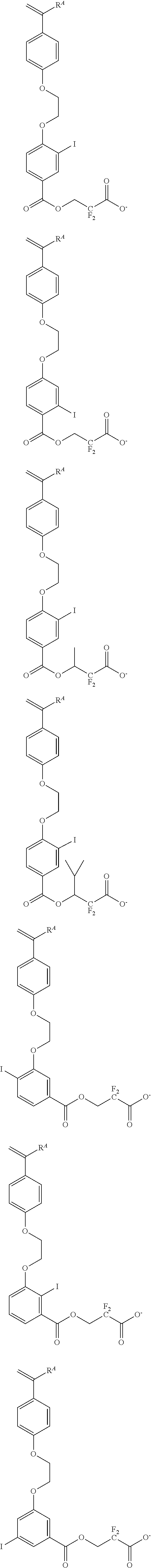

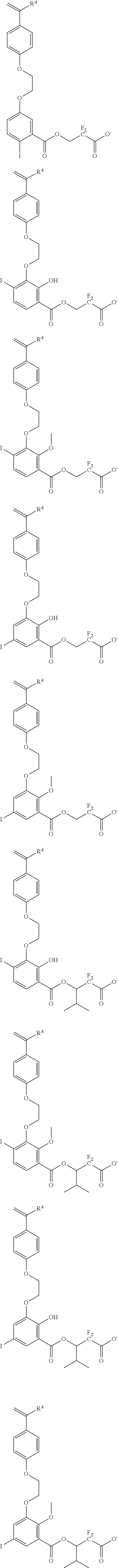

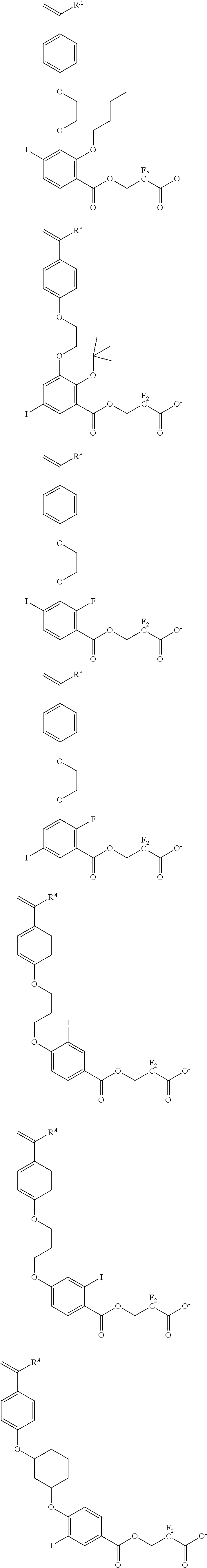

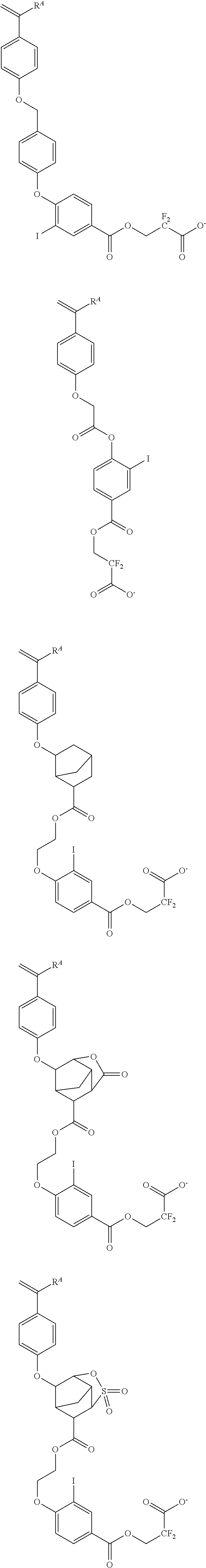

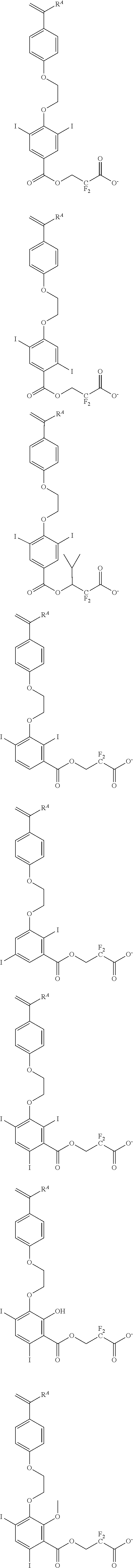

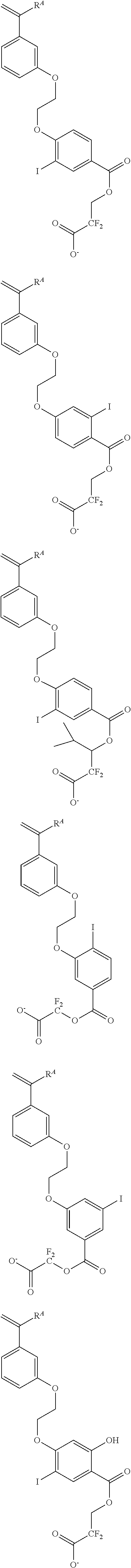

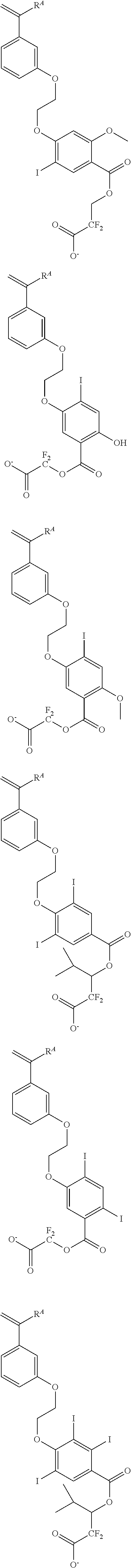

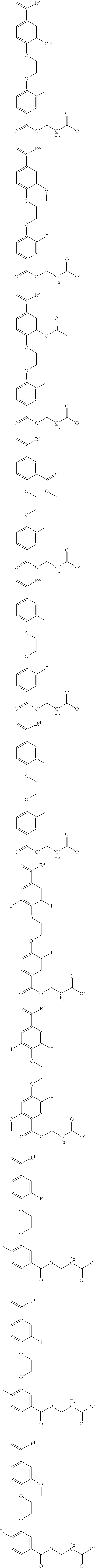

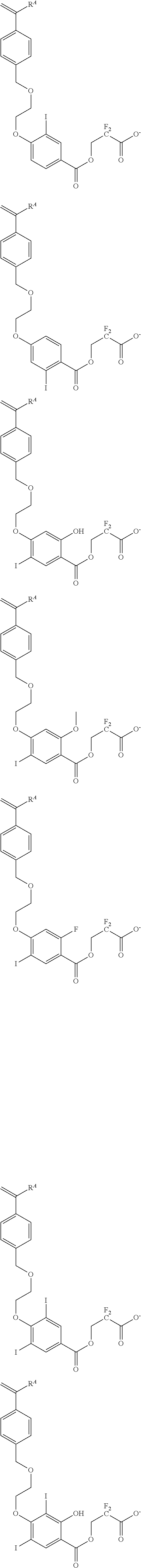

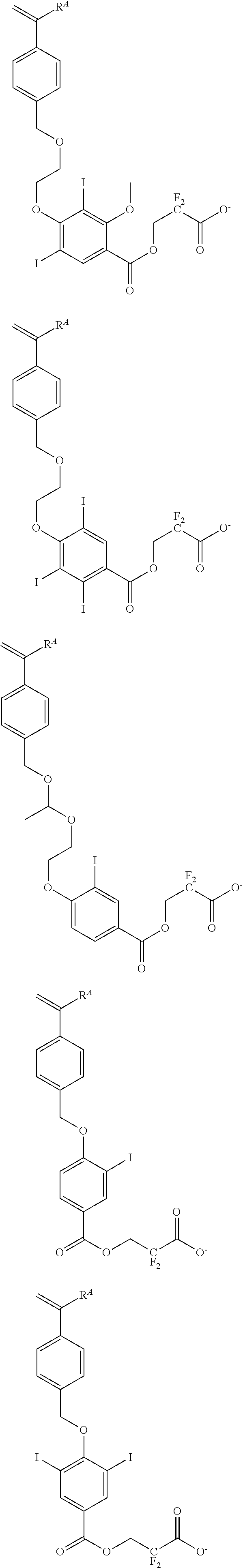

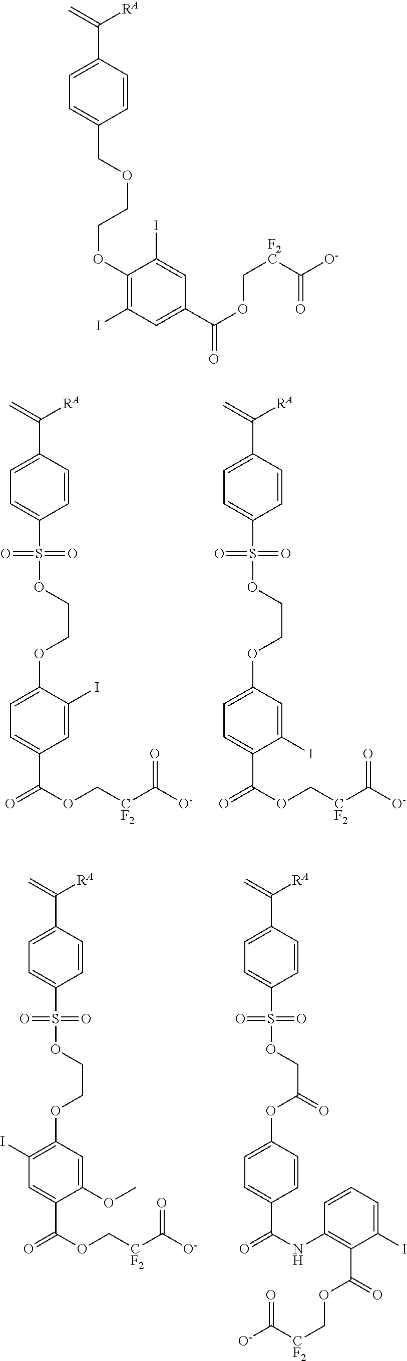

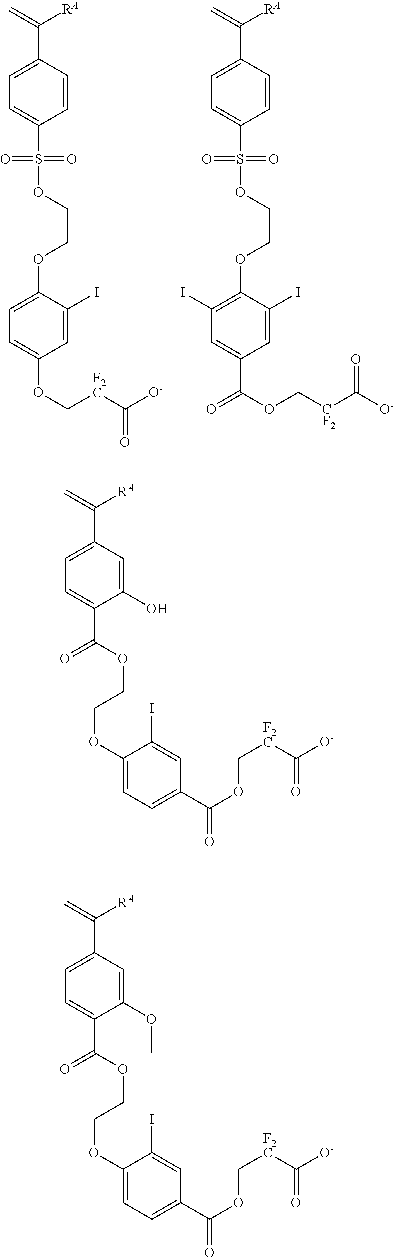

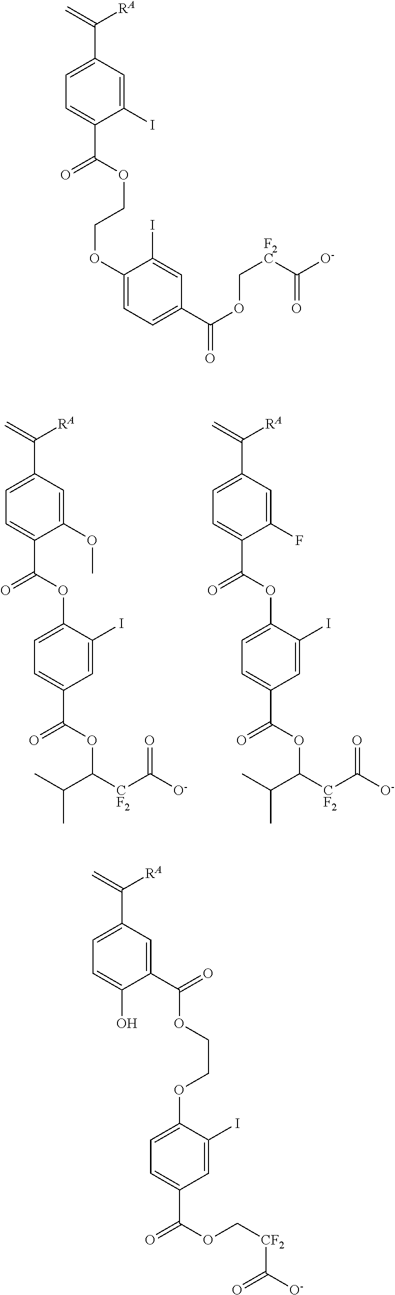

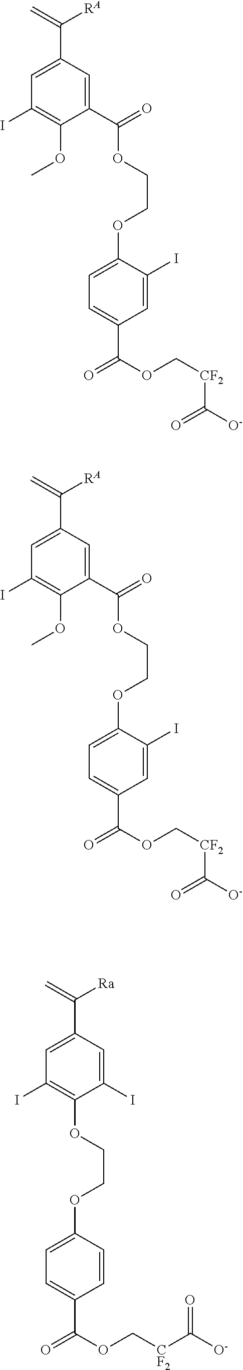

Examples of the cation of the sulfonium salt represented by the general formula (a)-1 are shown below, but not limited thereto. Note that for substituents on the benzene ring, all possible positions of o-, m-, and p-positions are included, and representative examples are shown below. The same applies hereinafter.

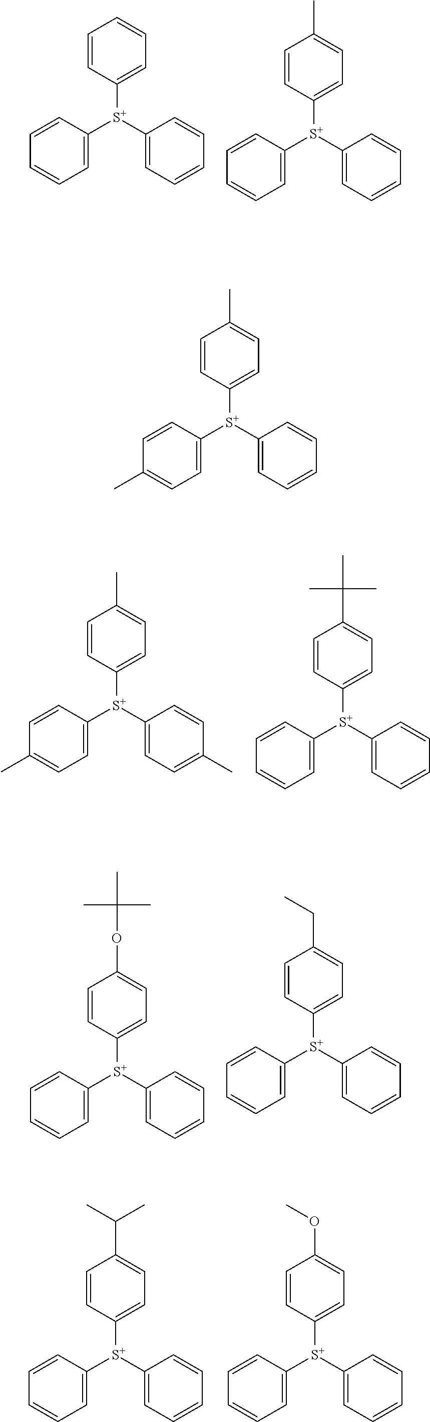

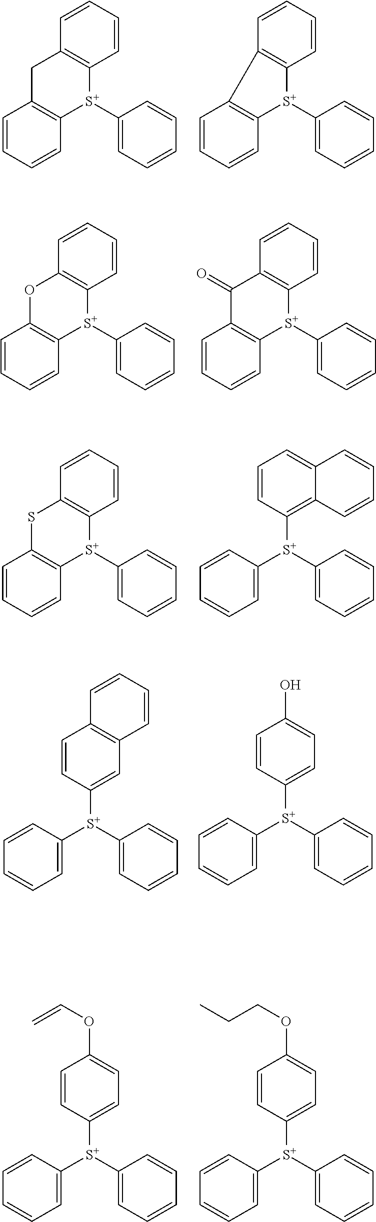

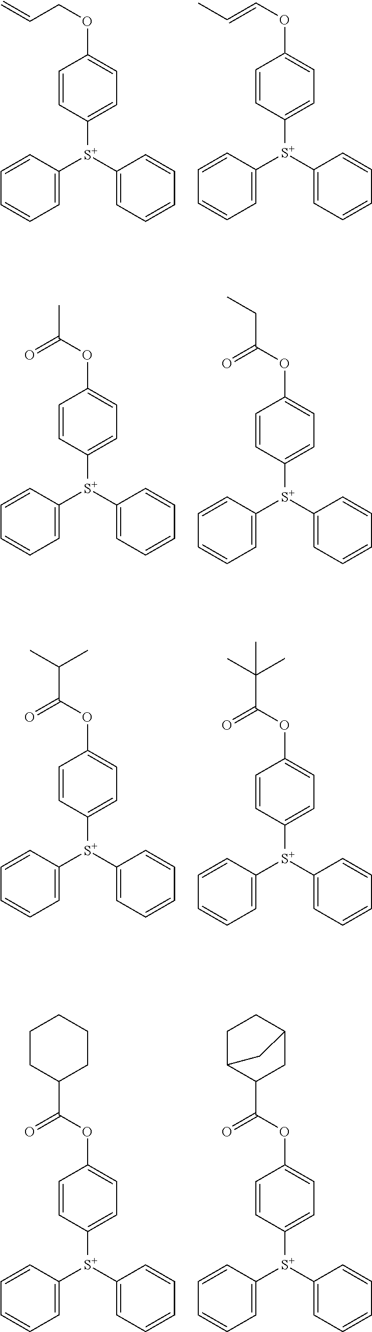

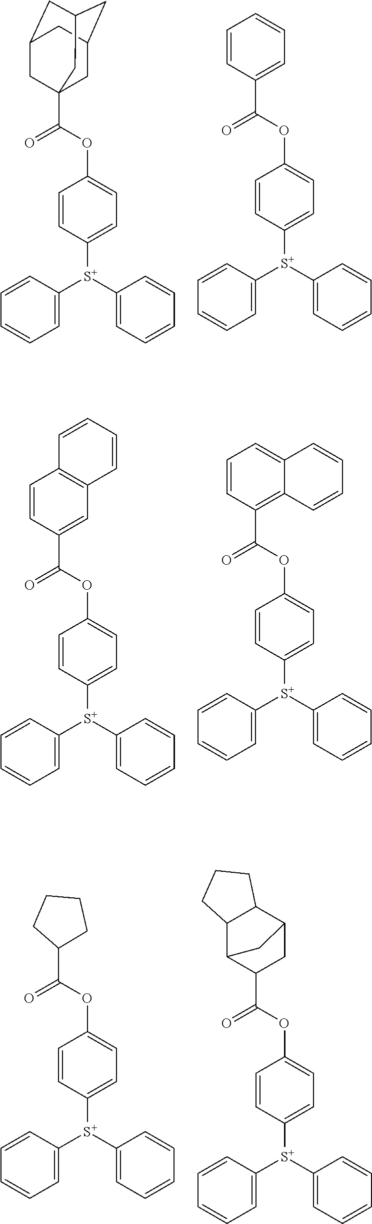

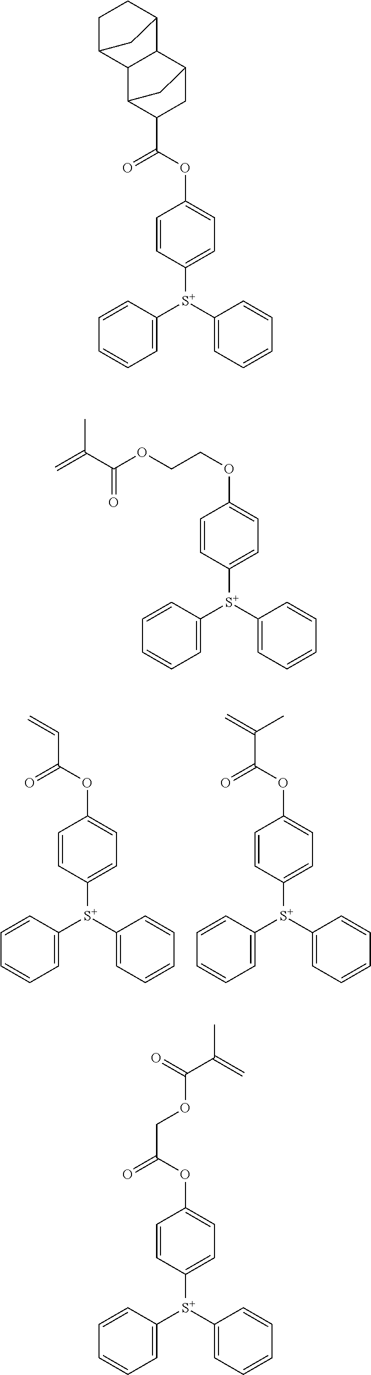

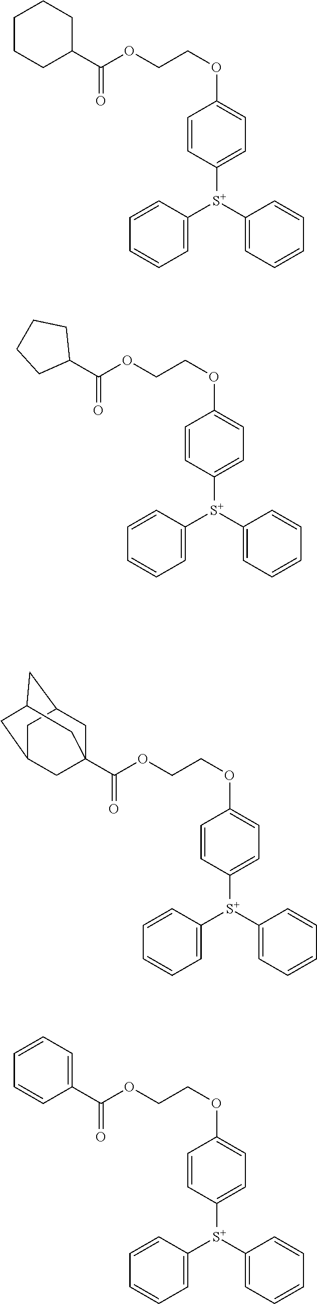

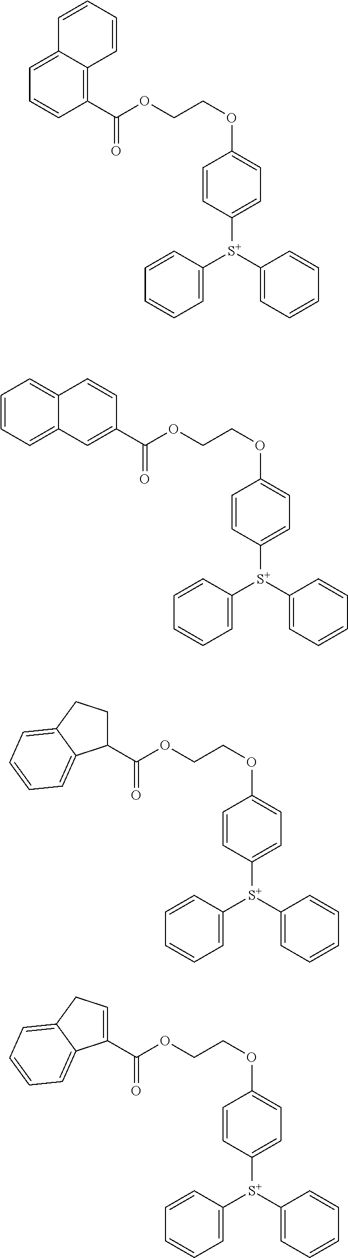

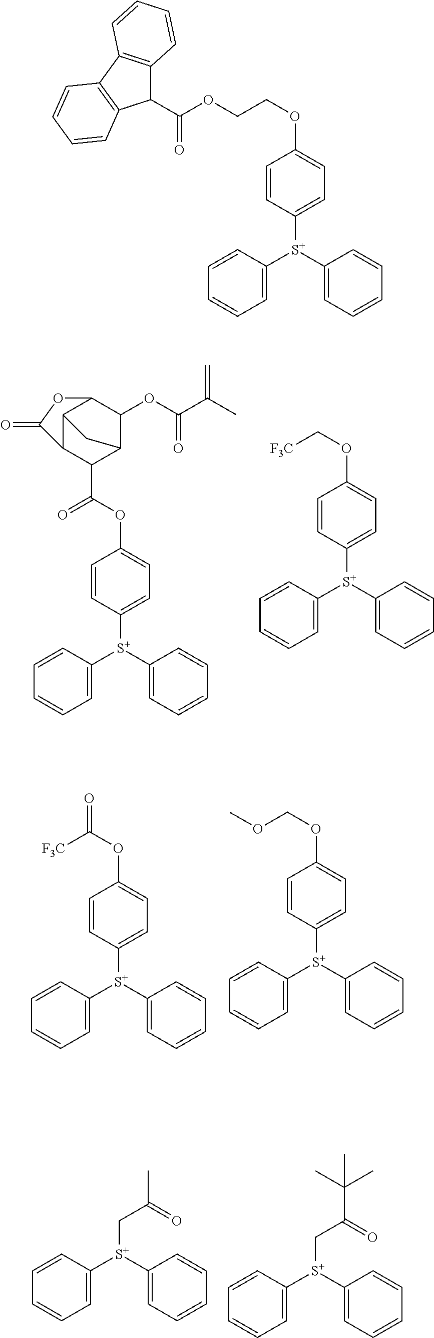

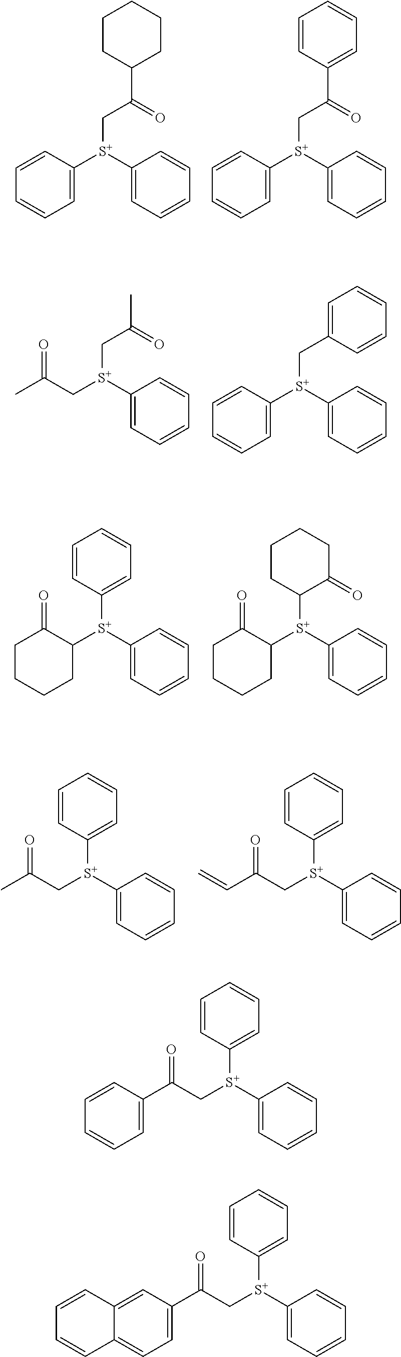

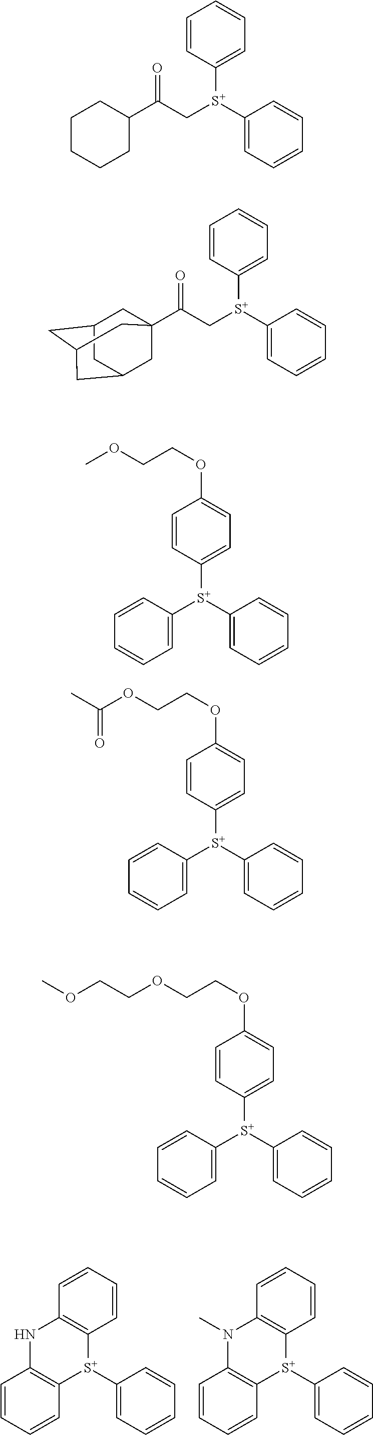

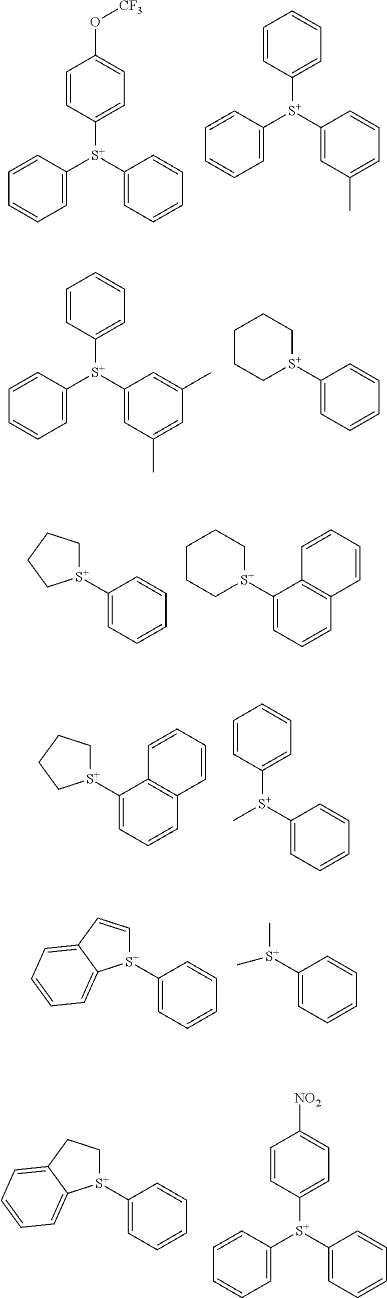

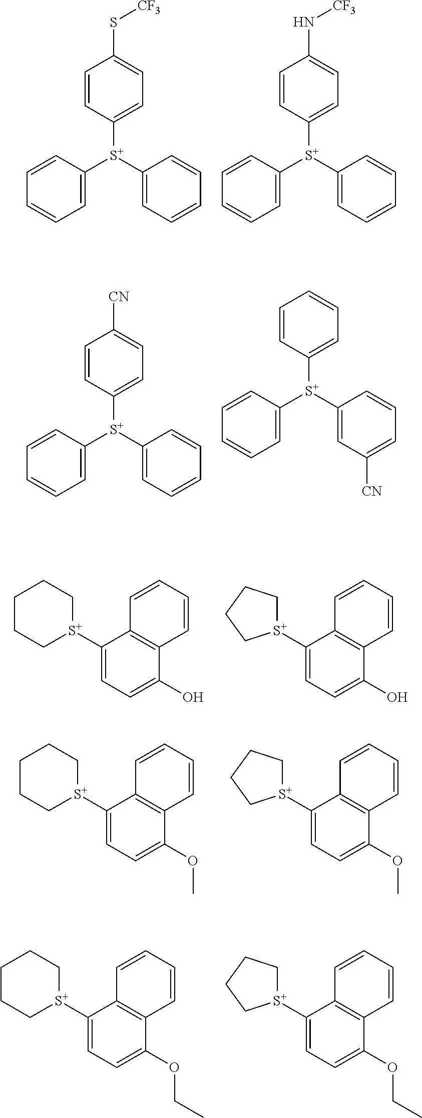

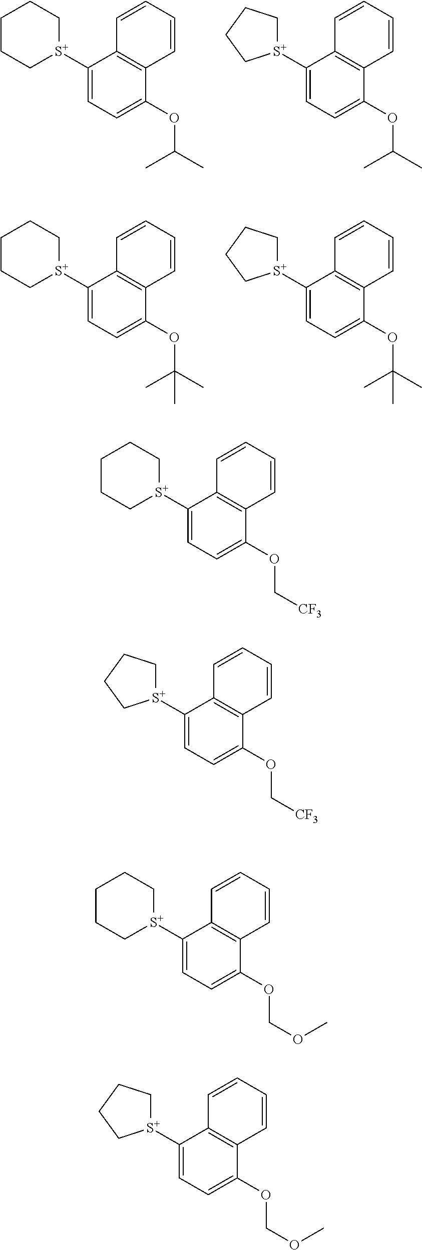

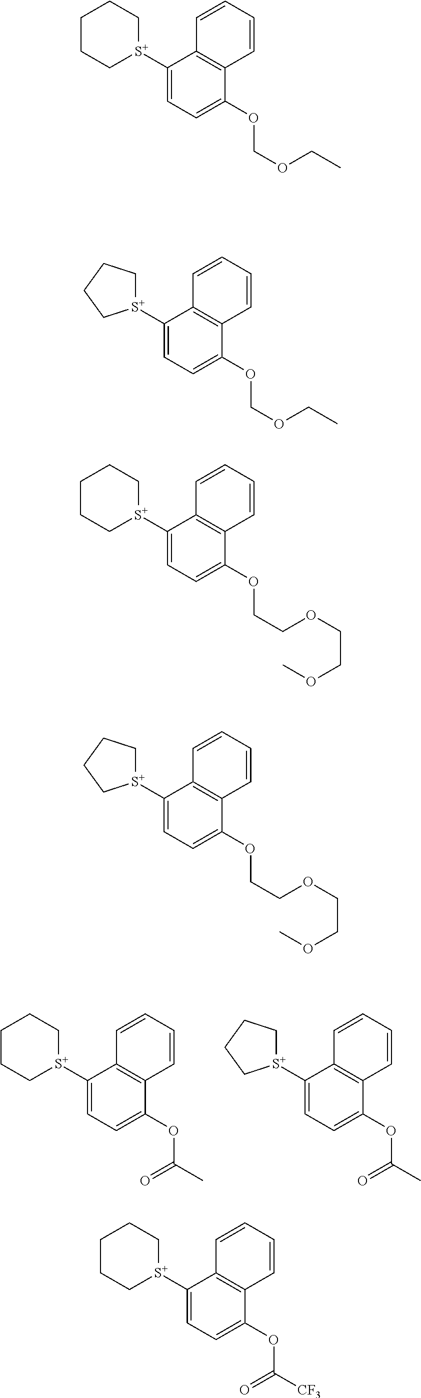

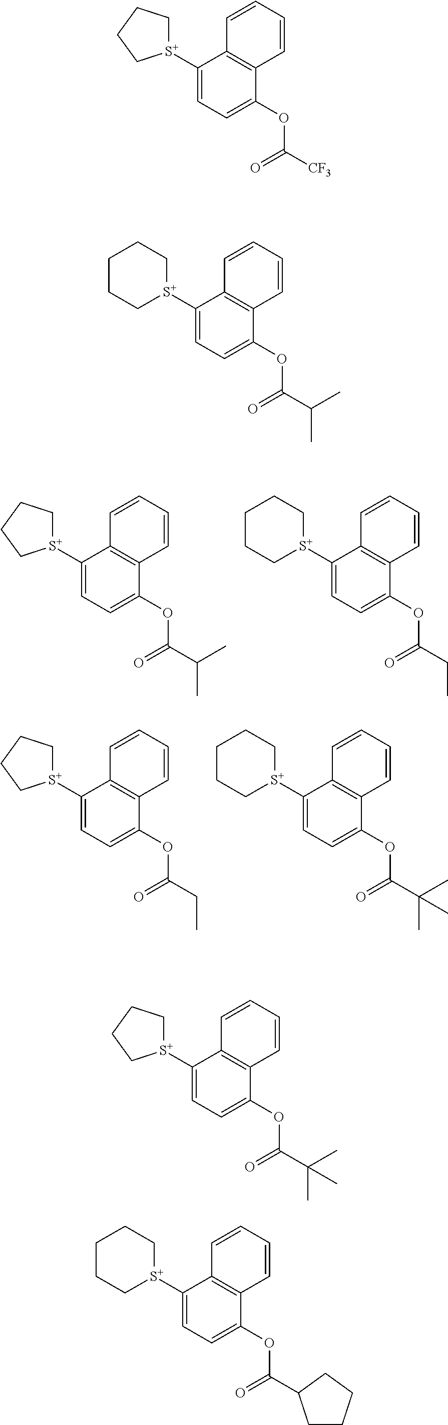

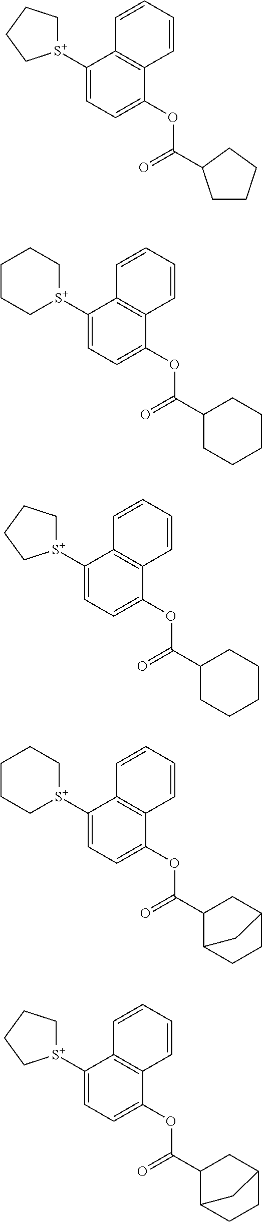

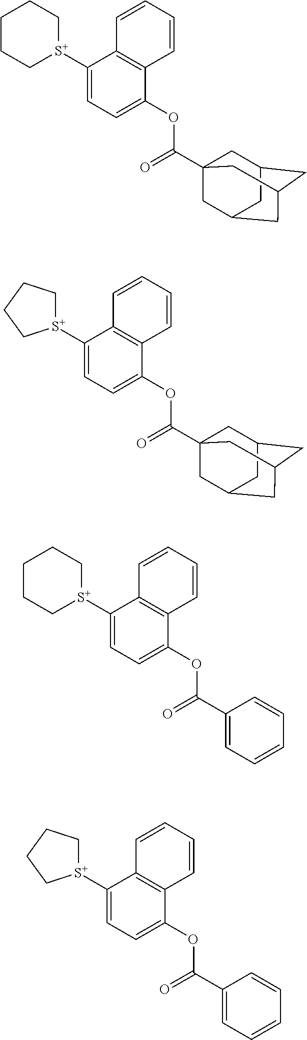

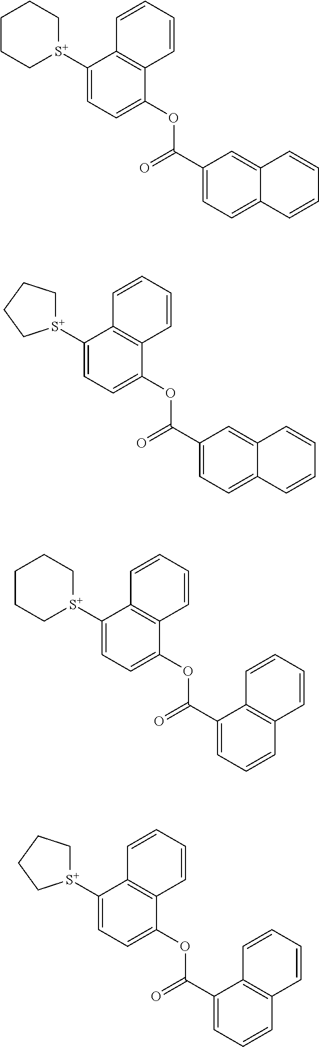

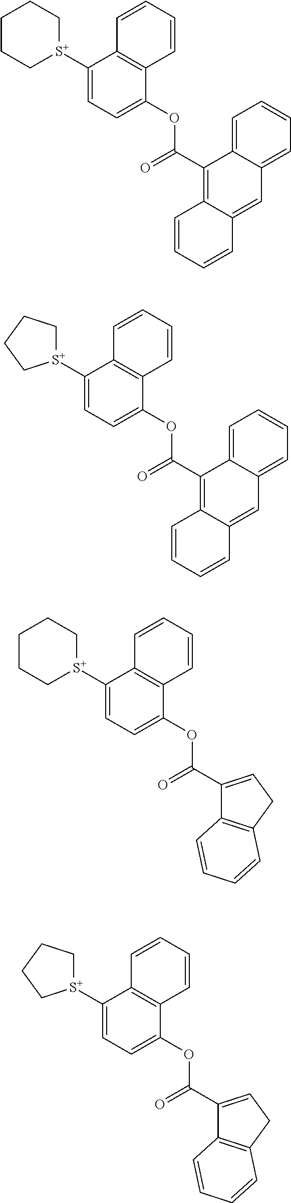

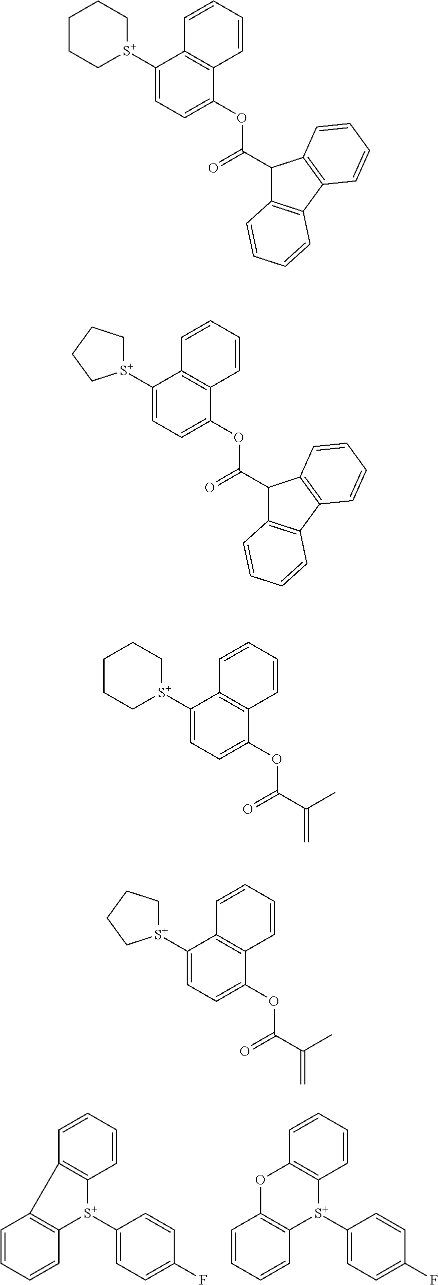

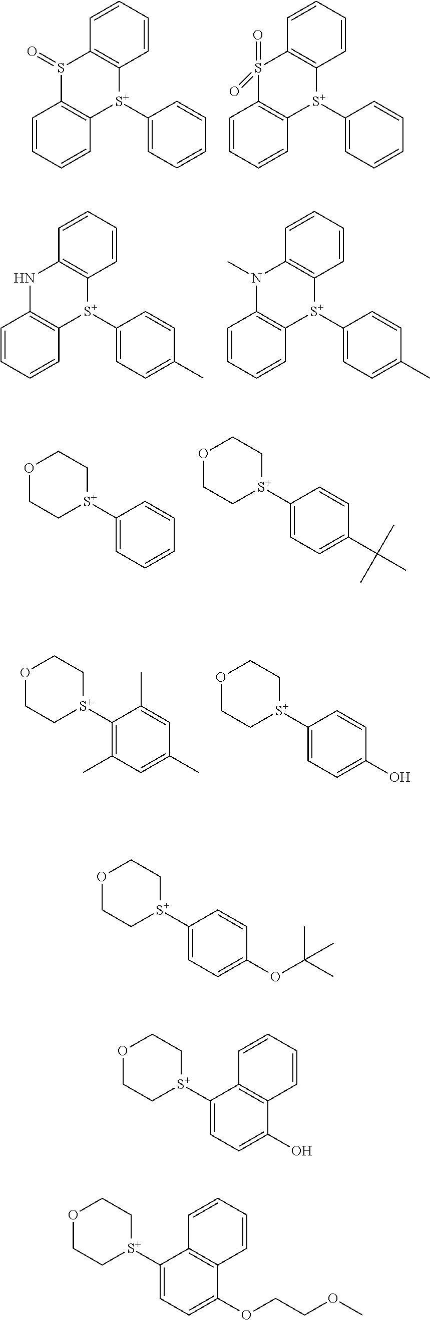

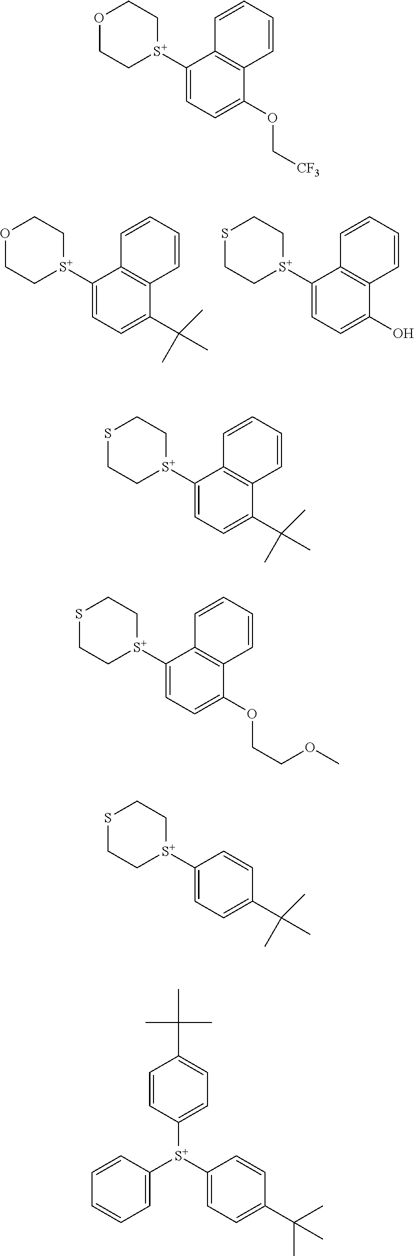

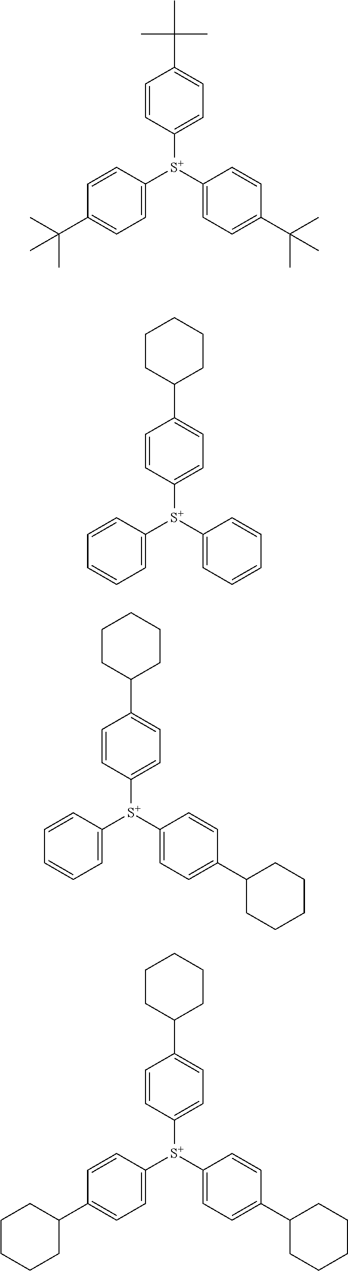

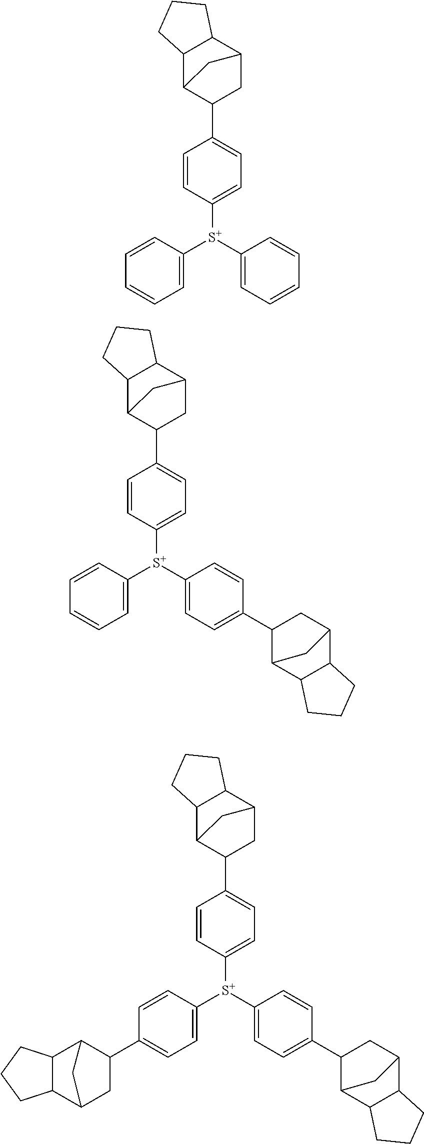

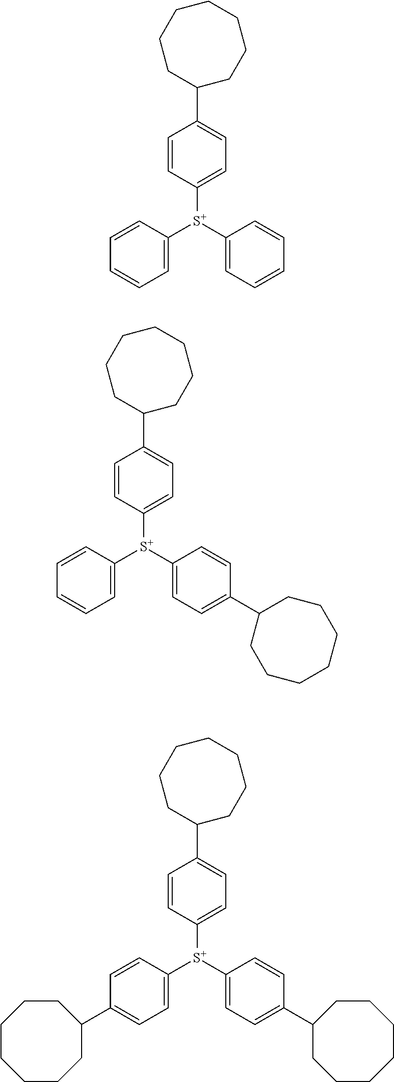

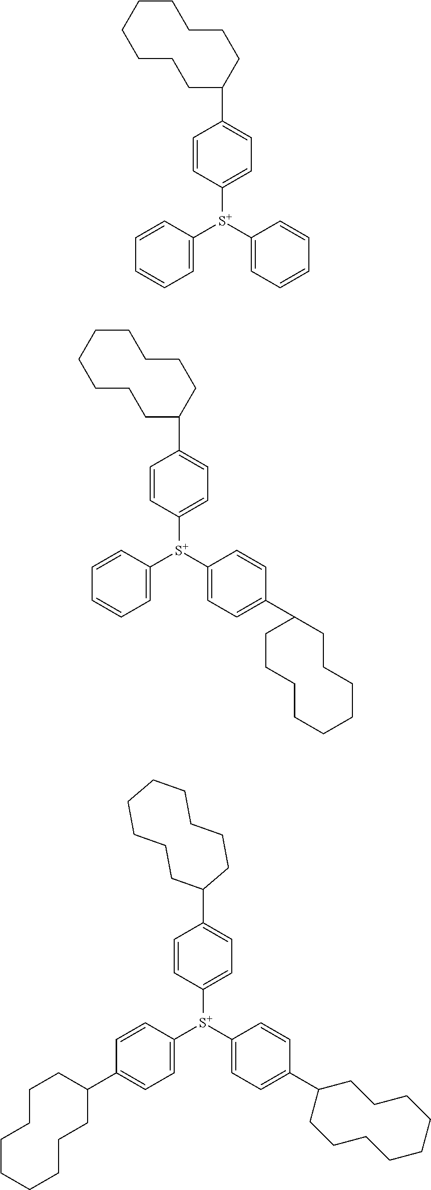

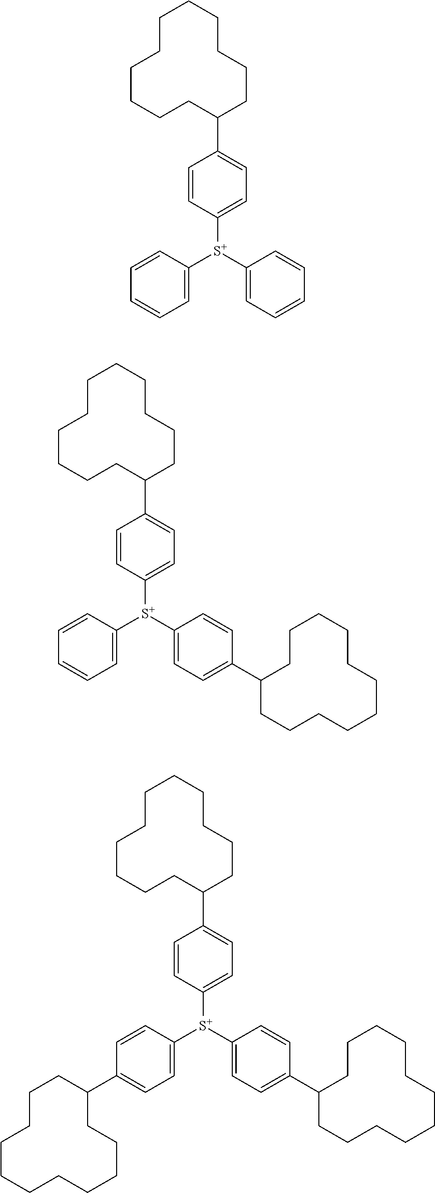

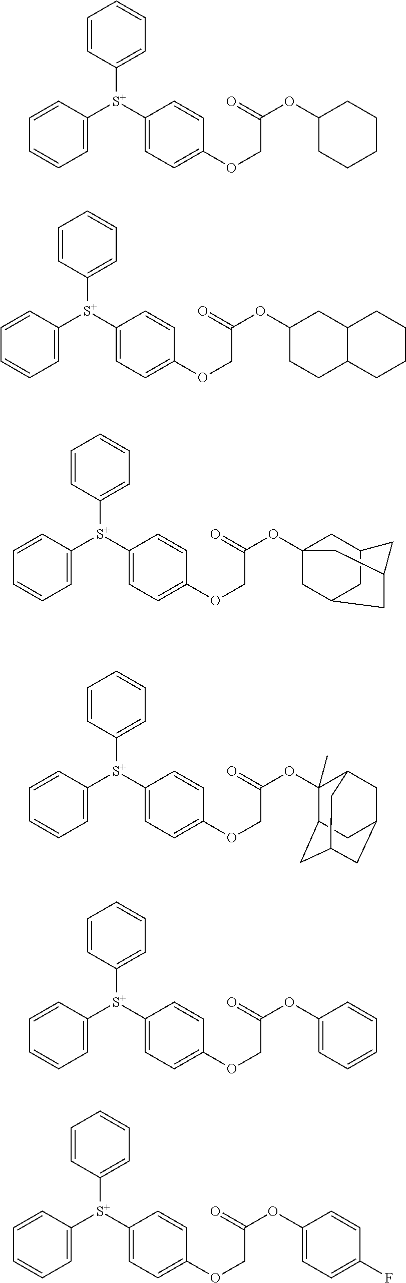

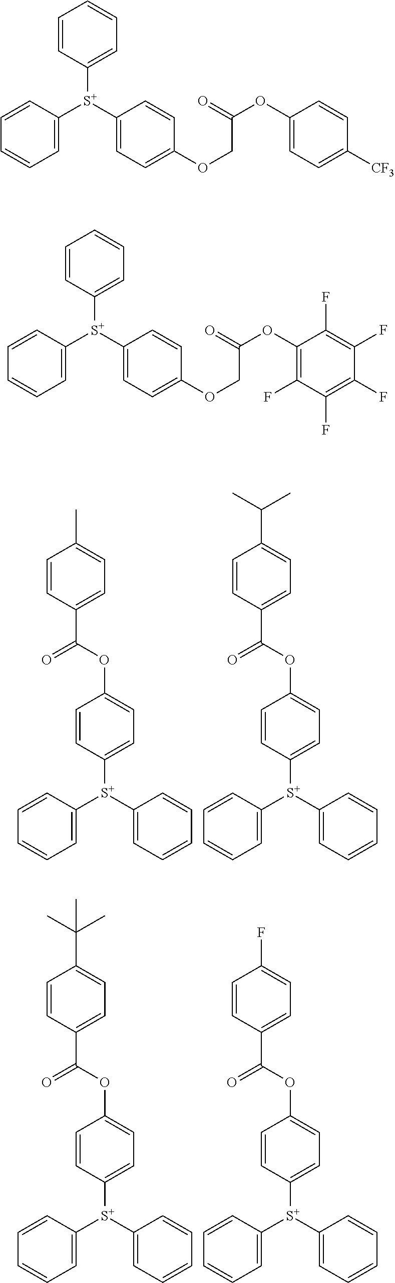

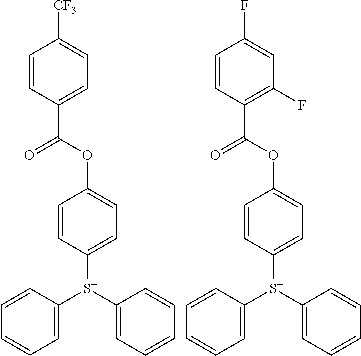

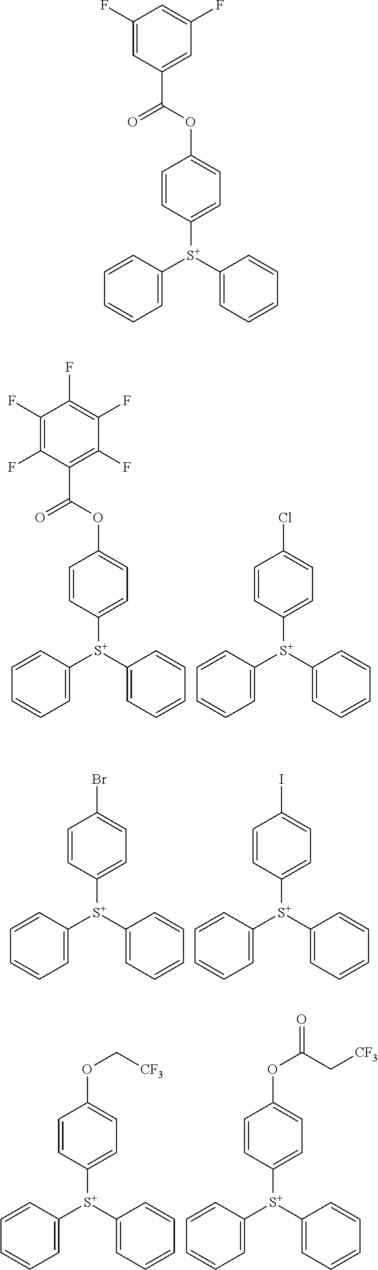

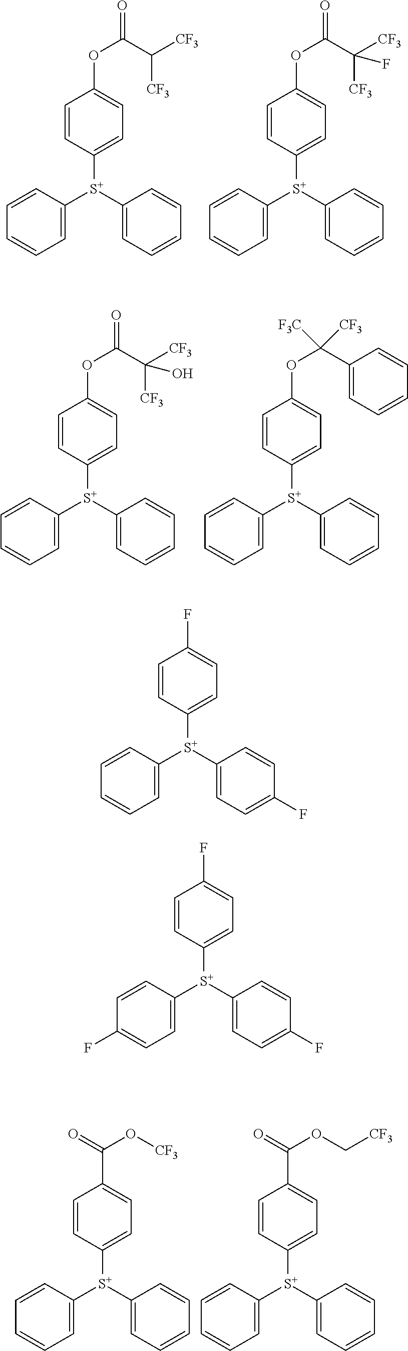

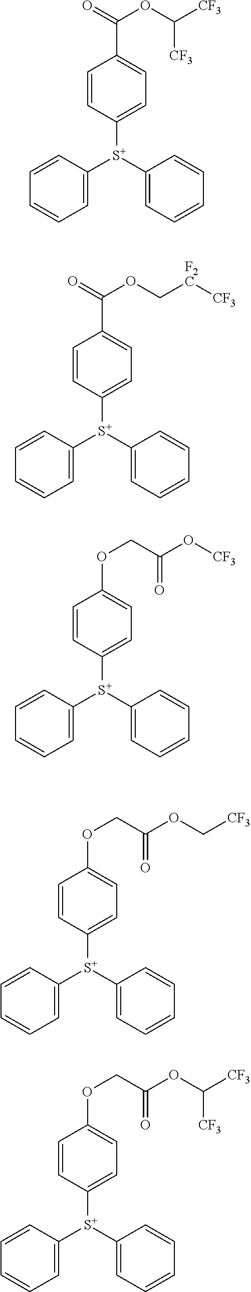

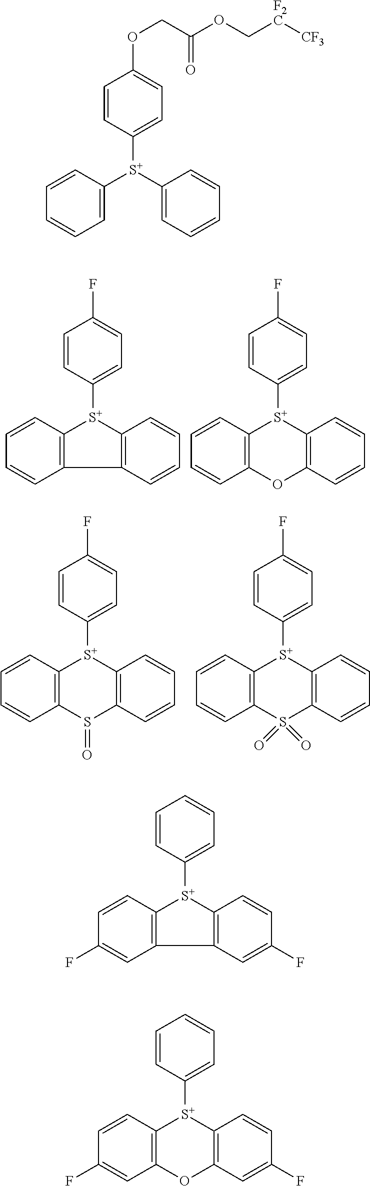

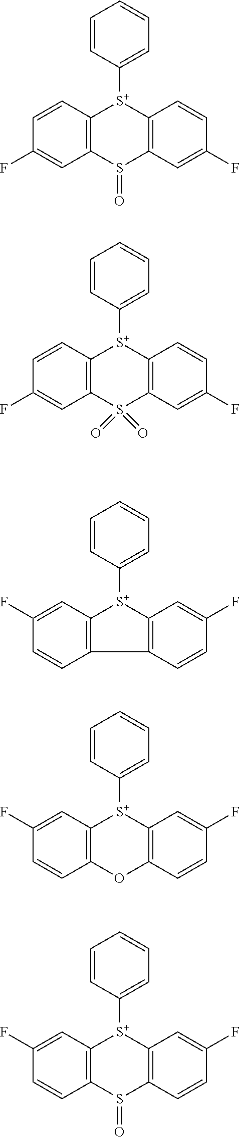

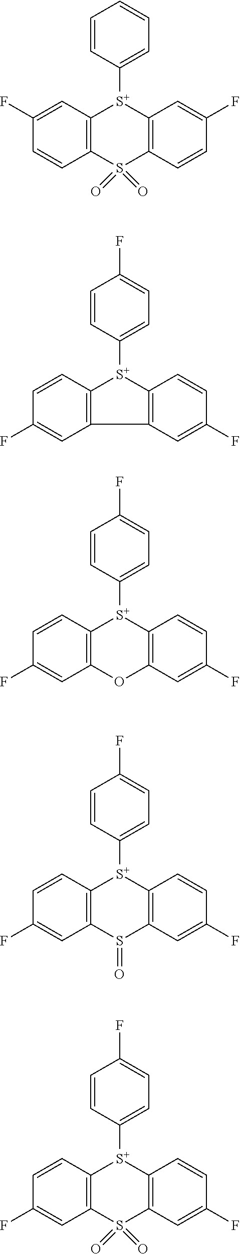

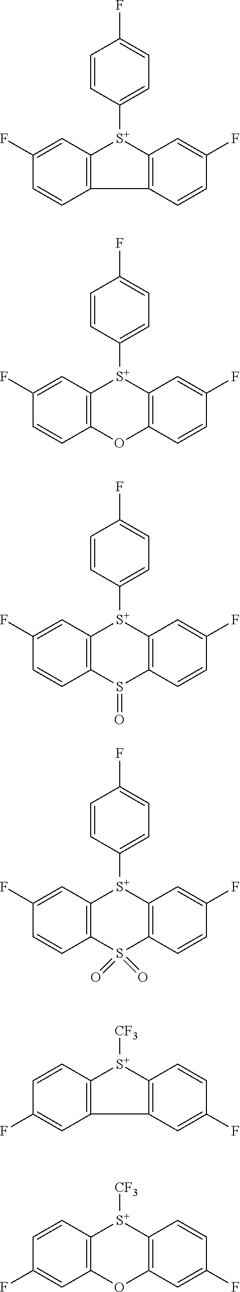

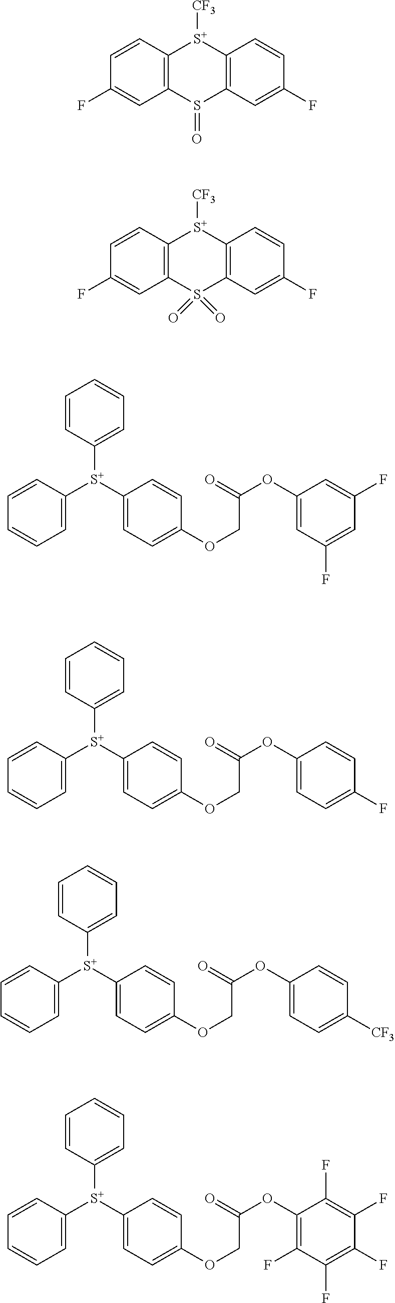

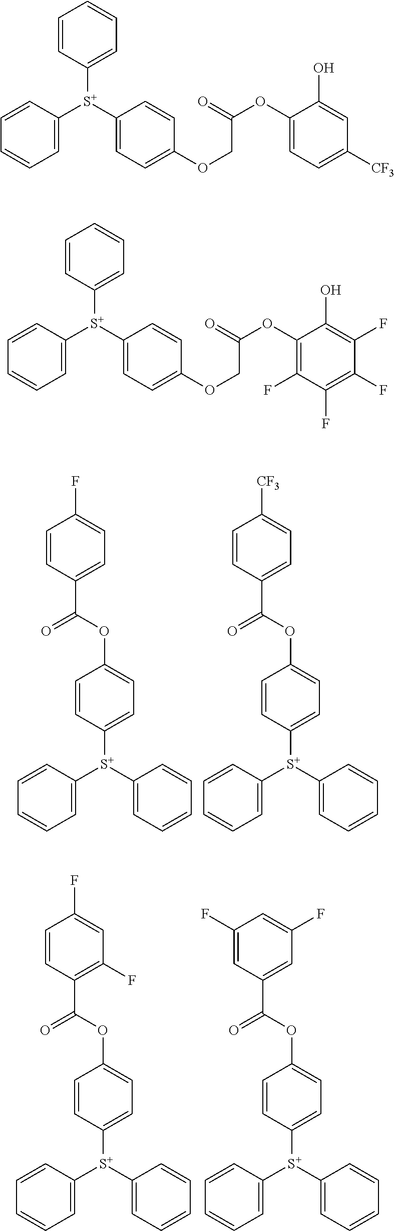

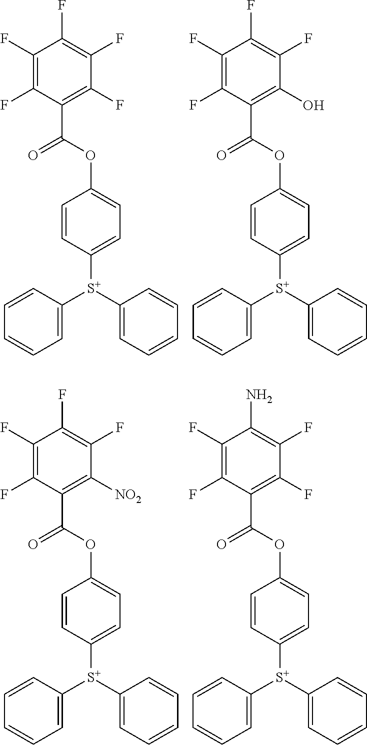

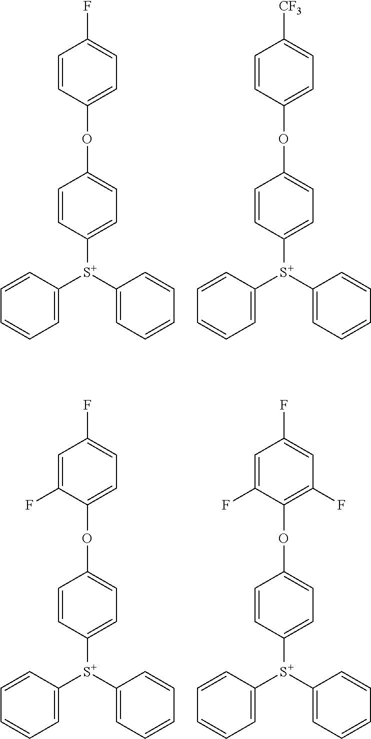

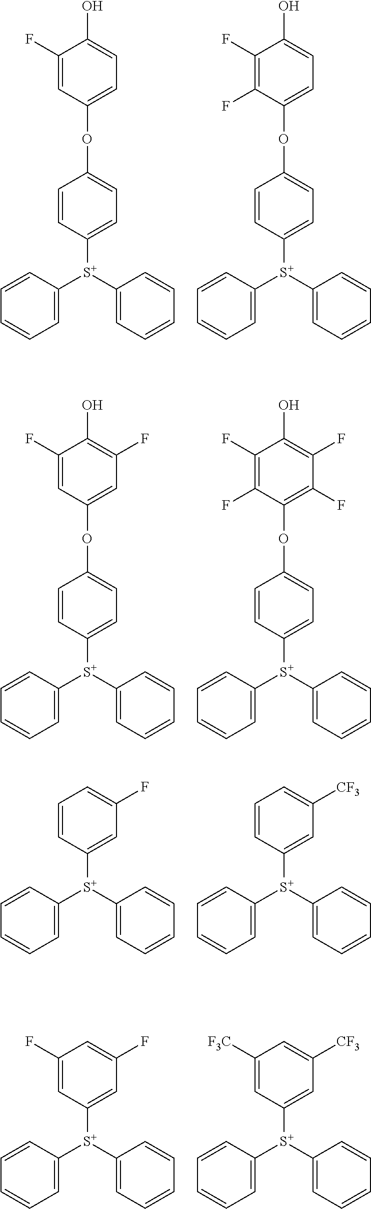

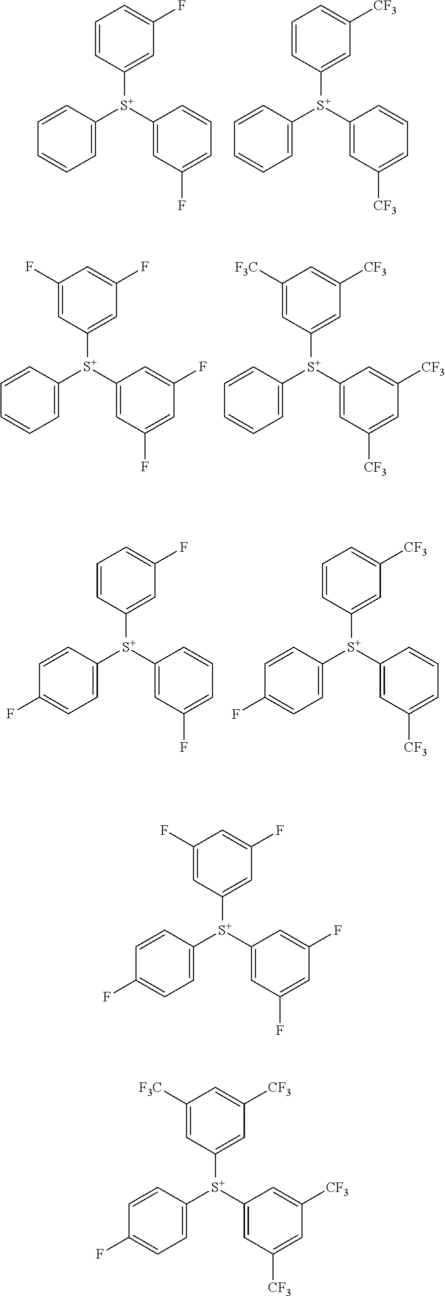

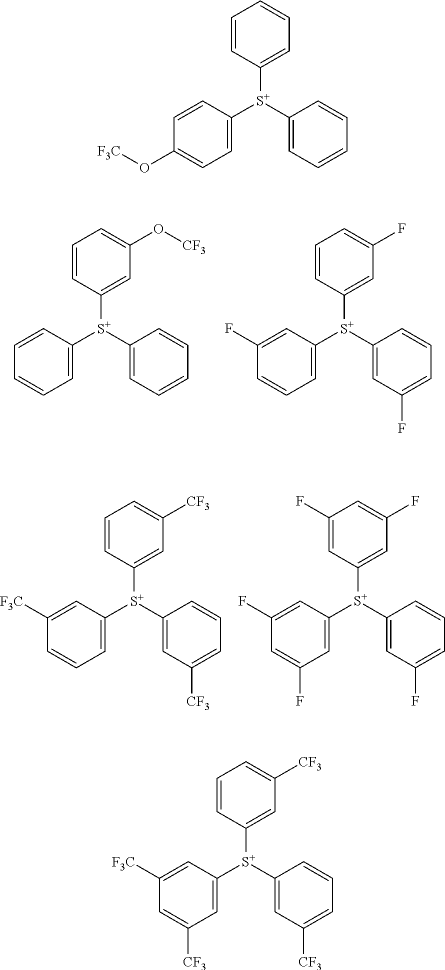

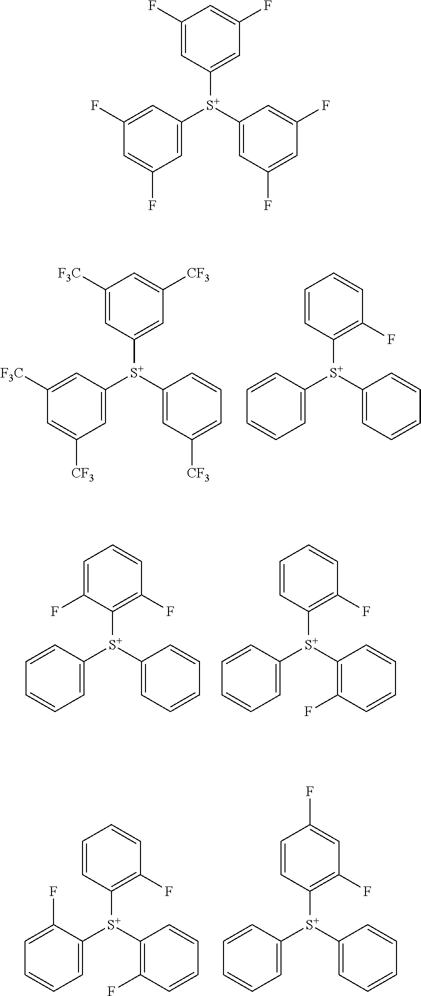

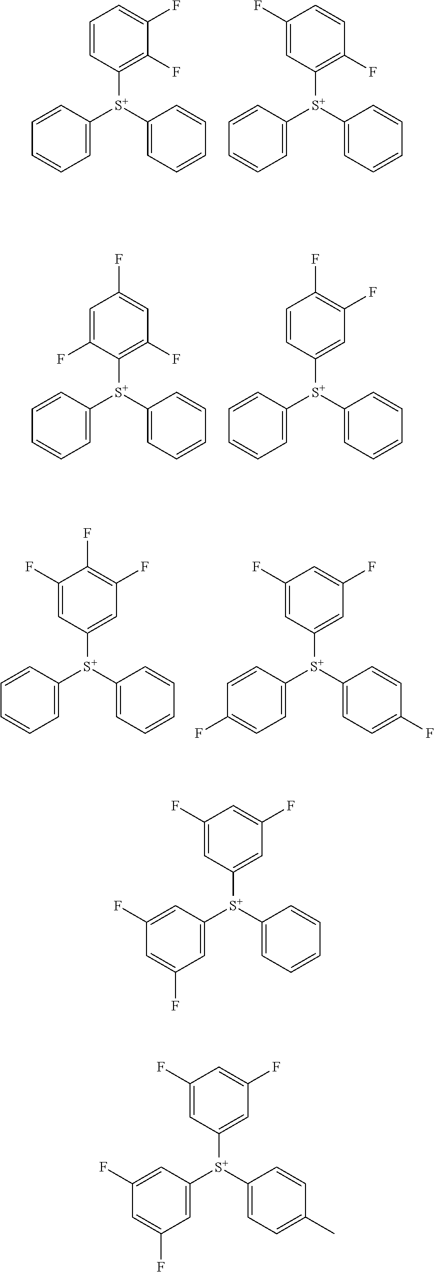

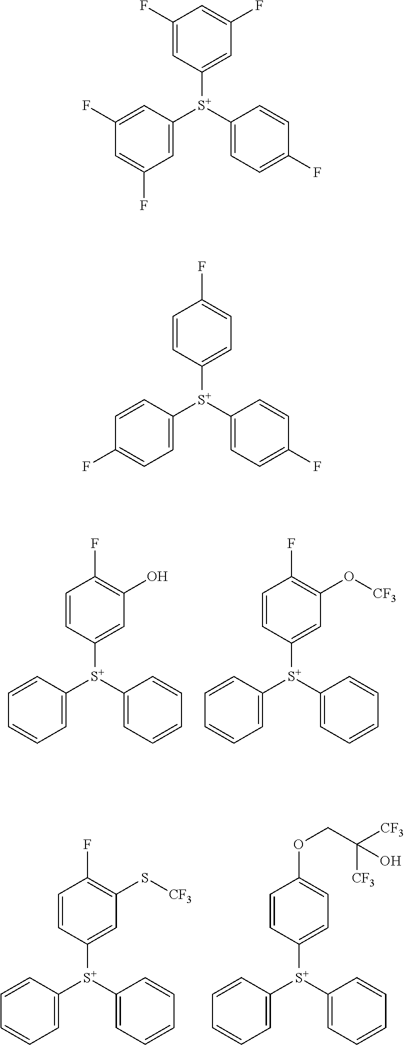

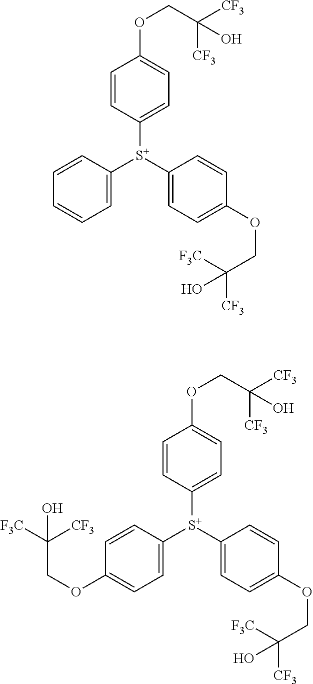

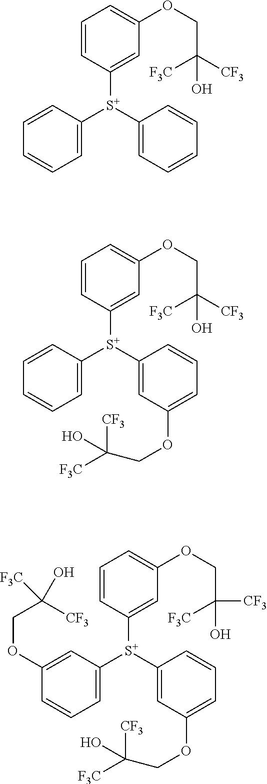

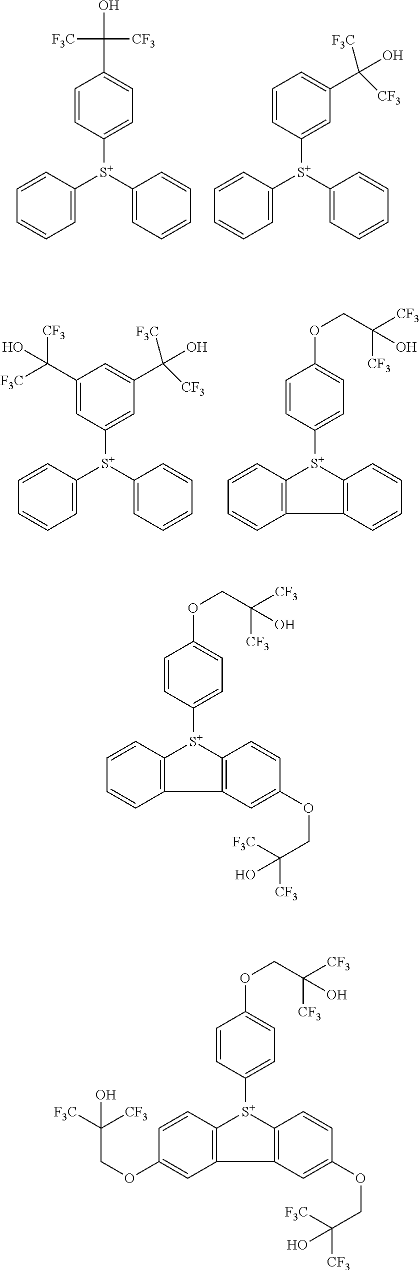

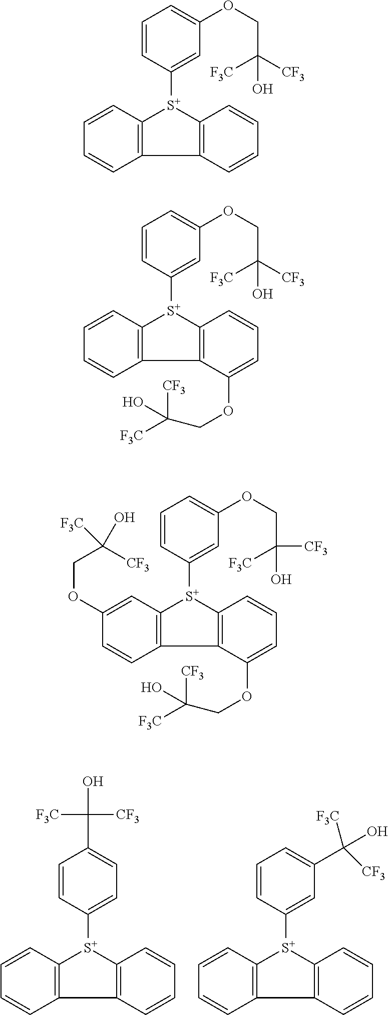

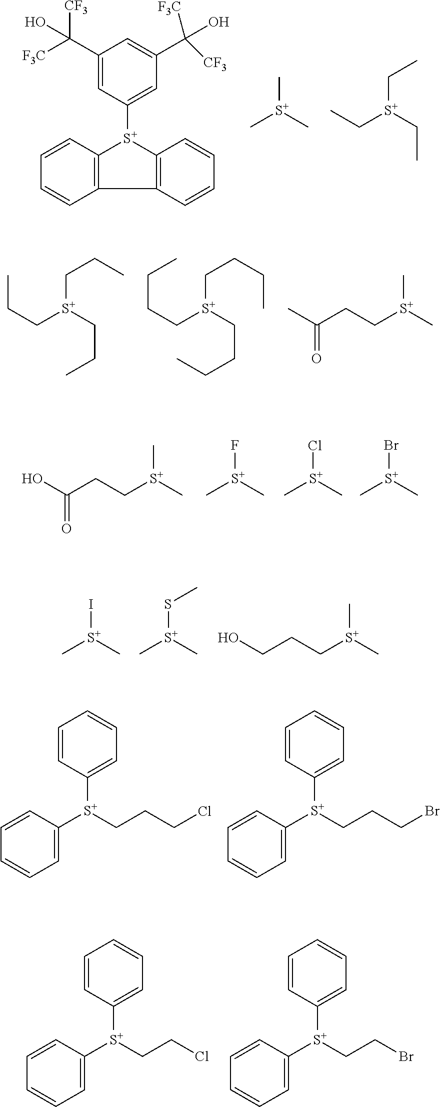

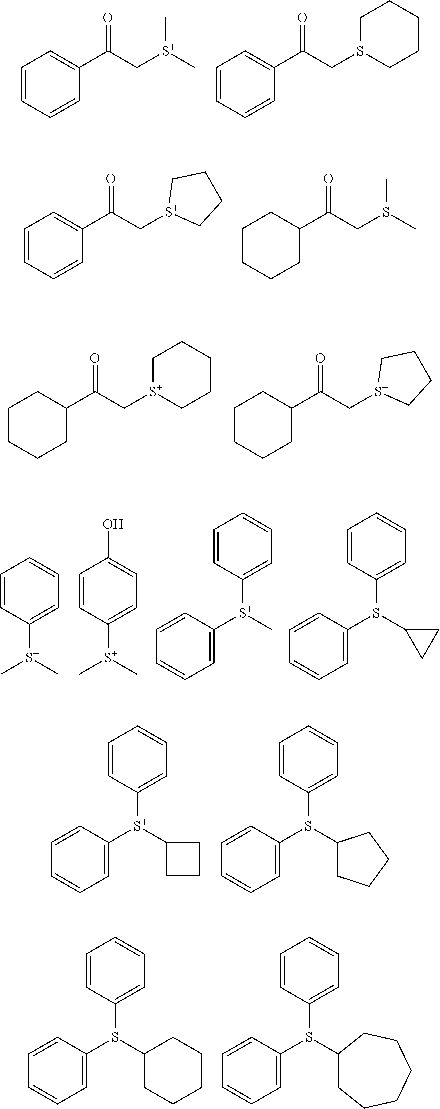

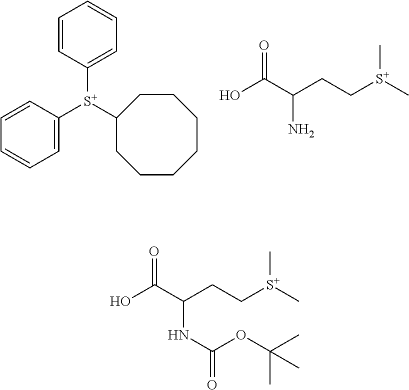

Examples of the cation of the iodonium salt represented by the general formula (a)-2 are shown below, but not limited thereto.

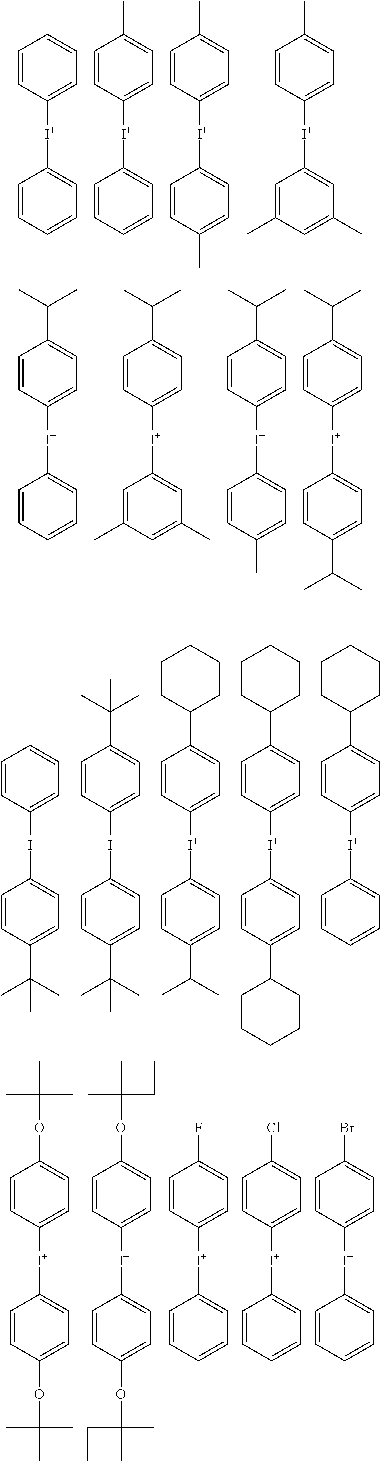

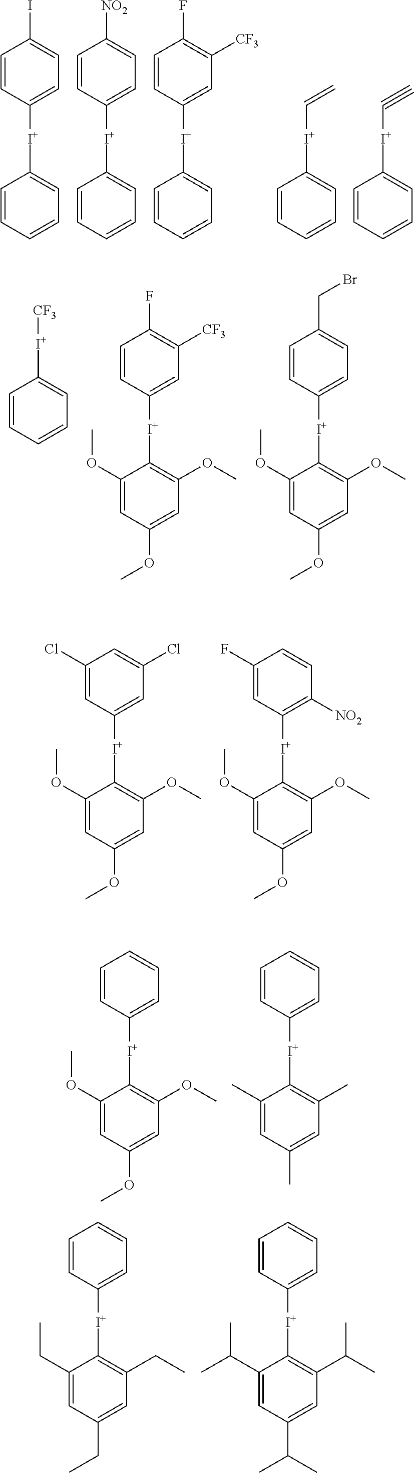

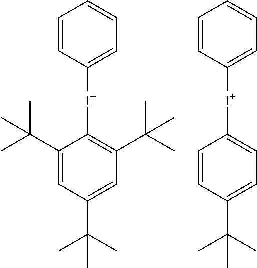

To increase dissolution contrast, the base polymer may contain a repeating unit in which a hydrogen atom of a carboxy group is substituted with an acid labile group (hereinafter also referred to as the repeating unit (c1)) and/or a repeating unit in which a hydrogen atom of a phenolic hydroxy group is substituted with an acid labile group (hereinafter also referred to as the repeating unit (c2)).

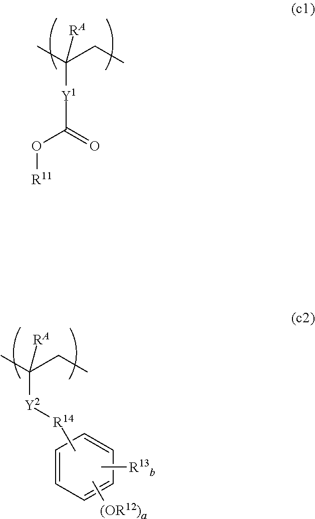

In the formulae, R^{A} each independently represents a hydrogen atom or a methyl group; Y¹ represents a single bond, a phenylene group, a naphthylene group, or a linking group having 1 to 12 carbon atoms and having an ester bond, an ether bond, or a lactone ring; Y² represents a single bond, an ester bond, or an amide bond; R¹¹ and R¹² represent an acid labile group; R¹³ represents a fluorine atom, a trifluoromethyl group, a cyano group, or an alkyl group having 1 to 6 carbon atoms; R¹⁴ represents a single bond, or a linear or branched alkanediyl group having 1 to 6 carbon atoms, in which some of carbon atoms thereof are optionally substituted with an ether bond or an ester bond; “a” represents 1 or 2; and “b” represents an integer of 0 to 4.

Examples of a monomer providing the repeating unit (c1) are shown below, but not limited thereto. Note that in the following formulae, R^{A} and R¹¹ are as defined above.

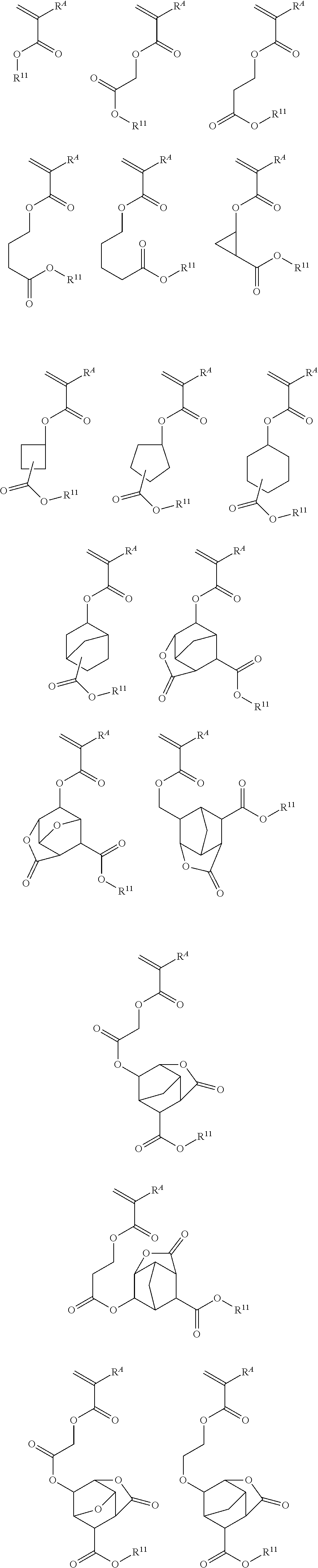

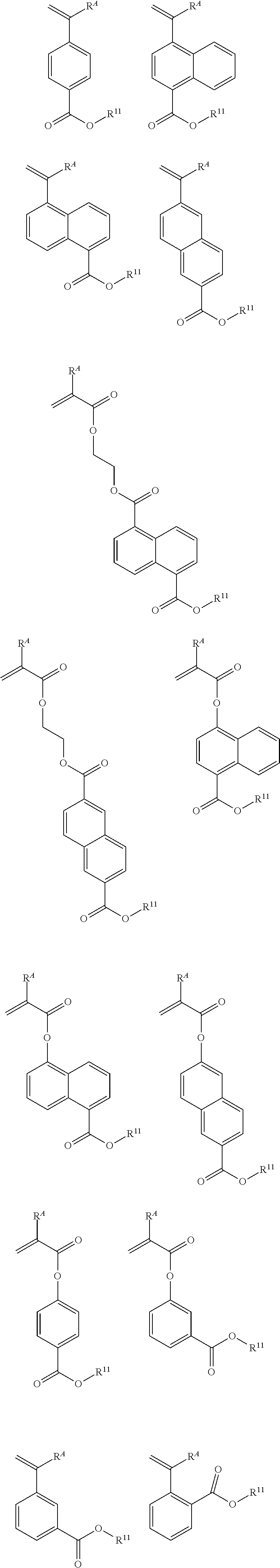

Examples of a monomer from which the repeating unit (c2) is made are shown below, but not limited thereto. Note that in the following formulae, R^{A} and R¹² are as defined above.

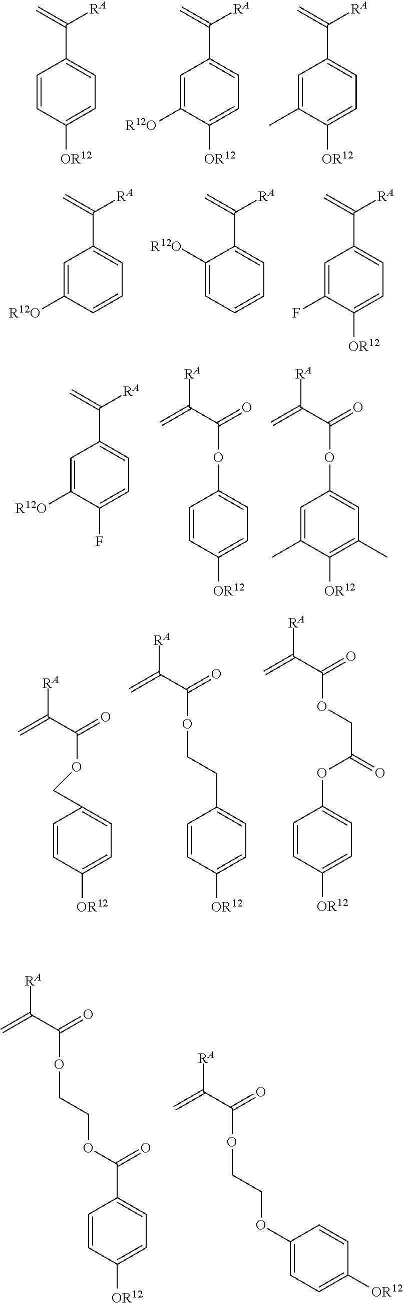

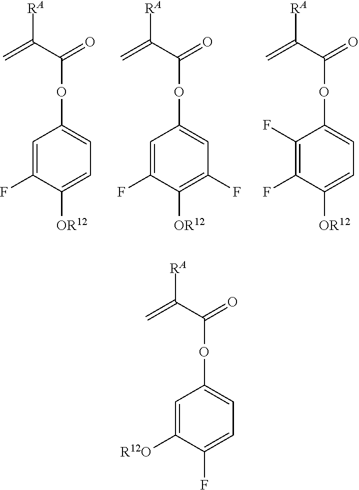

Various acid labile groups are selected as the acid labile group represented by R¹¹ or R¹². Examples thereof include those represented by the following formulae (AL-1) to (AL-3).

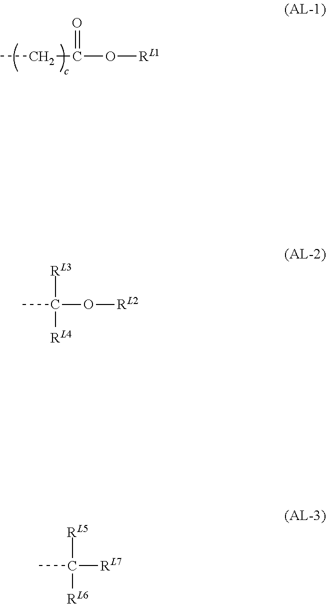

In the formula (AL-1), “c” represents an integer of 0 to 6. R^{L1} represents a tertiary hydrocarbyl group having 4 to 20 carbon atoms, preferably 4 to 15 carbon atoms, a trihydrocarbylsilyl group in which each hydrocarbyl group is a saturated hydrocarbyl group having 1 to 6 carbon atoms, a saturated hydrocarbyl group having 4 to 20 carbon atoms and containing a carbonyl group, an ether bond, or an ester bond, or the group represented by the formula (AL-3).

The tertiary hydrocarbyl group represented by R^{L1} may be saturated or unsaturated, and may be branched or cyclic. Specific examples thereof include tert-butyl group, tert-pentyl group, 1,1-diethylpropyl group, 1-ethylcyclopentyl group, 1-butylcyclopentyl group, 1-ethylcyclohexyl group, 1-butylcyclohexyl group, 1-ethyl-2-cyclopentenyl group, 1-ethyl-2-cyclohexenyl group, 2-methyl-2-adamantyl group, and the like. Examples of the trihydrocarbylsilyl group (trialkylsilyl group) include trimethylsilyl group, triethylsilyl group, dimethyl-tert-butylsilyl group, and the like. The saturated hydrocarbyl group containing a carbonyl group, an ether bond, or an ester bond may be linear, branched, or cyclic, and is preferably cyclic. Specific examples thereof include 3-oxocyclohexyl group, 4-methyl-2-oxooxan-4-yl group, 5-methyl-2-oxooxolan-5-yl group, 2-tetrahydropyranyl group, 2-tetrahydrofuranyl group, and the like.

Examples of the acid labile group represented by the formula (AL-1) include tert-butoxycarbonyl group, tert-butoxycarbonylmethyl group, tert-pentyloxycarbonyl group, tert-pentyloxycarbonylmethyl group, 1,1-diethylpropyloxycarbonyl group, 1,1-diethylpropyloxycarbonylmethyl group, 1-ethylcyclopentyloxycarbonyl group, 1-ethylcyclopentyloxycarbonylmethyl group, 1-ethyl-2-cyclopentenyloxycarbonyl group, 1-ethyl-2-cyclopentenyloxycarbonylmethyl group, 1-ethoxyethoxycarbonylmethyl group, 2-tetrahydropyranyloxycarbonylmethyl group, 2-tetrahydrofuranyloxycarbonylmethyl group, and the like.

Further examples of the acid labile group represented by the formula (AL-1) include groups represented by the following formulae (AL-1)-1 to (AL-1)-10,

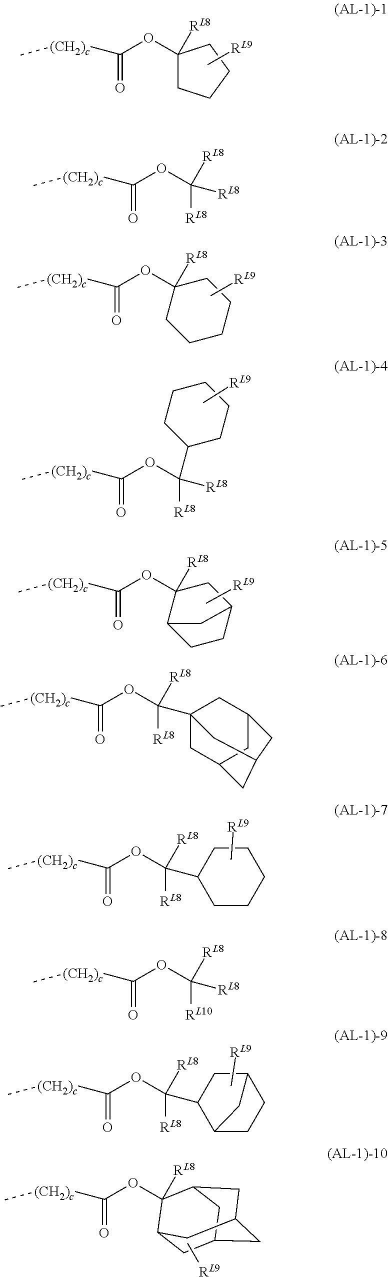

wherein the dashed line represents an attachment point.

In the formulae (AL-1)-1 to (AL-1)-10, “c” is as defined above. R^{L8} each independently represents a saturated hydrocarbyl group having 1 to 10 carbon atoms or an aryl group having 6 to 20 carbon atoms. R^{L9} represents a hydrogen atom or a saturated hydrocarbyl group having 1 to 10 carbon atoms. R^{L10} represents a saturated hydrocarbyl group having 2 to 10 carbon atoms or an aryl group having 6 to 20 carbon atoms. The saturated hydrocarbyl group may be linear, branched, or cyclic.

In the formula (AL-2), each of R^{L2} and R^{L3} independently represents a hydrogen atom or a saturated hydrocarbyl group having 1 to 18 carbon atoms, preferably 1 to 10 carbon atoms. The saturated hydrocarbyl group may be linear, branched, or cyclic, and specific examples thereof include methyl group, ethyl group, propyl group, isopropyl group, n-butyl group, sec-butyl group, tert-butyl group, cyclopentyl group, cyclohexyl group, 2-ethylhexyl group, n-octyl group, and the like.

In the formula (AL-2), R^{L4} represents a hydrocarbyl group having 1 to 18 carbon atoms, preferably 1 to 10 carbon atoms and optionally having a heteroatom. The hydrocarbyl group may be saturated or unsaturated, and may be linear, branched, or cyclic. Examples of the hydrocarbyl group include a saturated hydrocarbyl group having 1 to 18 carbon atoms and the like, where some of hydrogen atoms thereof may be substituted with a hydroxy group, an alkoxy group, an oxo group, an amino group, an alkylamino group, or the like. Such substituted saturated hydrocarbyl group includes those shown below, etc.,

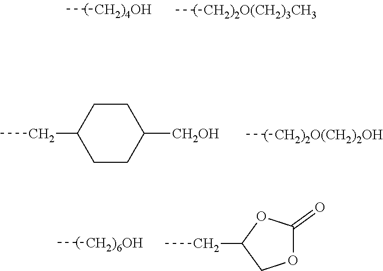

wherein the dashed line represents an attachment point.

R^{L2} and R^{L3}, R^{L2} and R^{L4}, or R^{L3} and R^{L4} optionally bond together to form a ring with a carbon atom or with the carbon atom and an oxygen atom attached thereto. In this case, R^{L2} and R^{L3}, R^{L2} and R^{L4}, or R^{L3} and R^{L4} involved in the ring formation each independently represents an alkanediyl group having 1 to 18 carbon atoms, preferably 1 to 10 carbon atoms. The number of carbon atoms in the ring obtained by bonding them is preferably 3 to 10, more preferably 4 to 10.

As the acid labile group represented by the formula (AL-2), the linear or branched ones include those represented by the following formulae (AL-2)-1 to (AL-2)-69, but are not limited thereto. Note that in the following formulae, the dashed line represents an attachment point.

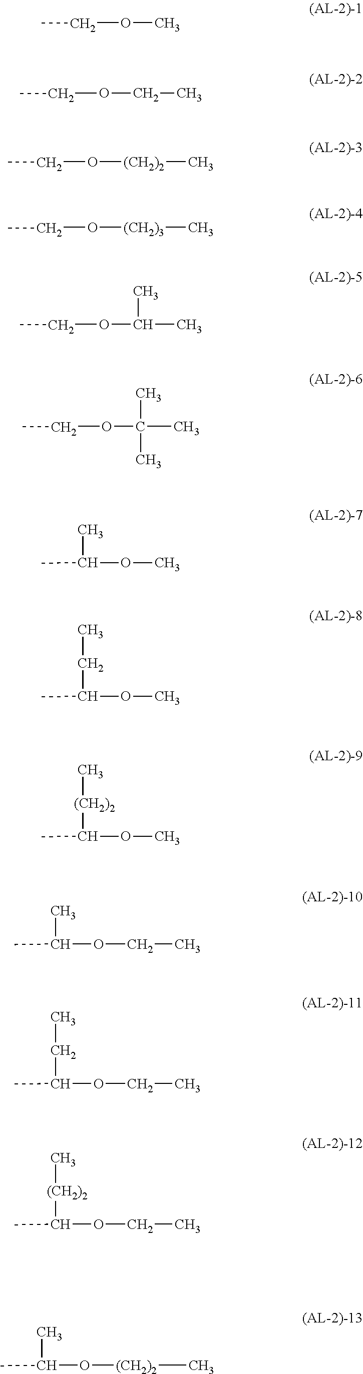

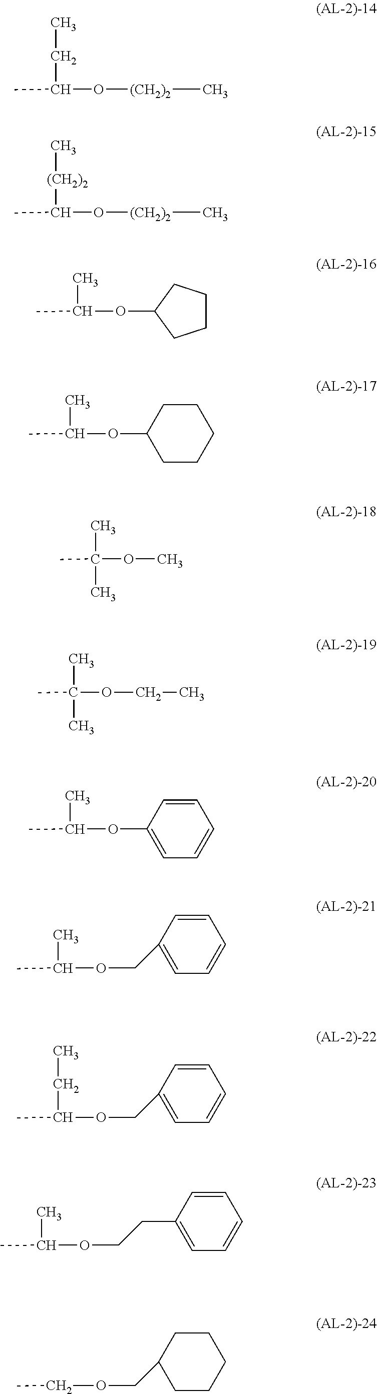

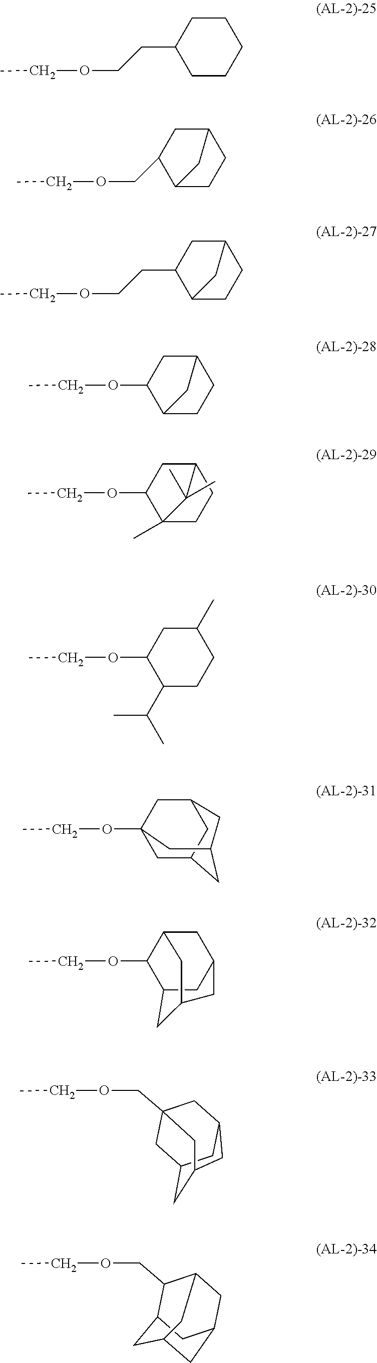

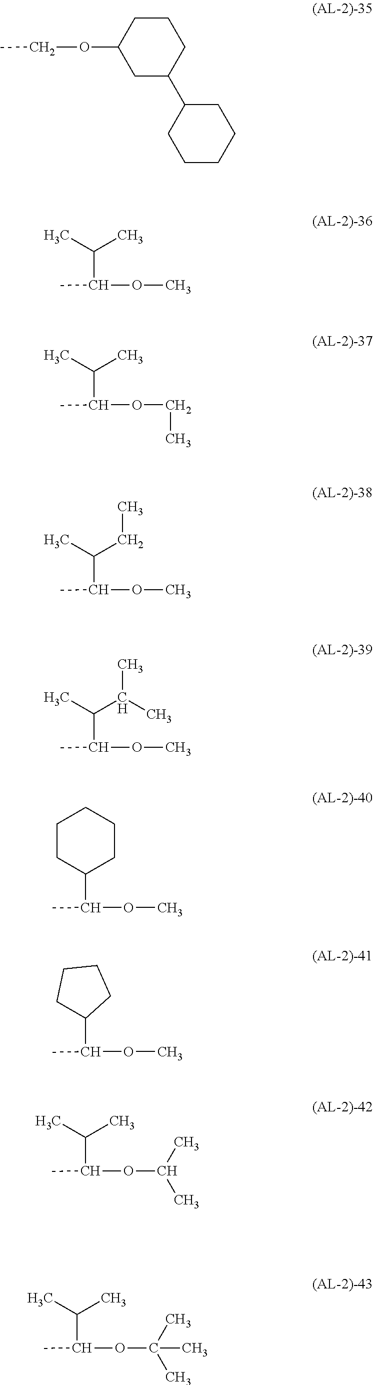

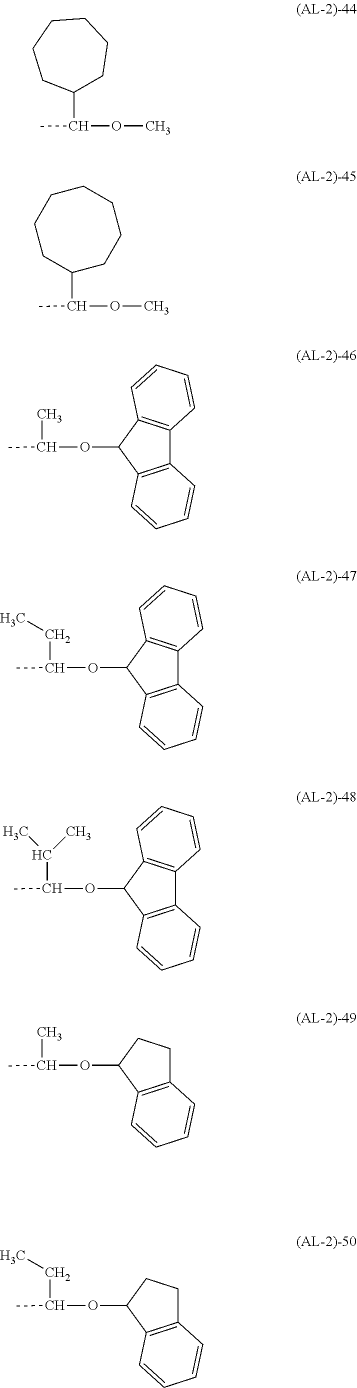

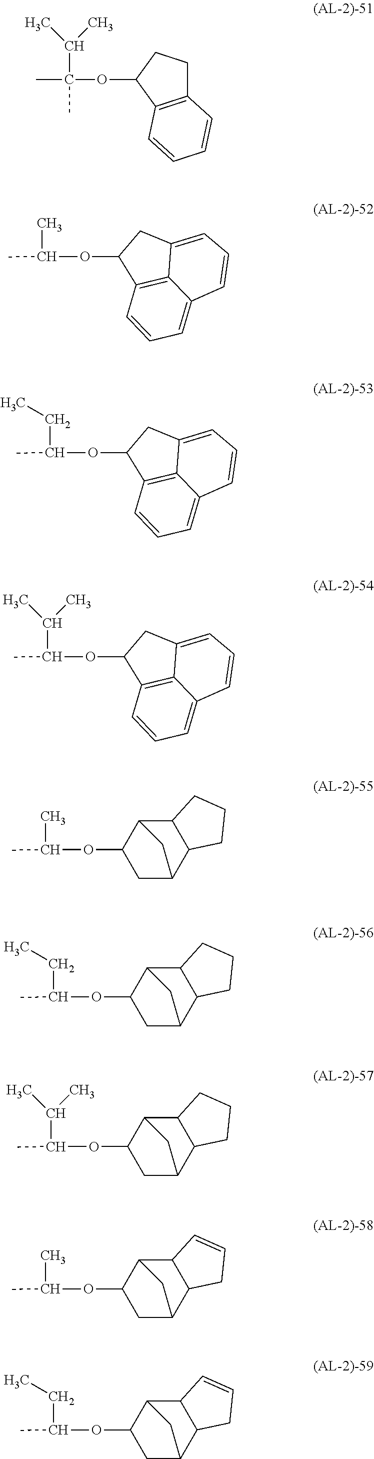

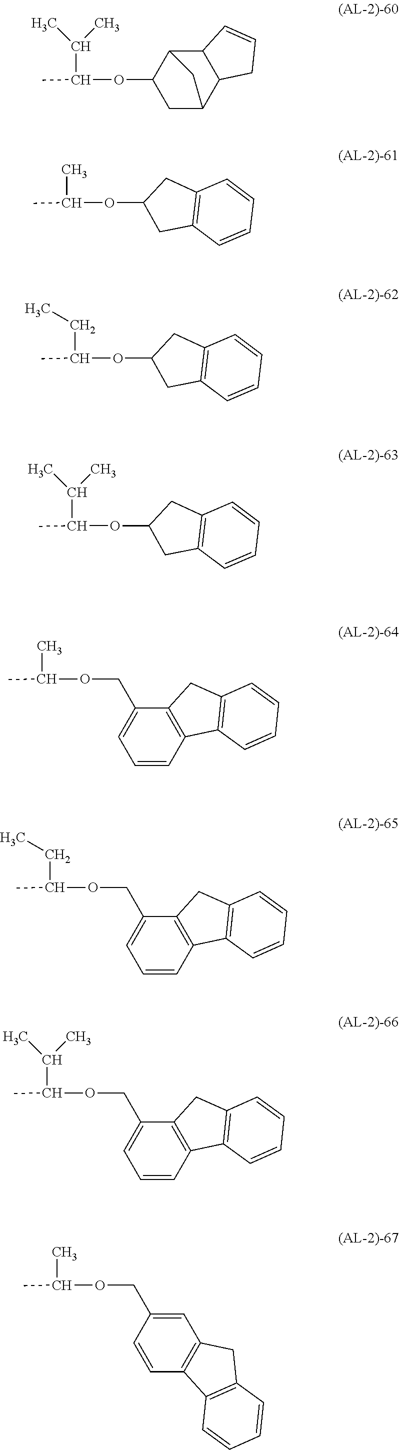

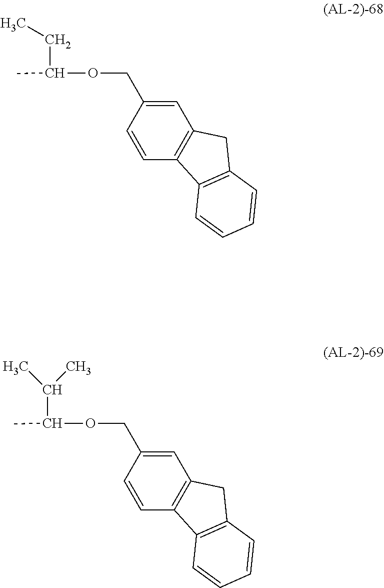 [SMILES: CC[C@@H](C)OCc1ccc2c(c1)Cc1ccccc1-2 ; CC(C)[C@@H](C)OCc1ccc2c(c1)Cc1ccccc1-2]

As the acid labile group represented by the formula (AL-2), examples of the cyclic ones include tetrahydrofuran-2-yl group, 2-methyltetrahydrofuran-2-yl group, tetrahydropyran-2-yl group, 2-methyltetrahydropyran-2-yl group, and the like.

Further examples of the acid labile group include groups represented by the following formulae (AL-2a) and (AL-2b). The base polymer may be intermolecularly or intramolecularly crosslinked by the acid labile group.

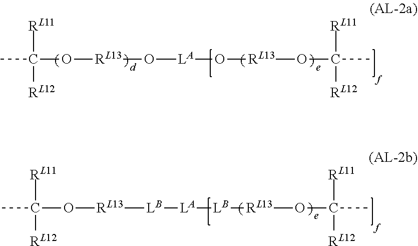

In the formulae, the dashed line represents an attachment point.

In the formula (AL-2a) or (AL-2b), each of R^{L11} and R^{L12} independently represents a hydrogen atom or a saturated hydrocarbyl group having 1 to 8 carbon atoms. The saturated hydrocarbyl group may be linear, branched, or cyclic. Furthermore, R^{L11} and R^{L12} optionally bond together to form a ring with a carbon atom attached thereto. In this case, each of R^{L11} and R^{L12} independently represents an alkanediyl group having 1 to 8 carbon atoms. R^{L13} each independently represents a saturated hydrocarbylene group having 1 to 10 carbon atoms. The saturated hydrocarbylene group may be linear, branched, or cyclic. Each of “d” and “e” independently represents an integer of 0 to 10, preferably an integer of 0 to 5, and “f” represents an integer of 1 to 7, preferably an integer of 1 to 3.

In the formula (AL-2a) or (AL-2b), L^{A} represents a (f+1)-valent aliphatic saturated hydrocarbon group having 1 to 50 carbon atoms, a (f+1)-valent alicyclic saturated hydrocarbon group having 3 to 50 carbon atoms, a (f+1)-valent aromatic hydrocarbon group having 6 to 50 carbon atoms, or a (f+1)-valent heterocyclic group having 3 to 50 carbon atoms. Furthermore, some of carbon atoms of these groups may be substituted with a heteroatom-containing group, and some of hydrogen atoms attached to the carbon atoms of these groups may be substituted with a hydroxy group, a carboxy group, an acyl group, or a fluorine atom. L^{A} is preferably a saturated hydrocarbylene group having 1 to 20 carbon atoms, a saturated hydrocarbon group such as a trivalent saturated hydrocarbon group and a tetravalent saturated hydrocarbon group, an arylene group having 6 to 30 carbon atoms, or the like. The saturated hydrocarbon group may be linear, branched, or cyclic. L^{B} represents —C(═O)—O—, —NH—C(═O)—O—, or —NH—C(═O)—NH—.

Examples of the crosslinking acetal group represented by the formula (AL-2a) or (AL-2b) include groups such as those represented by the following formulae (AL-2)-70 to (AL-2)-77,

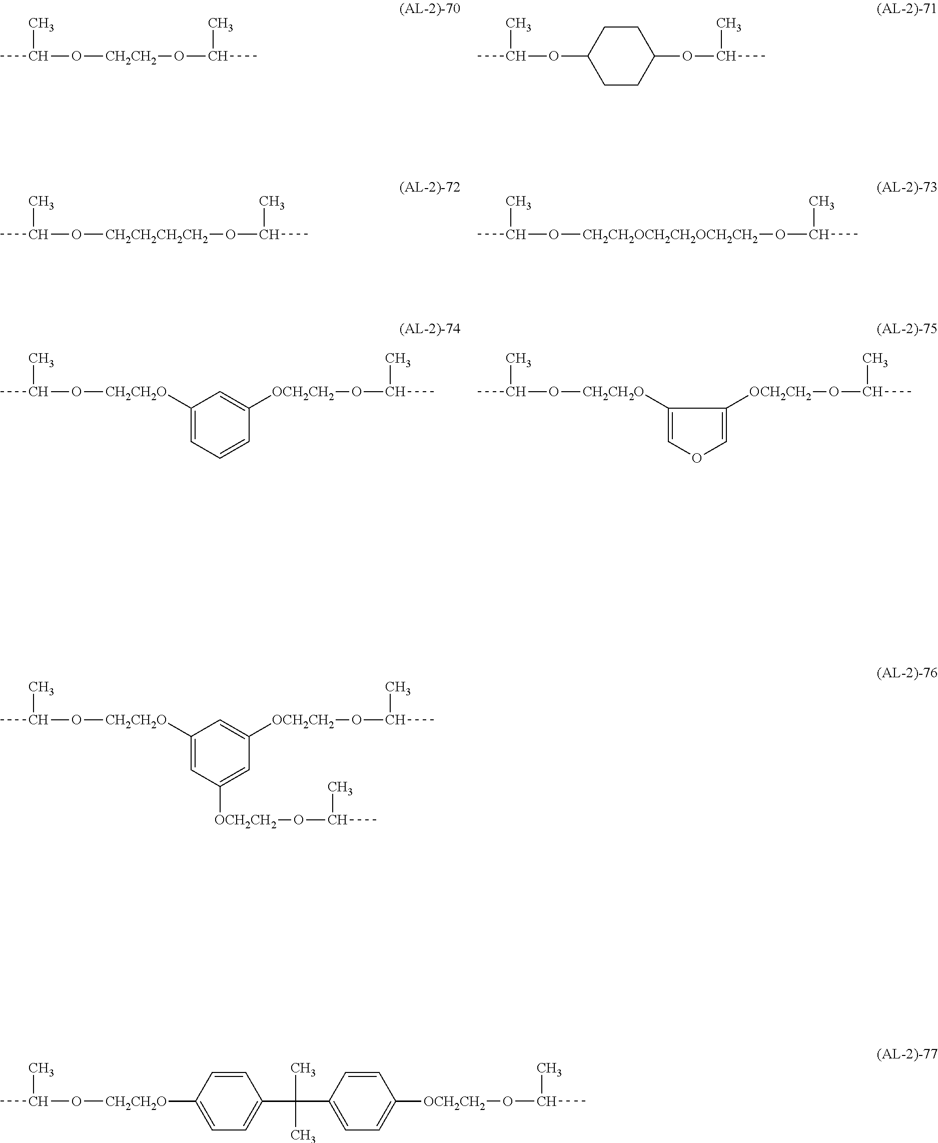

wherein the dashed line represents an attachment point.

In the formula (AL-3), each of R^{L5}, R^{L6}, and R^{L7} independently represents a hydrocarbyl group having 1 to 20 carbon atoms, optionally having a heteroatom such as an oxygen atom, a sulfur atom, a nitrogen atom, and a fluorine atom. The hydrocarbyl group may be saturated or unsaturated, and may be linear, branched, or cyclic. Specific Examples thereof include an alkyl group having 1 to 20 carbon atoms, a cyclic saturated hydrocarbyl group having 3 to 20 carbon atoms, an alkenyl group having 2 to 20 carbon atoms, a cyclic unsaturated hydrocarbyl group having 3 to 20 carbon atoms, an aryl group having 6 to 10 carbon atoms, and the like. Furthermore, R^{L5} and R^{L6}, R^{L5} and R^{L7}, or R^{L6} and R^{L7} optionally bond together to form an alicyclic ring having 3 to 20 carbon atoms with a carbon atom attached thereto.

Examples of the group represented by the formula (AL-3) include tert-butyl group, 1,1-diethylpropyl group, 1-ethylnorbornyl group, 1-methylcyclopentyl group, 1-isopropylcyclopentyl group, 1-ethylcyclopentyl group, 1-methylcyclohexyl group, 2-(2-methyl)adamantyl group, 2-(2-ethyl)adamantyl group, tert-pentyl group, and the like.

Additionally, the group represented by the formula (AL-3) also includes groups represented by the following formulae (AL-3)-1 to (AL-3)-19,

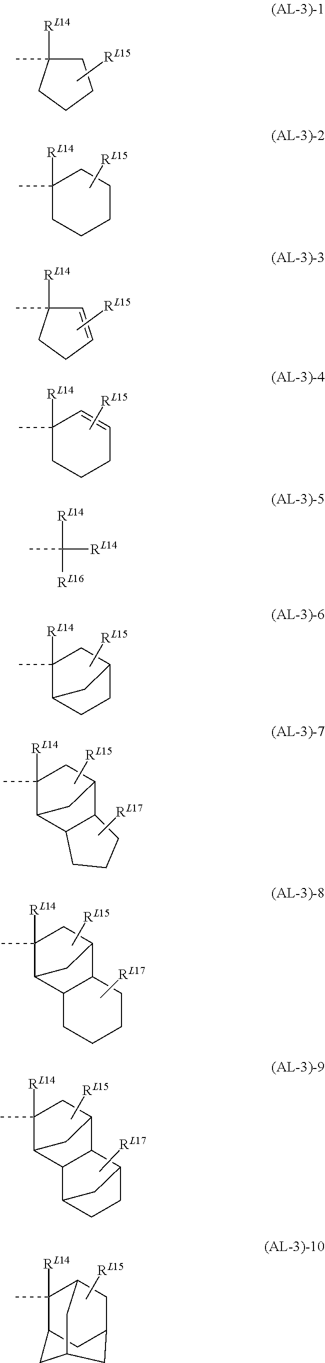

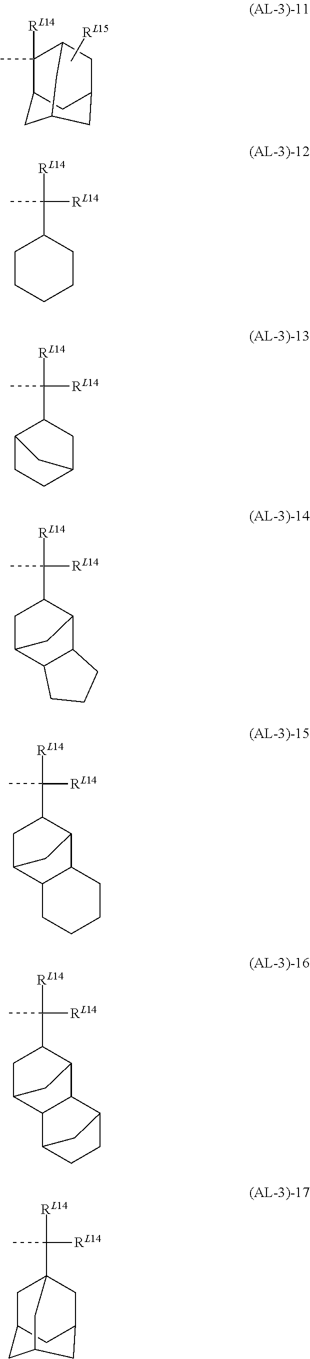

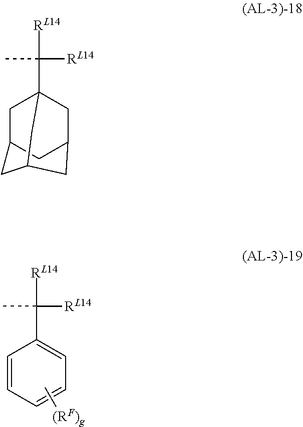

wherein the dashed line represents an attachment point.

In the formulae (AL-3)-1 to (AL-3)-19, R^{L14} each independently represents a hydrogen atom, a saturated hydrocarbyl group having 1 to 8 carbon atoms, or an aryl group having 6 to 20 carbon atoms. Each of R^{L15} and R^{L16} independently represents a hydrogen atom or a saturated hydrocarbyl group having 1 to 20 carbon atoms. R^{L16} represents an aryl group having 6 to 20 carbon atoms. The saturated hydrocarbyl group may be linear, branched, or cyclic. Furthermore, the aryl group is preferably a phenyl group or the like. R^{F} represents a fluorine atom or a trifluoromethyl group. “g” represents an integer of 1 to 5.

Further examples of the acid labile group include groups represented by the following formulae (AL-3)-20 and (AL-3)-21. The polymer may be intramolecularly or intermolecularly crosslinked by the acid labile group.

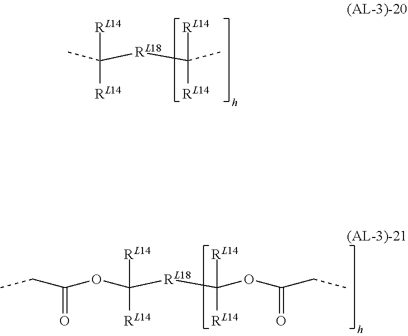

In the formulae, the dashed line represents an attachment point.

In the formulae (AL-3)-20 and (AL-3)-21, R^{L14} is as defined above. R^{L18} represents a (h+1)-valent saturated hydrocarbylene group having 1 to 20 carbon atoms or a (h+1)-valent arylene group having 6 to 20 carbon atoms, optionally containing a heteroatom such as an oxygen atom, a sulfur atom, and a nitrogen atom. The saturated hydrocarbylene group may be linear, branched, or cyclic. “h” represents an integer of 1 to 3.

Examples of a monomer from which the repeating unit containing the acid labile group represented by the formula (AL-3) is made include (meth)acrylate having an exo-form structure represented by the following formula (AL-3)-22.

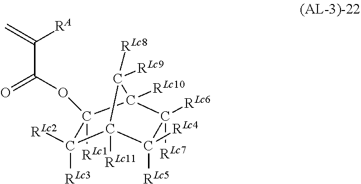

In the formula (AL-3)-22, R^{A} is as defined above. R^{Lc1} represents a saturated hydrocarbyl group having 1 to 8 carbon atoms or an optionally substituted aryl group having 6 to 20 carbon atoms. The saturated hydrocarbyl group may be linear, branched, or cyclic. Each of R^{Lc2} to R^{Lc11} independently represents a hydrogen atom or a hydrocarbyl group having 1 to 15 carbon atoms and optionally having a heteroatom. Examples of the heteroatom include an oxygen atom and the like. Examples of the hydrocarbyl group include an alkyl group having 1 to 15 carbon atoms, an aryl group having 6 to 15 carbon atoms, and the like. R^{Lc2} and R^{LC3}, R^{Lc4} and R^{Lc6}, R^{Lc4} and R^{Lc7}, R^{Lc5} and R^{Lc7}, R^{Lc5} and R^{Lc11}, R^{Lc6} and R^{Lc10}, R^{Lc8} and R^{Lc9}, or R^{Lc9} and R^{LC10} optionally bond together to form a ring with carbon atoms attached thereto. In this case, a group involved in the bonding is a hydrocarbylene group having 1 to 15 carbon atoms and optionally having a heteroatom. Furthermore, R^{Lc2} and R^{Lc11}, R^{Lc8} and R^{Lc11}, or R^{Lc4} and R^{Lc6}, all pairs of which are attached to carbon atoms adjacent to each other, may directly bond together to form a double bond. Note that the formula also represents an enantiomer.

Here, examples of the monomer represented by the formula (AL-3)-22, from which the repeating unit is made, are described in JP 2000-327633 A, etc. Specific examples thereof are shown below, but not limited thereto. Note that in the following formulae, R^{A} is as defined above.

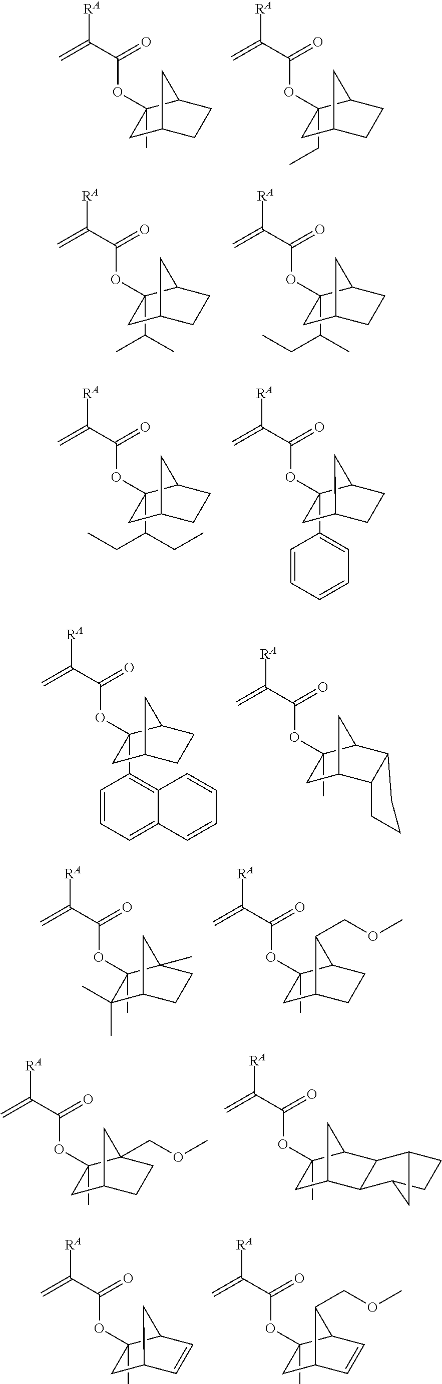

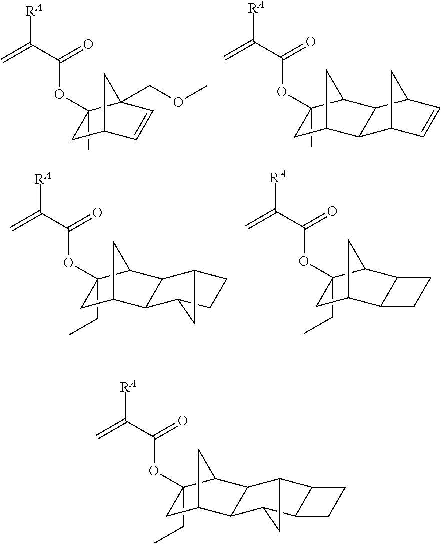

Examples of the monomer from which the repeating unit containing the acid labile group represented by the formula (AL-3) is made also include (meth)acrylate containing a furandiyl group, a tetrahydrofurandiyl group, or an oxanorbornanediyl group, represented by the following formula (AL-3)-23.

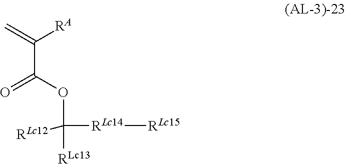

In the formula (AL-3)-23, R^{A} is as defined above. Each of R^{Lc12} and R^{Lc13} independently represents a hydrogen atom or a hydrocarbyl group having 1 to 10 carbon atoms. R^{Lc12} and R^{Lc13} optionally bond together to form an alicyclic ring with a carbon atom attached thereto. R^{Lc14} represents a furandiyl group, a tetrahydrofurandiyl group, or an oxanorbornanediyl group. R^{Lc15} represents a hydrogen atom or a hydrocarbyl group having 1 to 10 carbon atoms and optionally having a heteroatom. The hydrocarbyl group may be linear, branched, or cyclic. Specific examples thereof include a saturated hydrocarbyl group having 1 to 10 carbon atoms, and the like.

Examples of the monomer represented by the formula (AL-3)-23 from which the repeating unit is made are shown below, but not limited thereto. Note that in the following formulae, R^{A} is as defined above, Ac represents an acetyl group, and Me represents a methyl group.

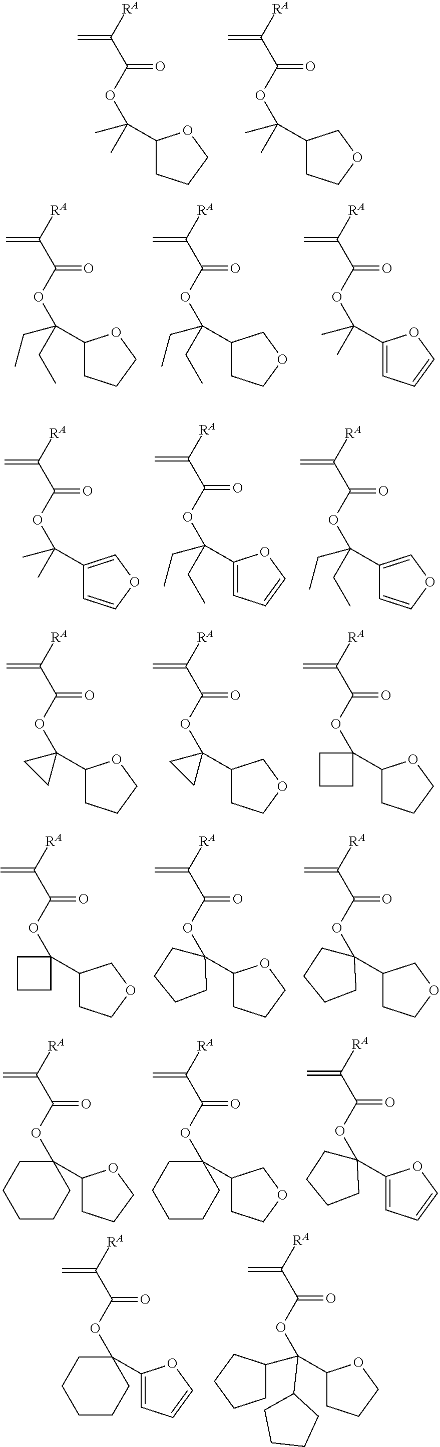

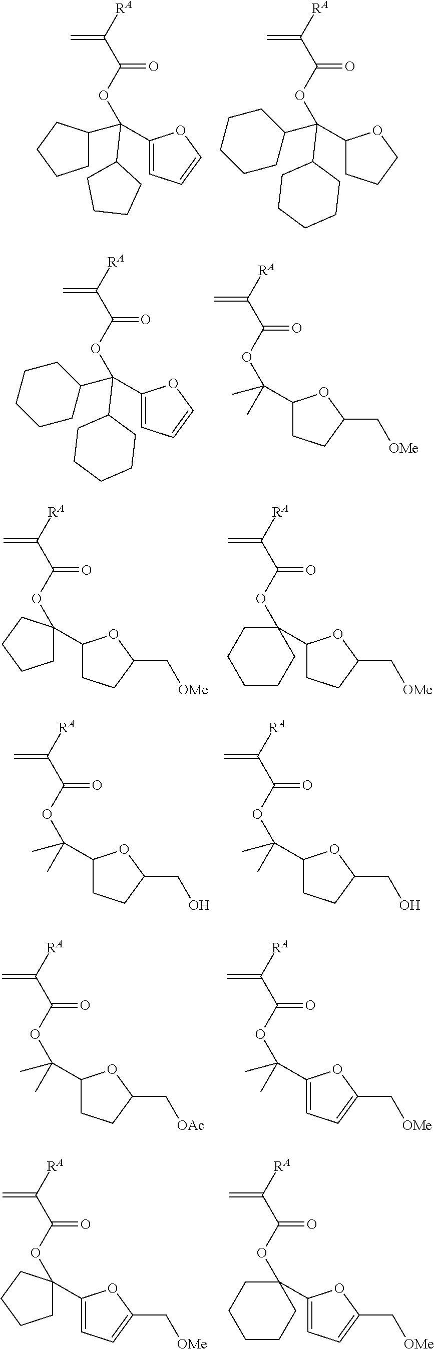

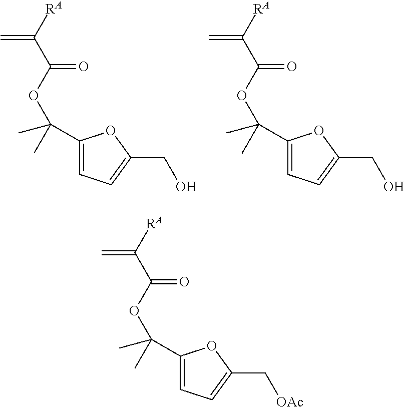

intentionally left blank

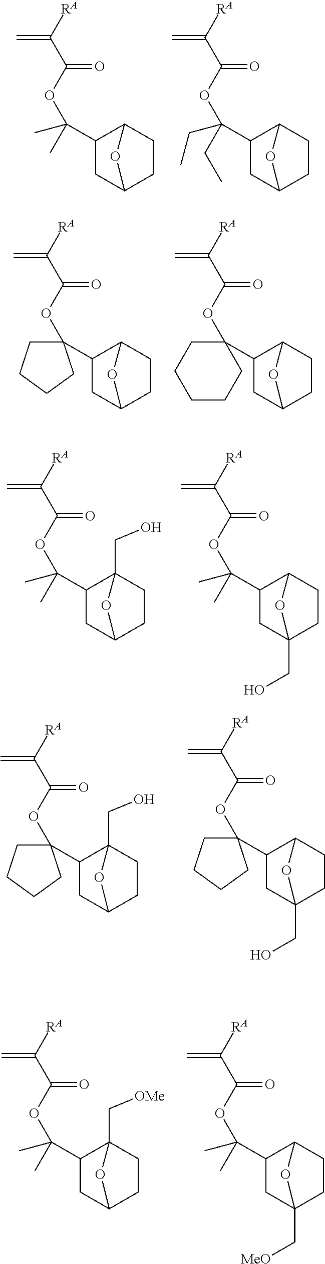

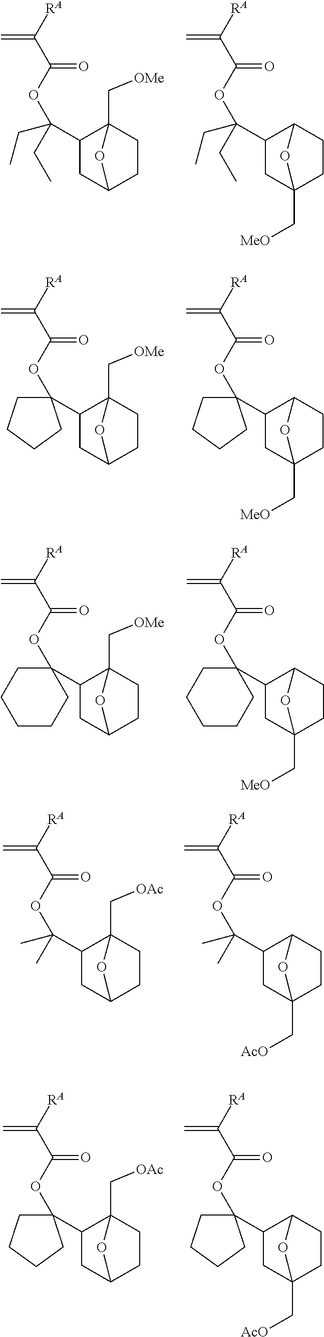

The base polymer may further contain a repeating unit (d) containing an adhesive group selected from a hydroxy group, a carboxy group, a lactone ring, a carbonate group, a thiocarbonate group, a carbonyl group, a cyclic acetal group, an ether bond, an ester bond, a sulfonic acid ester bond, a cyano group, an amide group, —O—C(═O)—S—, and —O—C(═O)—NH—.

Examples of a monomer from which the repeating unit (d) is made are shown below, but not limited thereto. Note that in the following formulae, R^{A} is as defined above.

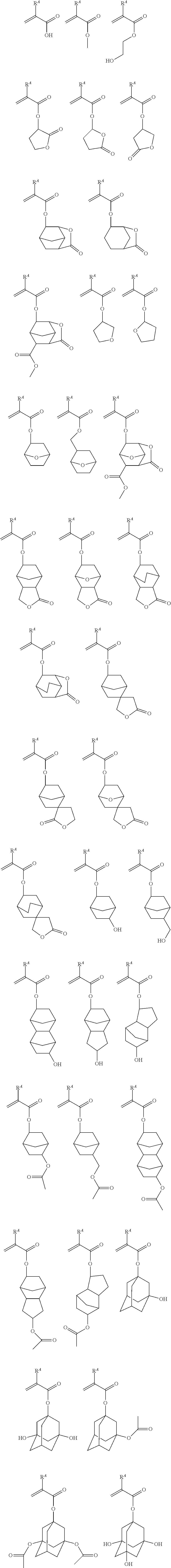

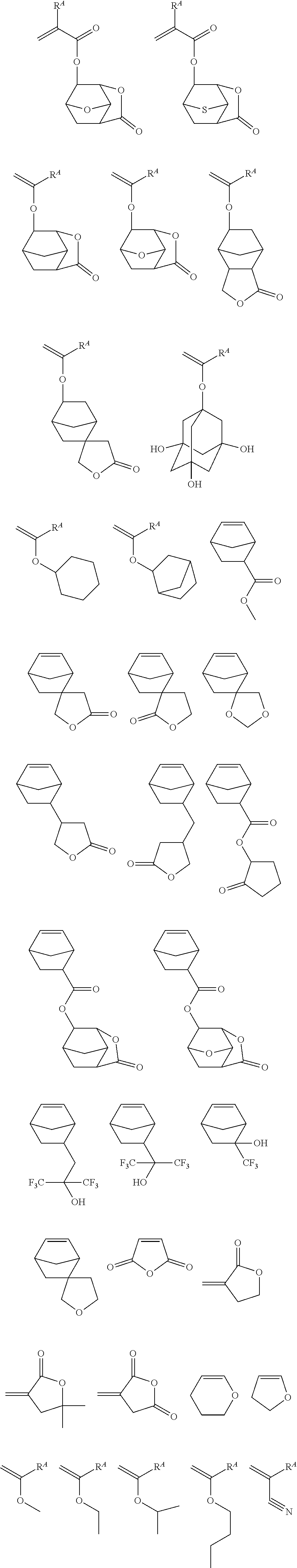

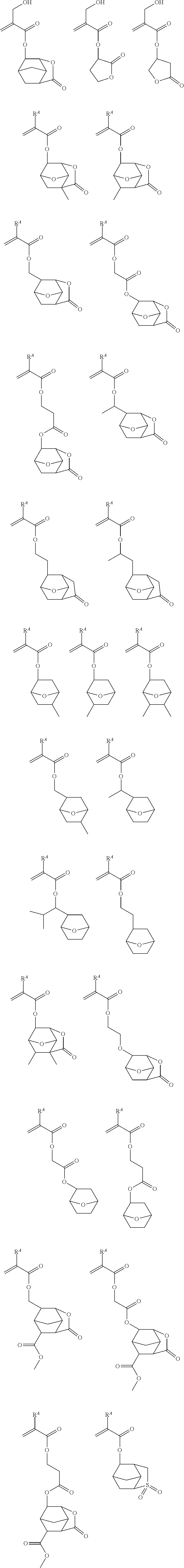

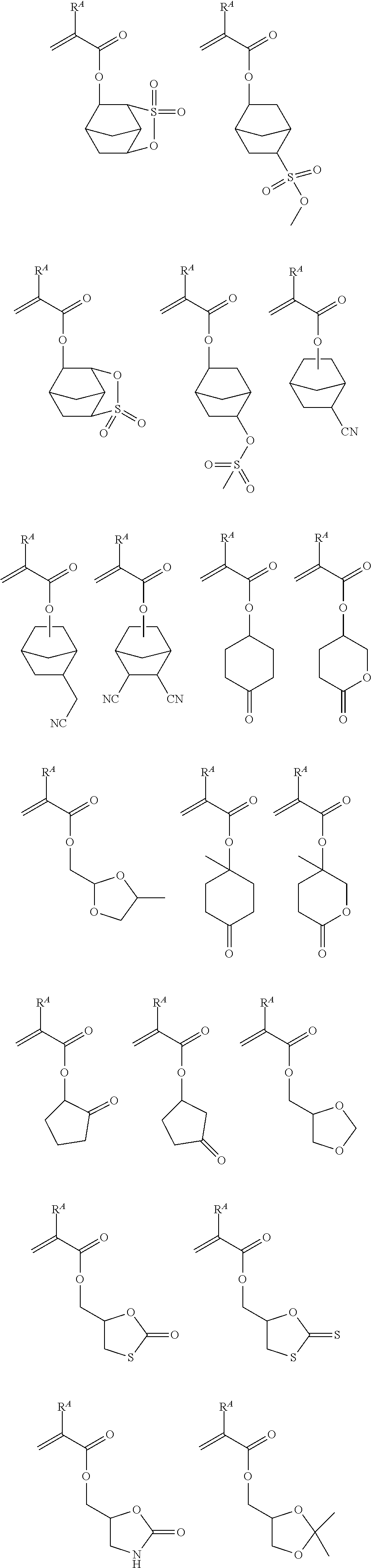

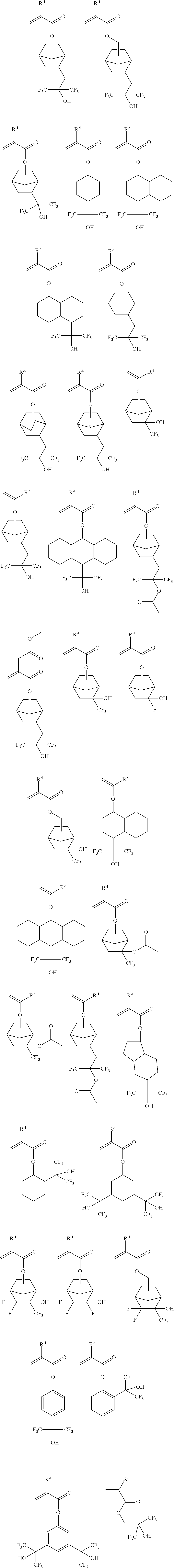

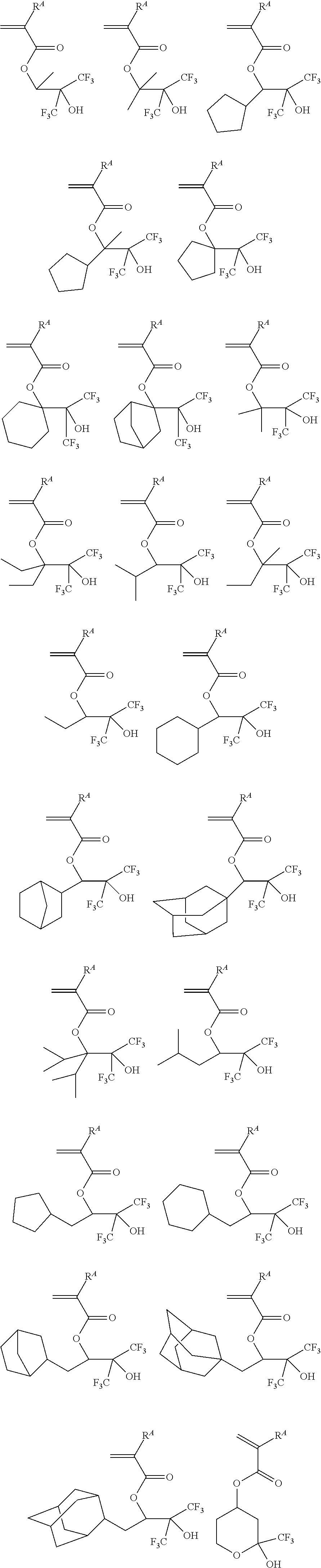

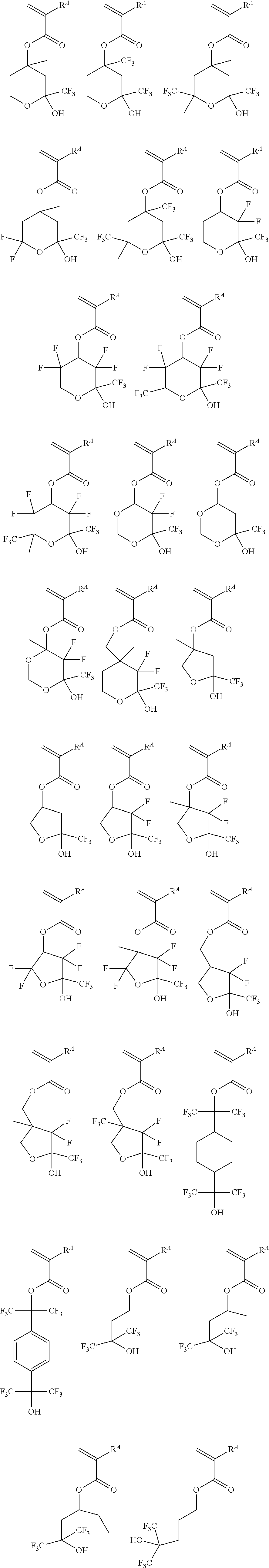

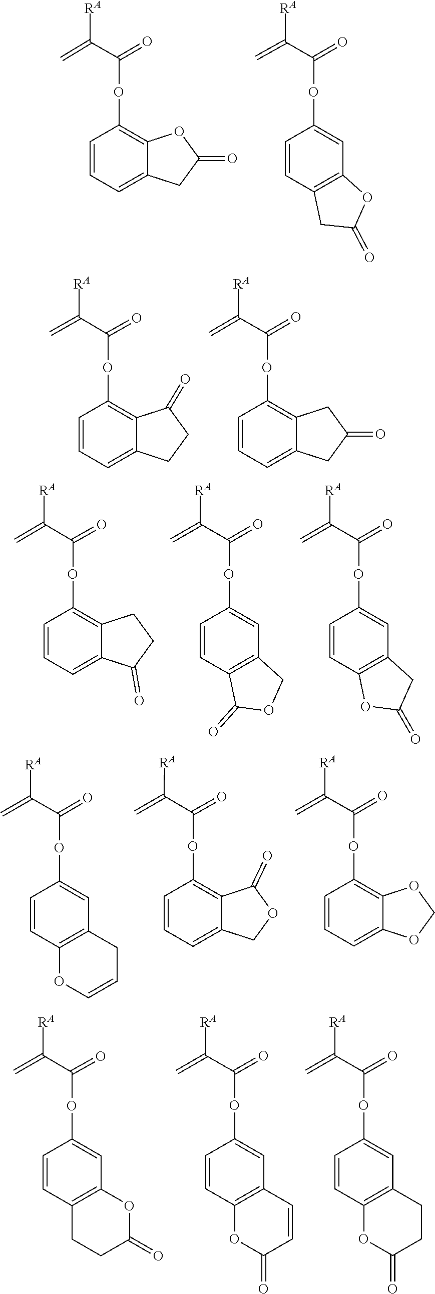

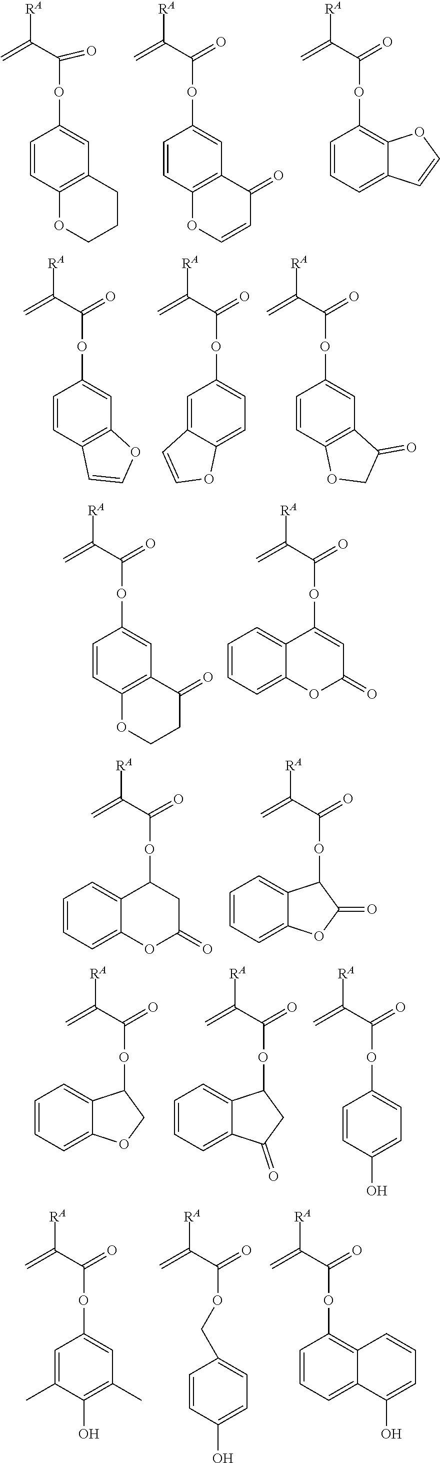

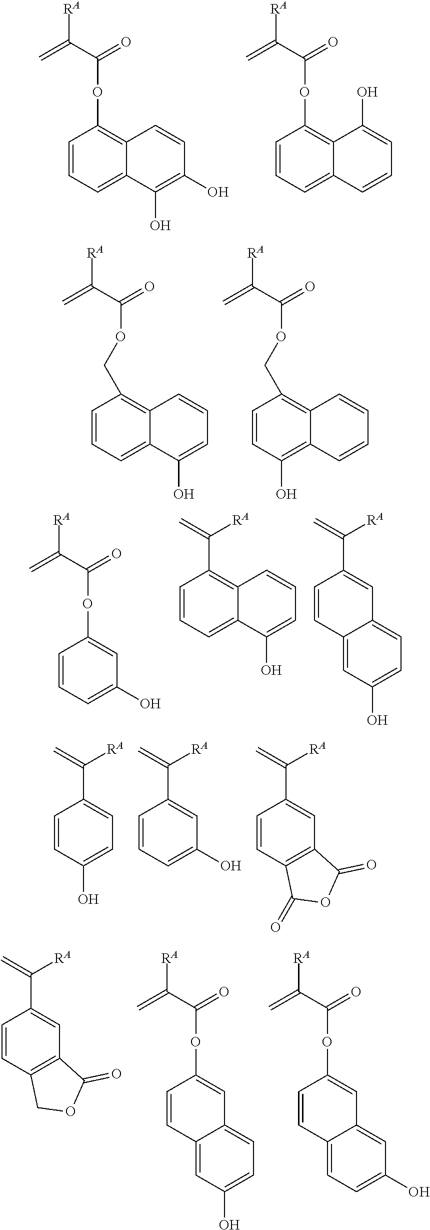

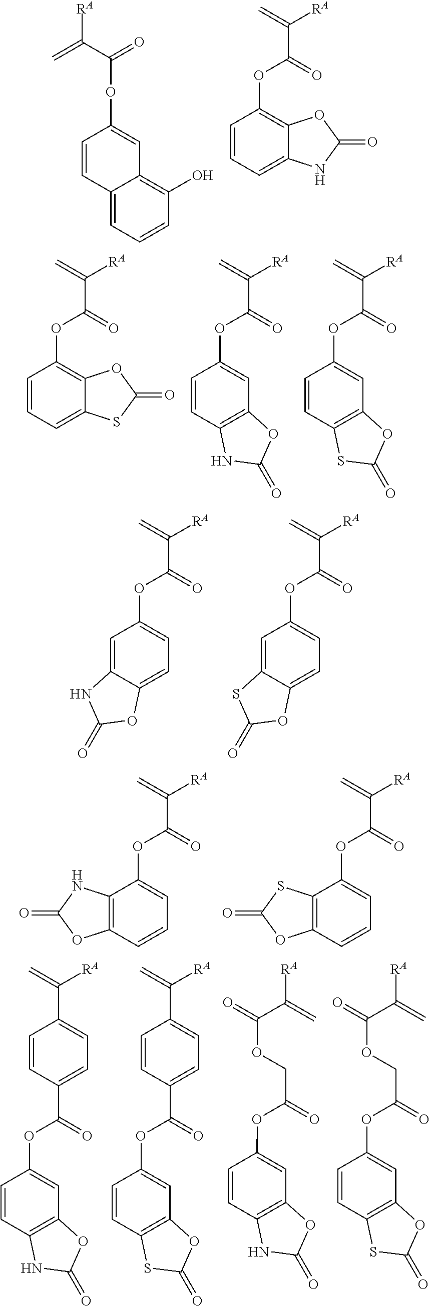

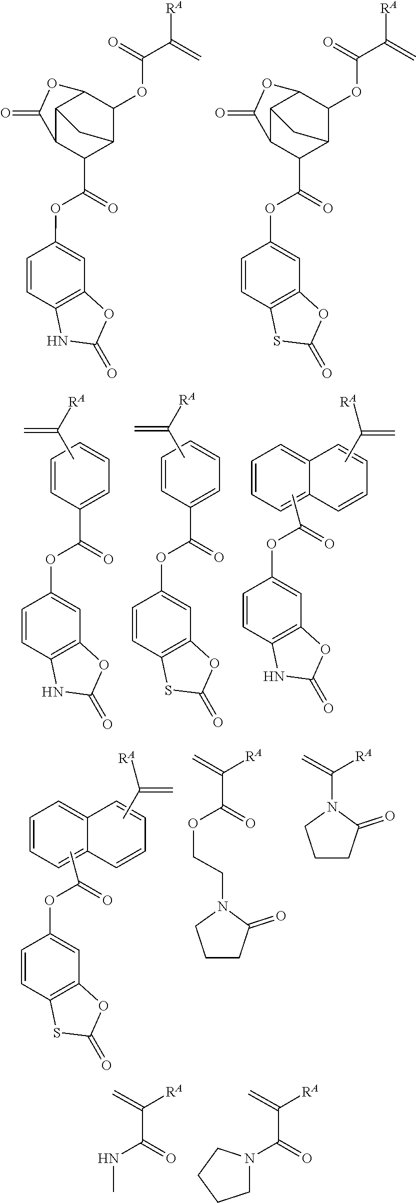

The base polymer can further contain a repeating unit (b) derived from an onium salt containing a polymerizable unsaturated bond. Preferred examples of the repeating unit (b) include a repeating unit represented by the following formula (b1) (hereinafter also referred to as the repeating unit (b1)), a repeating unit represented by the following formula (b2) (hereinafter also referred to as the repeating unit (b2)), a repeating unit represented by the following formula (b3) (hereinafter also referred to as the repeating unit (b3)), and a repeating unit represented by the following formula (b4) (hereinafter also referred to as the repeating unit (b4)). Note that the repeating units (b1) to (b4) can be used alone or in combination of two or more.

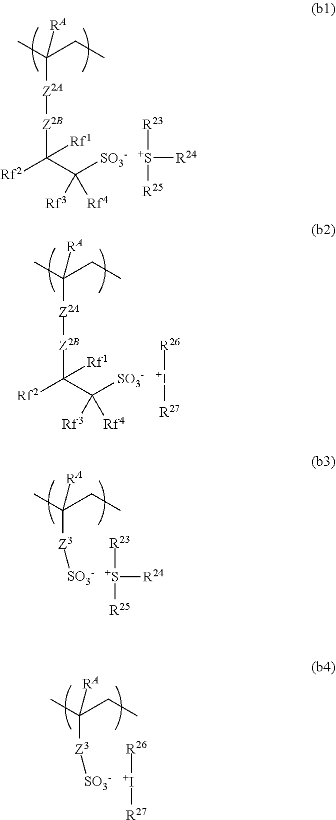

In the formulae (b1) to (b4), R^{A} each independently represents a hydrogen atom or a methyl group. Z^{2A} represents a single bond or an ester bond. Z^{2B} represents a single bond or a divalent group having 1 to 12 carbon atoms, optionally containing an ester bond, an ether bond, a lactone ring, a bromine atom, or an iodine atom. Z³ represents a single bond, a methylene group, an ethylene group, a phenylene group, a fluorinated phenylene group, —O—Z³¹—, —C(═O)—O—Z³¹—, or —C(═O)—NH—Z³¹—, wherein Z³¹ represents an alkanediyl group having 1 to 6 carbon atoms, an alkenediyl group having 2 to 6 carbon atoms, or a phenylene group, optionally containing a carbonyl group, an ester bond, an ether bond, a halogen atom, or a hydroxy group.

The Z^{2B} preferably contains one or more iodine atoms.

As described later, when an anion moiety of an acid generator attached to the polymer backbone contains an iodine atom, the increased number of photons to be absorbed enhances contrast in acid generation, thereby further improving edge roughness. The above effects can be exerted by using the base polymer having, in the polymer backbone, the repeating unit (b1) and/or (b2) containing one or more iodine atoms in the Z^{2B}, thereby achieving more enhanced sensitivity and more improved LWR and CDU.

In the formulae (b1) to (b2), each of R^{f1} to R^{f4} independently represents a hydrogen atom, a fluorine atom, or a trifluoromethyl group, provided that at least one of Rf¹ to Rf⁴ represents a fluorine atom. Particularly, at least one of R^{f3} and R^{f4} preferably represents a fluorine atom. More preferably, both of R^{f3} and R^{f4} represent a fluorine atom.

In the formulae (b1) to (b4), each of R²³ to R²⁷ independently represents a monovalent hydrocarbon group having 1 to 20 carbon atoms and optionally having a heteroatom. Furthermore, any two of R²³, R²⁴, and R²⁵ optionally bond together to form a ring with a sulfur atom attached thereto. The monovalent hydrocarbon group may be linear, branched, or cyclic, and specific examples thereof include an alkyl group having 1 to 12 carbon atoms, an aryl group having 6 to 12 carbon atoms, an aralkyl group having 7 to 20 carbon atoms, and the like. Furthermore, some or all of hydrogen atoms of these groups may be substituted with an alkyl group having 1 to 10 carbon atoms, a halogen atom, a trifluoromethyl group, a cyano group, a nitro group, a hydroxy group, a mercapto group, an alkoxy group having 1 to 10 carbon atoms, an alkoxycarbonyl group having 2 to 10 carbon atoms, or an acyloxy group having 2 to 10 carbon atoms, and some of carbon atoms of these groups may be substituted with a carbonyl group, an ether bond, or an ester bond.

In the formulae (b1) and (b3), specific examples of the sulfonium cation are the same as exemplified for the cation of the sulfonium salt represented by the above-described general formula (a)-1.

In the formulae (b2) and (b4), specific examples of the iodonium cation are the same as exemplified for the cation of the iodonium salt represented by the above-described general formula (a)-2.

Examples of a monomer from which the repeating unit (b1) is made are shown below, but not limited thereto. Note that in the following formulae, R^{A} is as defined above.

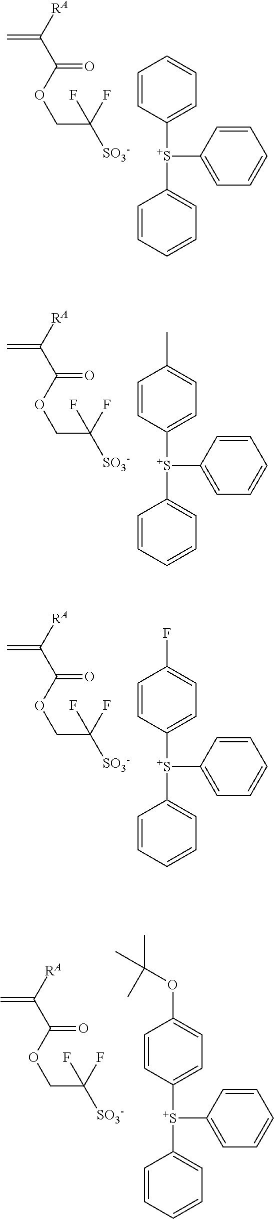

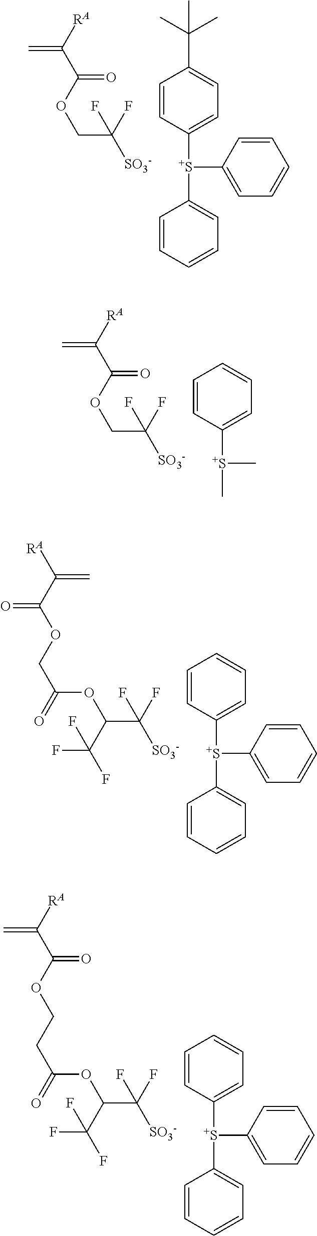

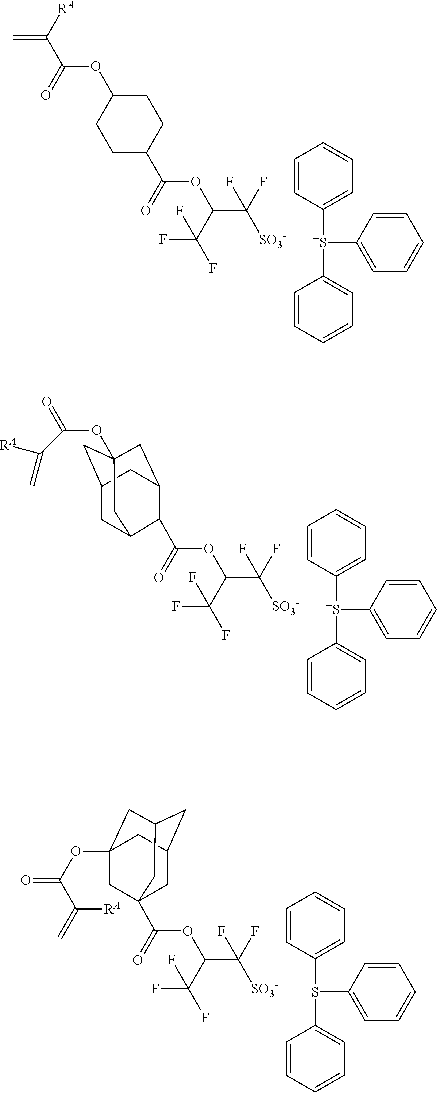

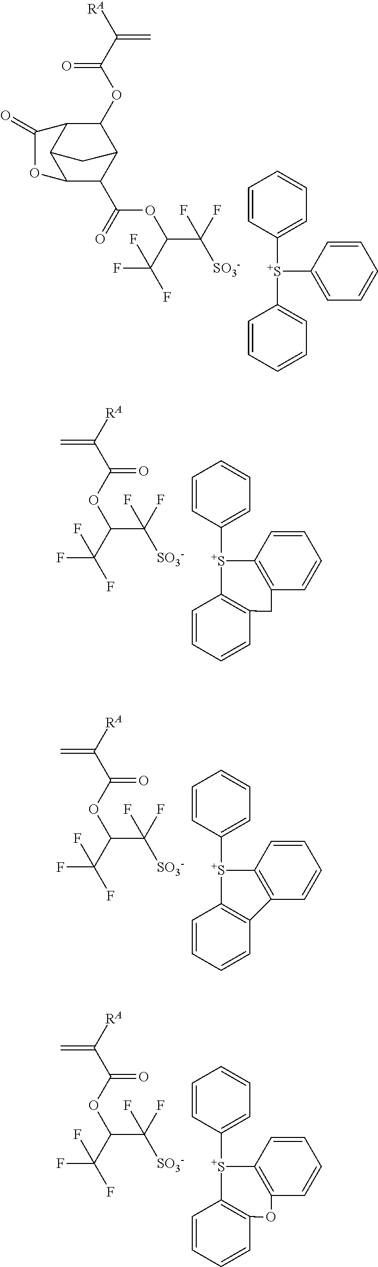

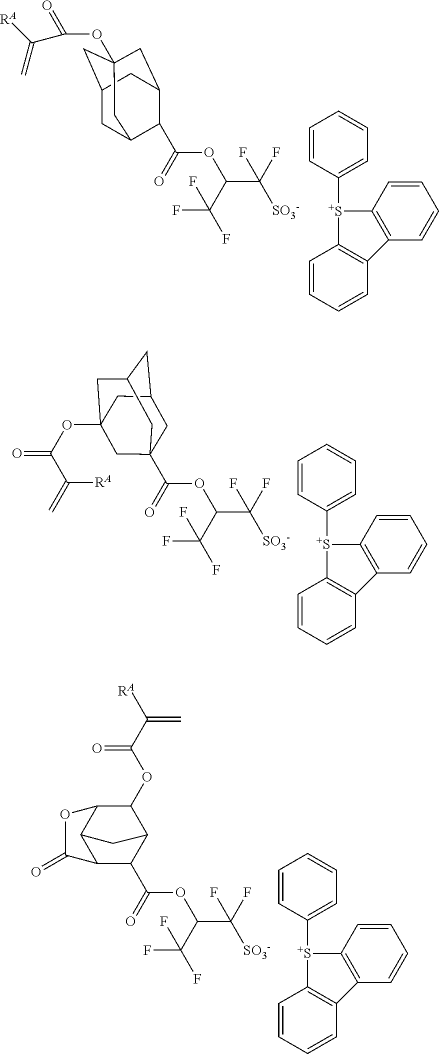

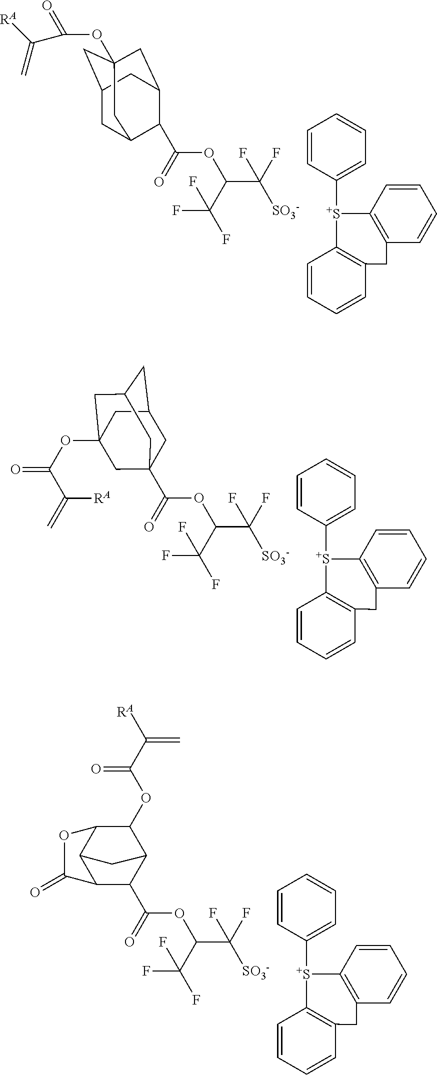

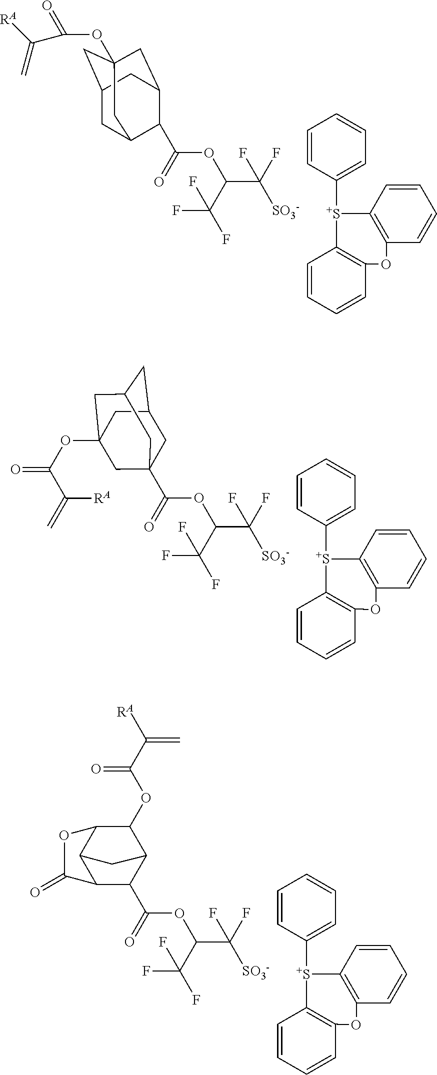

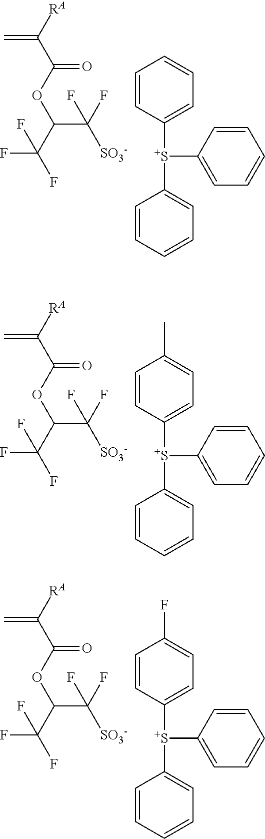

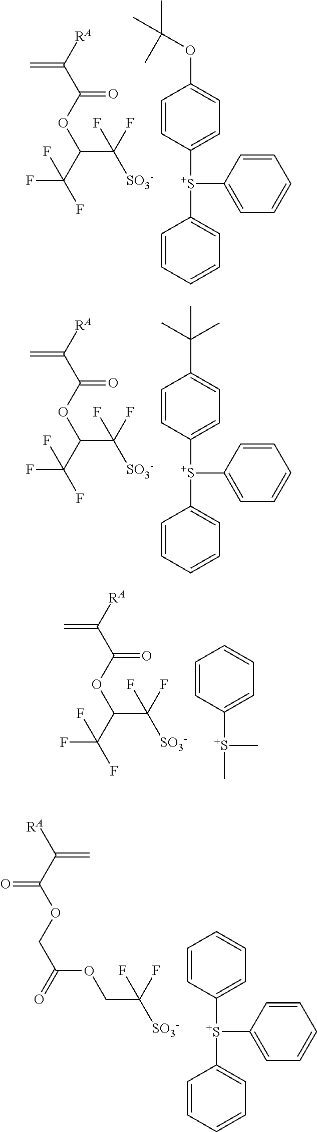

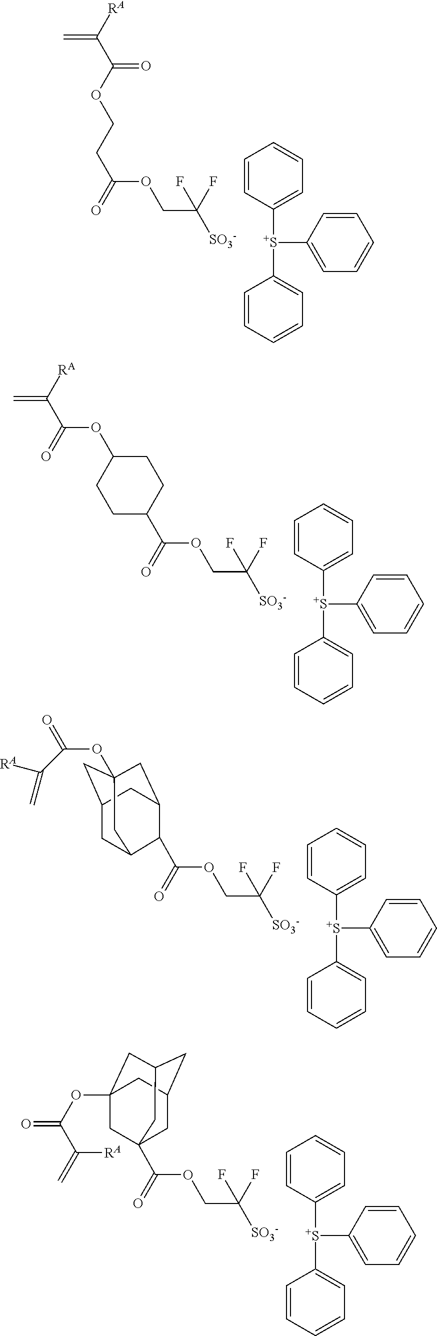

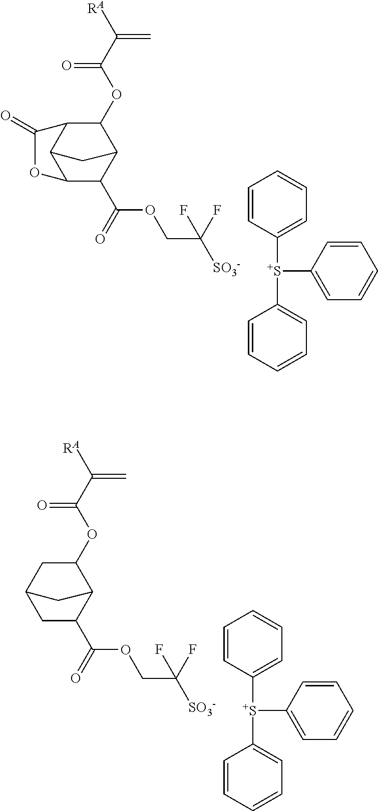

Examples of a monomer from which the repeating unit (b2) is made include, but are not limited to, those obtained by replacing the sulfonium cations of the monomers illustrated above with the iodonium cations as exemplified above.

Furthermore, preferred examples of the monomers from which the repeating units (b1) and (b2) are made also include those containing anions shown below. Note that in the following formulae, R^{A} is as defined above.

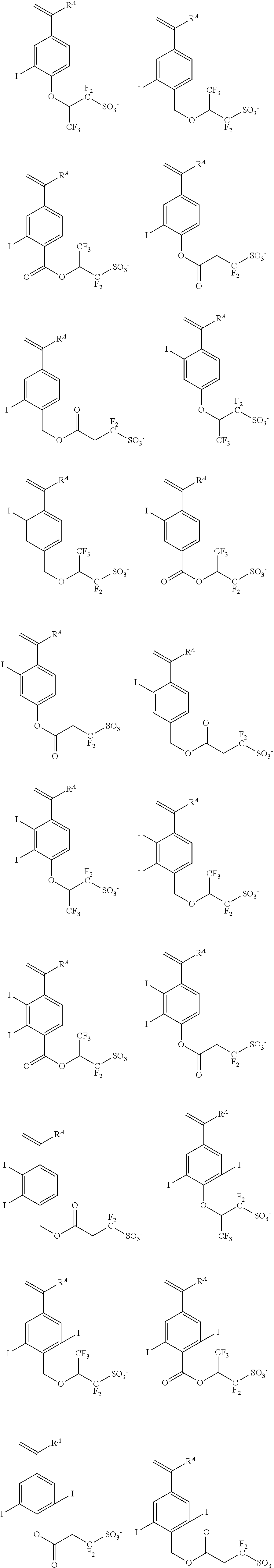

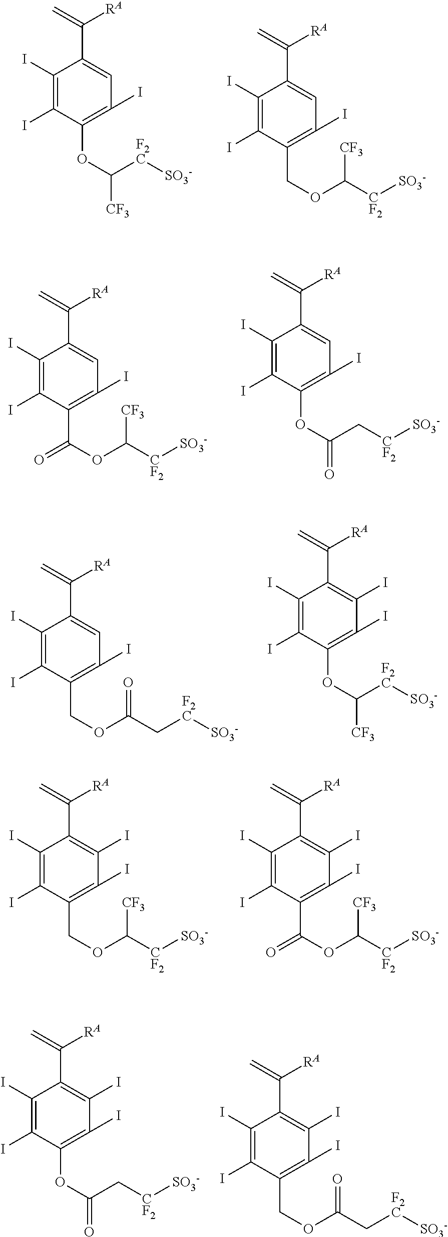

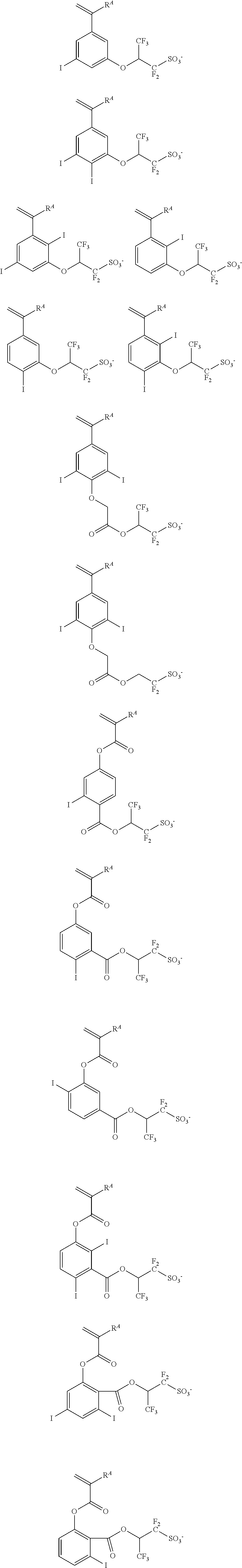

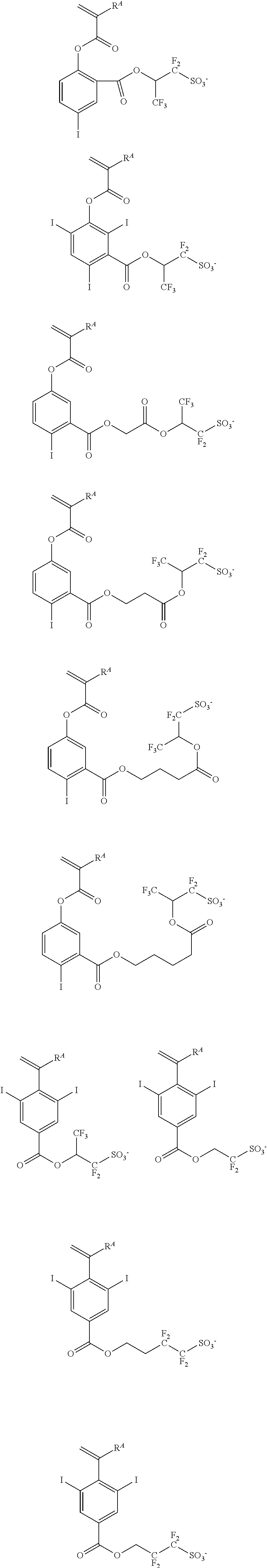

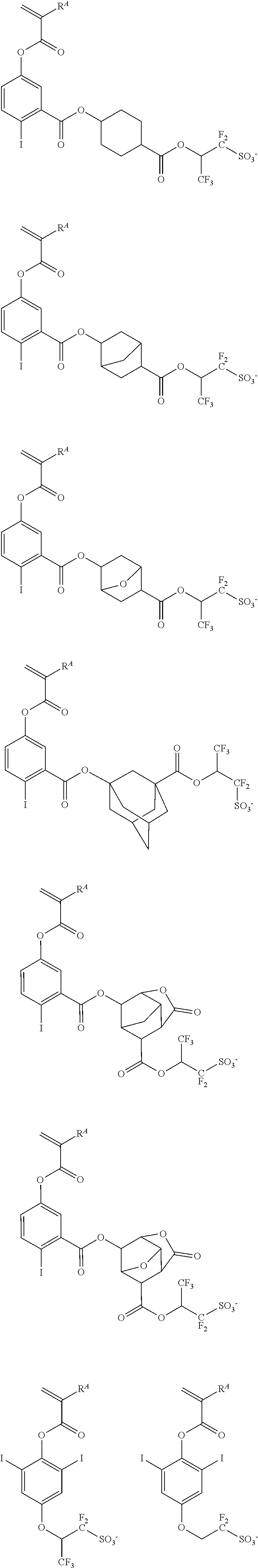

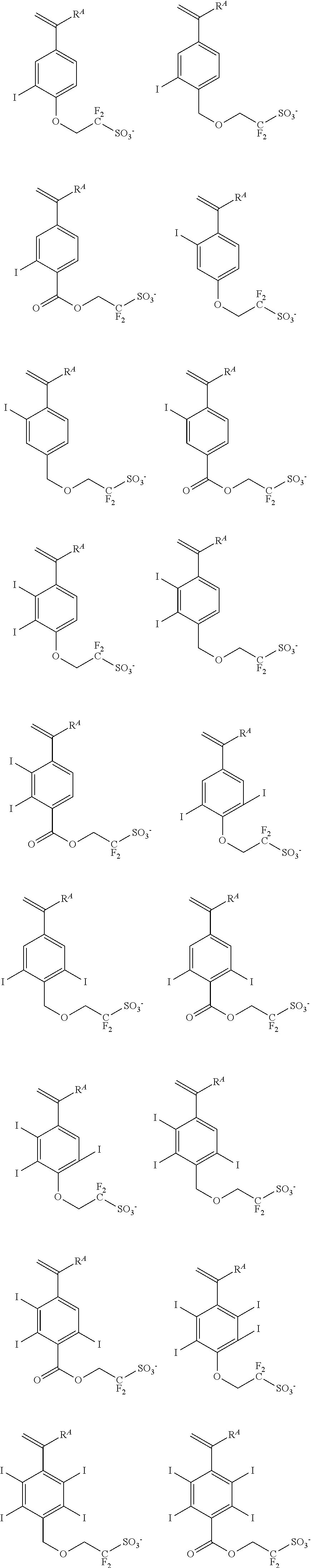

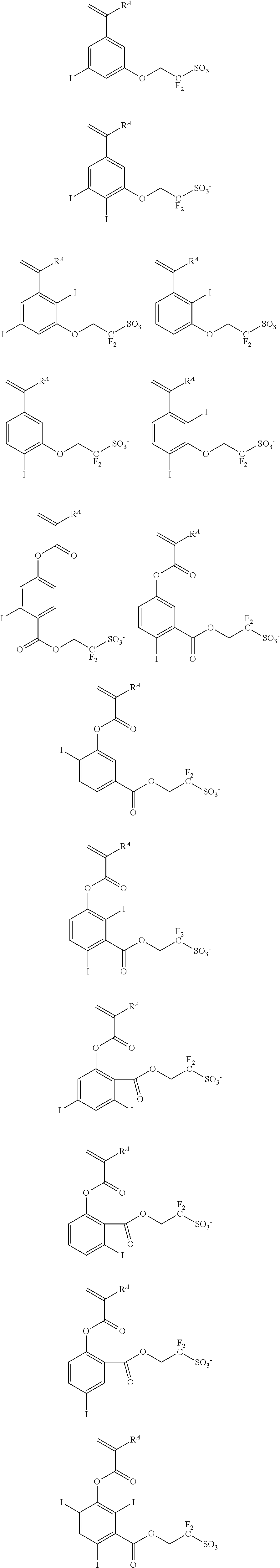

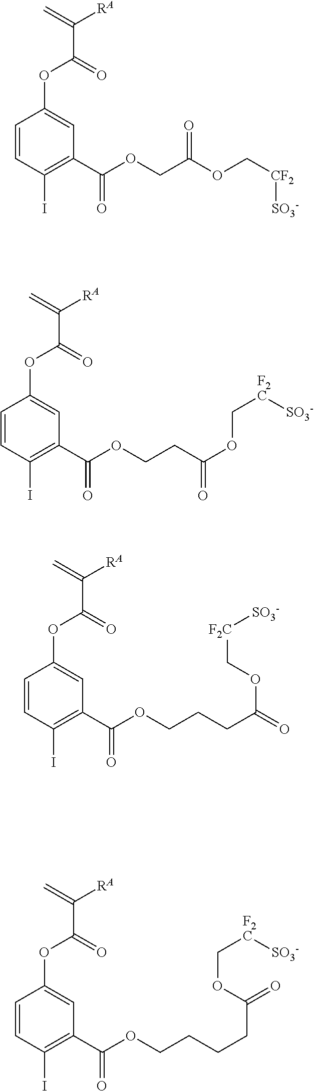

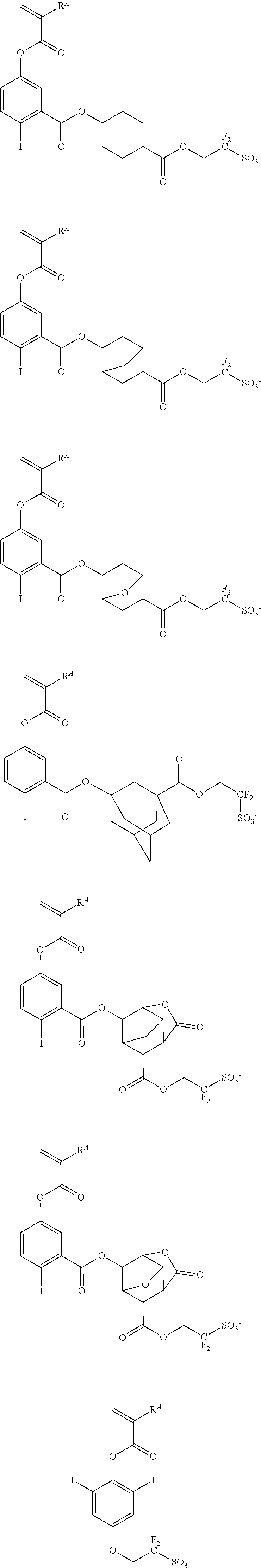

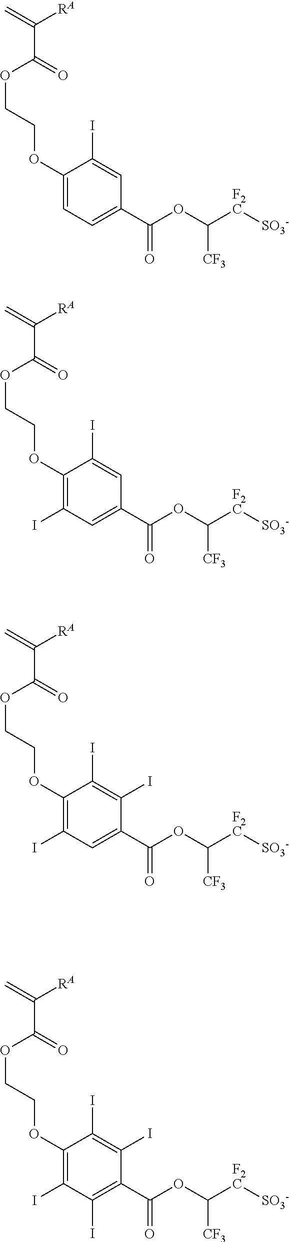

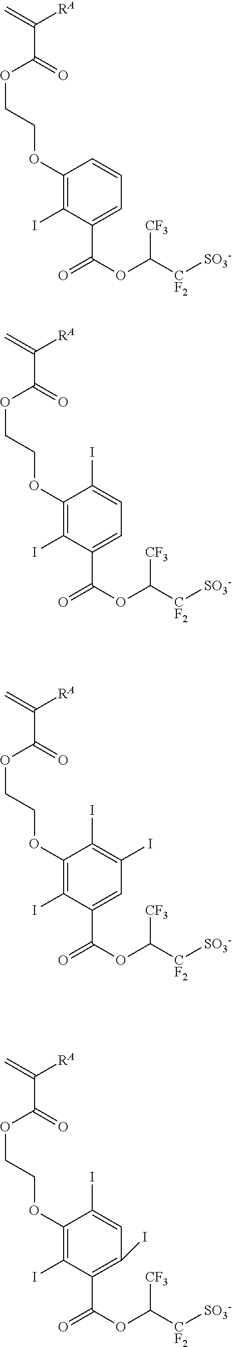

Examples of a monomer from which the repeating unit (b3) is made are shown below, but not limited thereto. Note that in the following formulae, R^{A} is as defined above.

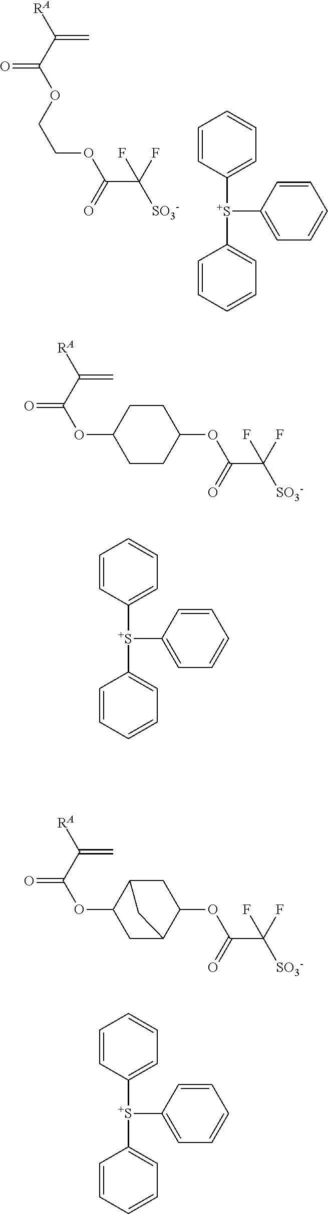

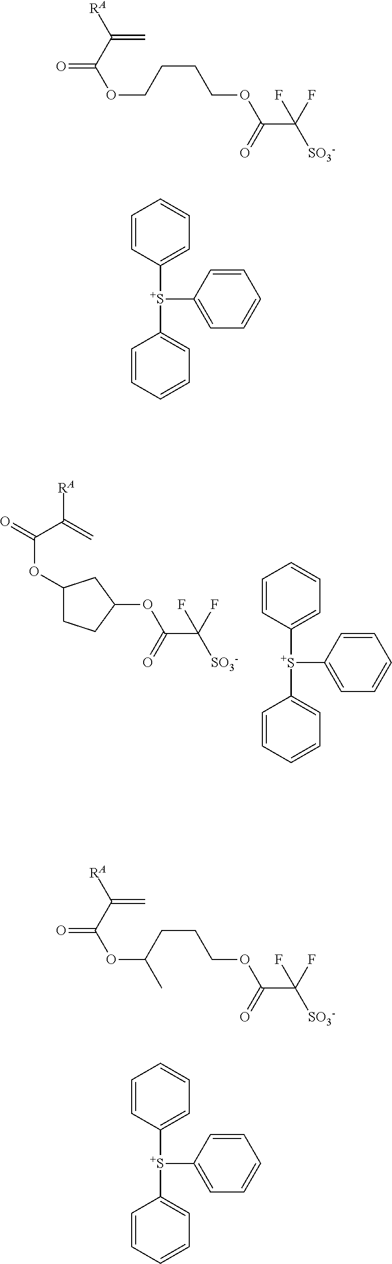

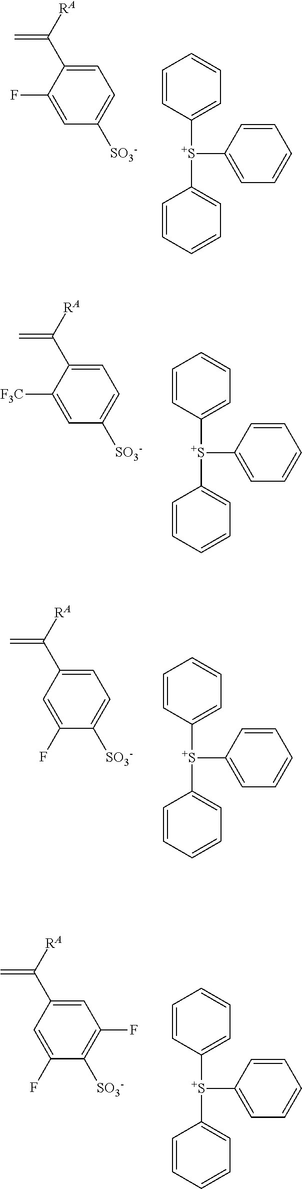

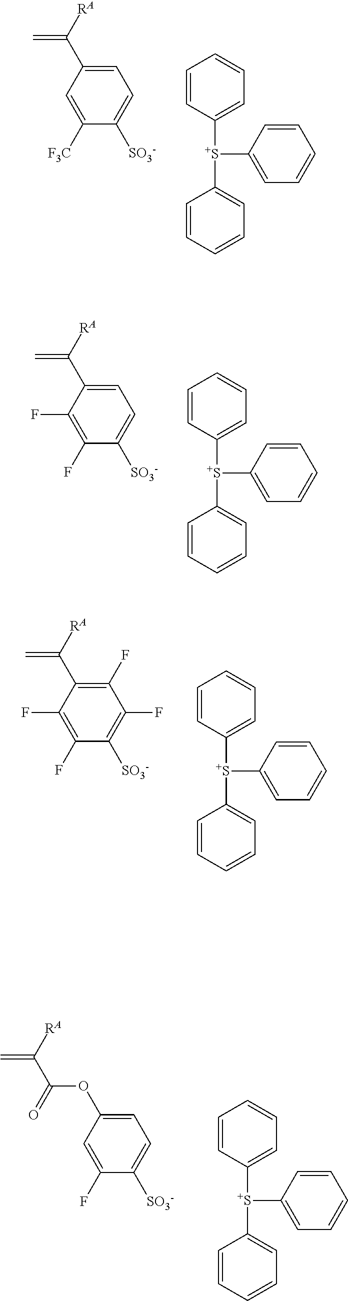

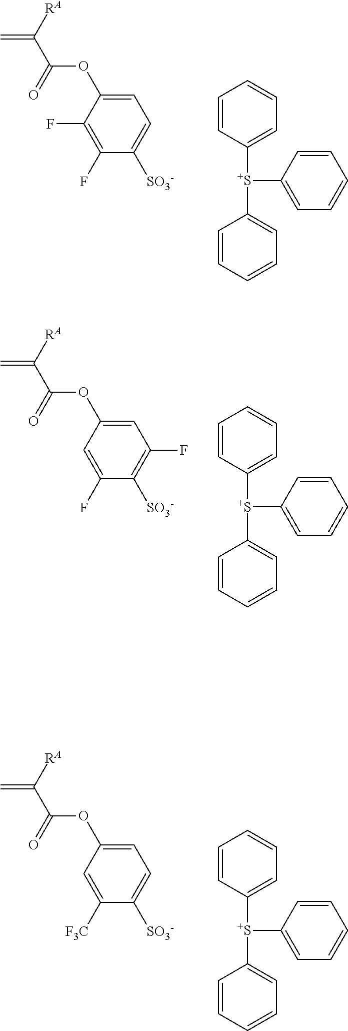

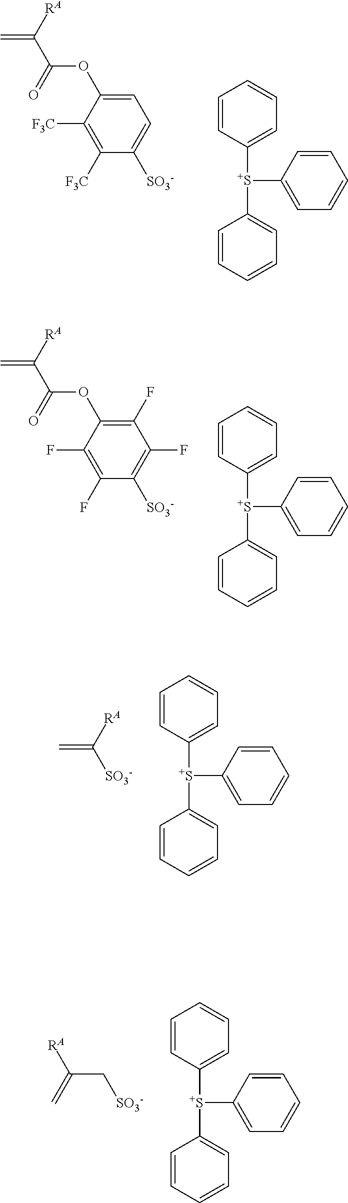

Examples of a monomer from which the repeating unit (b4) is made include, but are not limited to, those obtained by replacing the sulfonium cations of the monomers illustrated above with the iodonium cations as exemplified above.

The repeating units (b1) to (b4) have a function as an acid generator. Attachment of the acid generator to the polymer backbone can reduce acid diffusion and prevent decrease in resolution resulting from blurs due to the acid diffusion. Additionally, homogenous distribution of the acid generator can improve LWR. Note that when the base polymer containing the above repeating unit (b) is used, blending of an addition-type acid generator described later can be omitted.

The repeating unit (a1) and/or (a2) of the present invention has a function of a quencher of a sulfonium salt or an iodonium salt of a substituted or unsubstituted iodine-containing carboxylic acid attached to the polymer backbone via a phenylene group, while the repeating units (b1) to (b4) have a function of an acid generator. Copolymerization of the repeating unit (a1) and/or (a2) with the repeating units (b1) to (b4) enables to impart all the functions to one polymer. In this case, materials to be added other than the polymer may be only an organic solvent and a surfactant, and the simple material composition has advantage of high productivity.

A polymerization rate of the monomer having a double bond and functioning as a quencher used for the present invention is equivalent to a polymerization rate of the monomer having a double bond and functioning as an acid generator, such that copolymerization results in homogenous presence of the quencher and the acid generator in the polymer. This can improve edge roughness after development. When iodine is contained in the anion moiety of the acid generator, the increased number of absorbed photons leads to increased contrast in acid generation, thereby further improving edge roughness. In the repeating unit of the present invention that contains a sulfonium salt or an iodonium salt of an iodine-containing carboxylic acid, absorption by iodine increases the number of photons to be absorbed, resulting in enhanced contrast of quencher decomposition, thereby exerting improvement effect on edge roughness.

The base polymer may further contain a repeating unit (e) that contains no amino group but contains an iodine atom. Examples of a monomer from which the repeating unit (e) is made are shown below, but not limited thereto. Note that in the following formulae, R^{A} is as defined above.

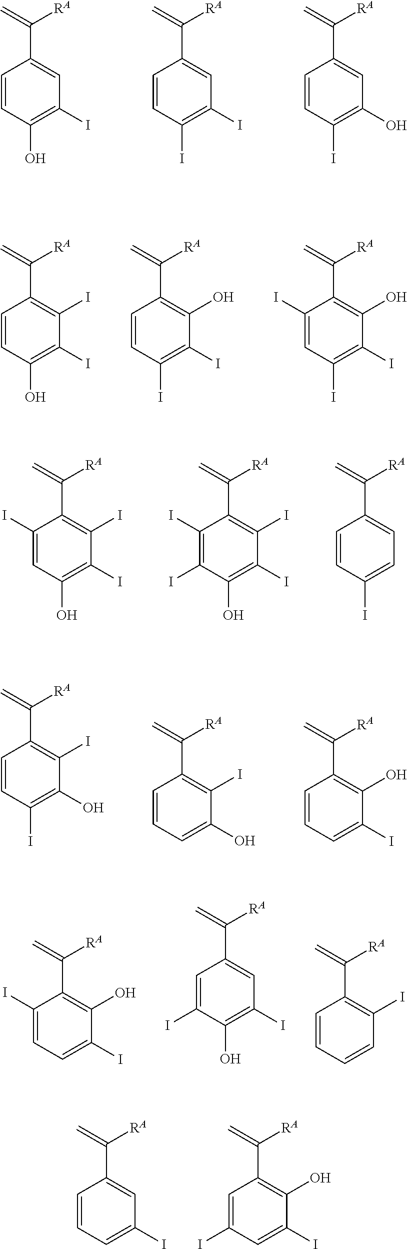

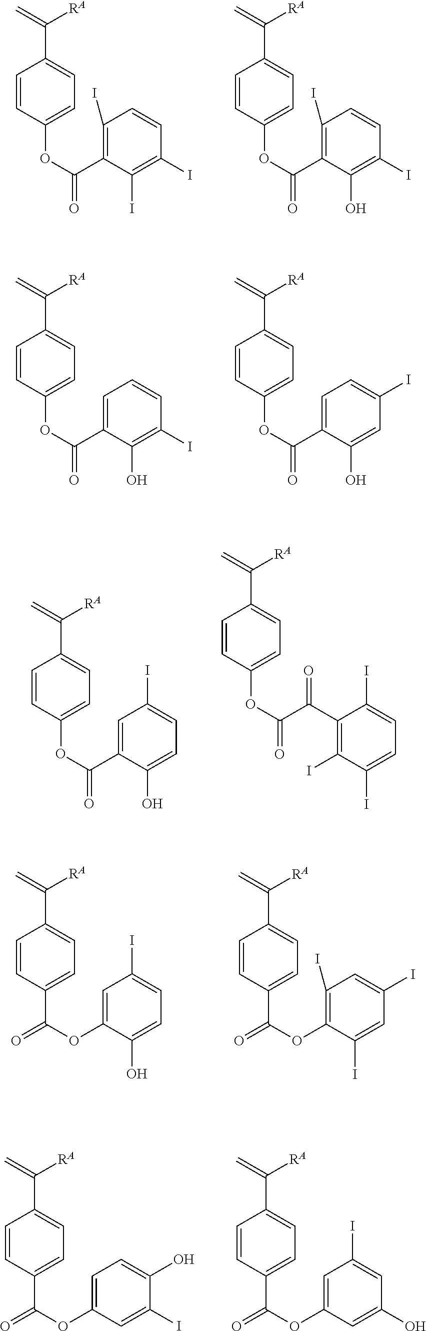

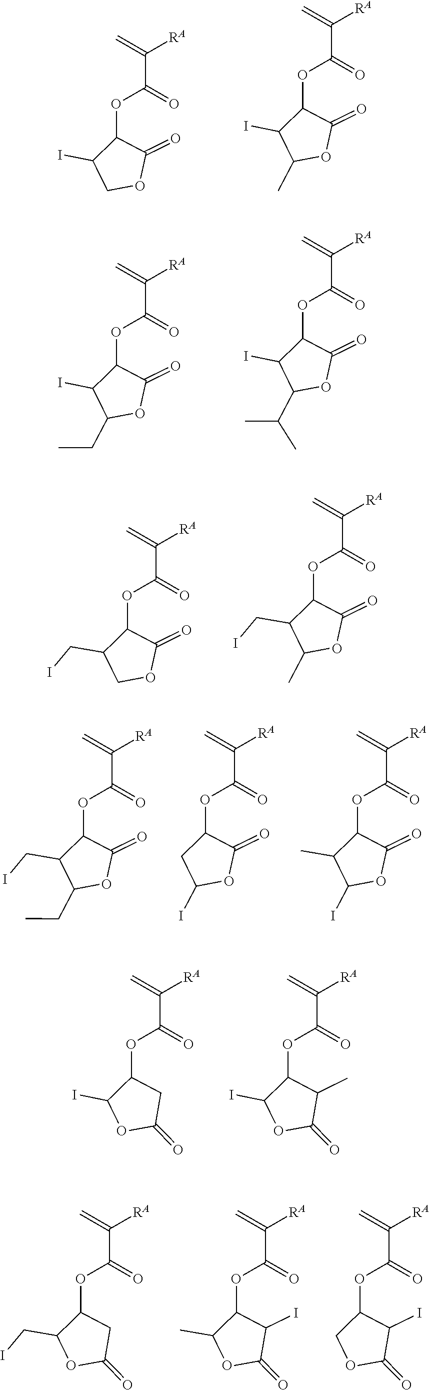

Besides the above-described repeating units, the base polymer may contain a repeating unit (f). Examples of the repeating unit (f) include those derived from styrene, vinylnaphthalene, indene, acenaphthylene, coumarin, coumarone, and the like.

In the base polymer, content ratios of the repeating units (a1), (a2), (b1), (b2), (b3), (b4), (c1), (c2), (d), (e), and (f) preferably satisfy 0≤a1<1.0, 0≤a2<1.0, 0<a1+a2<1.0, 0≤b1≤0.5, 0≤b2≤0.5, 0≤b3≤0.5, 0≤b4≤0.5, 0≤b1+b2+b3+b4≤0.9, 0≤c1≤0.5, 0≤c2≤0.5, 0≤c1+c2≤0.9, 0≤d≤0.5, 0≤e≤0.5, and 0≤f≤0.5, wherein a1, a2, b1, b2, b3, b4, c1, c2, d, e, and f respectively represent mole fraction of the repeating units; the content ratios more preferably satisfy 0.001≤a1≤0.8, 0.001≤a2≤0.8, 0.001≤a1+a2≤0.8, 0≤b1≤0.8, 0≤b2≤0.8, 0≤b3≤0.8, 0≤b4≤0.8, 0≤b1+b2+b3+b4≤0.8, 0≤c1≤0.8, 0≤c2≤0.8, 0≤c1+c2≤0.8, 0≤d≤0.4, 0≤e≤0.4, and 0≤f≤0.4, and further preferably satisfy 0.005≤a1≤0.7, 0.005≤a2≤0.7, 0.005≤a1+a2≤0.7, 0≤b1≤0.7, 0≤b2≤0.7, 0≤b3≤0.7, 0≤b4≤0.7, 0≤b1+b2+b3+b4≤0.7, 0≤c1≤0.7, 0≤c2≤0.7, 0≤c1+c2≤0.7, 0≤d≤0.3, 0≤e≤0.3, and 0≤f≤0.4; provided that a1+a2+b1+b2+b3+b4+c1+c2+d+e+f=1.0.

To synthesize the base polymer, for example, the above-described monomer from which the repeating unit is made may be heated in an organic solvent with a radical polymerization initiator added thereto to perform polymerization.

Examples of the organic solvent used in the polymerization include toluene, benzene, tetrahydrofuran (THF), diethyl ether, dioxane, propylene glycol monomethyl ether, γ-butyrolactone, and mixed solvents thereof. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, lauroyl peroxide, and the like. Temperature during the polymerization is preferably 50 to 80° C. Reaction time is preferably 2 to 100 hours, more preferably 5 to 20 hours.

In a case of copolymerizing a monomer containing a hydroxy group, the hydroxy group may be substituted with an acetal group susceptible to deprotection with acid, such as an ethoxyethoxy group, upon polymerization, and the deprotection may be performed with weak acid and water after the polymerization. Alternatively, the hydroxy group may be substituted with an acetyl group, a formyl group, a pivaloyl group, or the like, upon polymerization, and then alkaline hydrolysis may be performed after the polymerization.

In a case of copolymerizing hydroxystyrene or hydroxyvinylnaphthalene, acetoxystyrene or acetoxyvinylnaphthalene may be used in place of the hydroxystyrene or hydroxyvinylnaphthalene, and after the polymerization, an acetoxy group may be deprotected by the alkaline hydrolysis to yield the hydroxystyrene or hydroxyvinylnaphthalene.

For the alkaline hydrolysis, a base such as ammonia water and triethylamine can be used. Furthermore, the reaction temperature is preferably −20 to 100° C., more preferably 0 to 60° C. The reaction time is preferably 0.2 to 100 hours, more preferably 0.5 to 20 hours.

The base polymer has a weight average molecular weight (Mw) in terms of polystyrene of preferably 1,000 to 100,000, more preferably 2,000 to 30,000, which is determined by gel permeation chromatography (GPC) using THF as a solvent. When the Mw is 1,000 or more, the resist material has excellent heat resistance, whereas when the Mw is 100,000 or less, alkali solubility is sufficient to cause no footing phenomenon after patterning.

Furthermore, when the base polymer has a broad molecular weight distribution (Mw/Mn), there exists a low-molecular-weight or high-molecular-weight polymer, and thus this could result in foreign matters observed on the exposed pattern or a deteriorated pattern profile after exposure. As the pattern rule becomes finer, Mw and Mw/Mn tend to have greater influence. Therefore, to obtain a resist material suitably used for fine pattern dimension, the base polymer preferably has a narrow distribution such as Mw/Mn of 1.0 to 2.0, particularly 1.0 to 1.7.

The base polymer may contain two or more polymers that differ in composition ratio, Mw, and Mw/Mn. Furthermore, a polymer containing the repeating unit (a) may be blended with a polymer containing no repeating unit (a).

### Positive Resist Composition

The present invention further provides a positive resist composition containing the above positive resist material (base polymer). The positive resist composition can further contain one or more selected from an acid generator, an organic solvent, a quencher, and a surfactant. By adding these additives as necessary, it is possible to impart desirable properties to the above composition and a cured material thereof. These additives will be described below.

### Acid Generator

The positive resist composition of the present invention may further contain an acid generator that generates strong acid (hereinafter also referred to as the addition-type acid generator). The strong acid as described herein means a compound that has sufficient acidity to cause deprotection reaction of the acid labile group of the base polymer. Examples of the acid generator include compounds that generate acid in response to actinic light or radiation (photo-acid generator). Although the photo-acid generator can be any compound that generates acid when irradiated with a high-energy beam, preferred is the one that generates sulfonic acid, imide acid, or methide aid. Examples of the suitable photo-acid generator include sulfonium salt, iodonium salt, sulfonyldiazomethane, N-sulfonyloxyimide, oxime-O-sulfonate acid generators, and the like. Specific examples of the photo-acid generator include those described in paragraphs [0122] to [0142] of JP 2008-111103 A.

Additionally, a sulfonium salt represented by the following formula (1-1) and an iodonium salt represented by the following formula (1-2) can also be used suitably as the photo-acid generator.

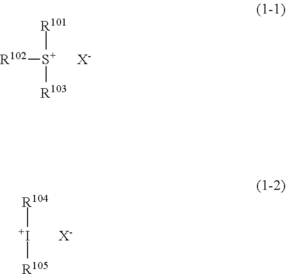

In the formulae (1-1) and (1-2), R¹⁰¹ to R¹⁰⁵ each independently represents a monovalent hydrocarbon group having 1 to 20 carbon atoms and optionally having a heteroatom. Furthermore, any two of R¹⁰¹, R¹⁰², and R¹⁰³ may bond together to form a ring with a sulfur atom attached thereto. The monovalent hydrocarbon group may be linear, branched, or cyclic, and specific examples thereof are the same as described above.

In the formulae (1-1) and (1-2), X⁻ represents an anion selected from the following formulae (1A) to (1D).

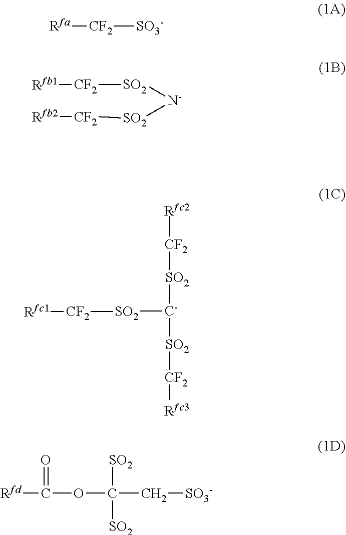

In the formula (1A), R^{fa} represents a fluorine atom or a hydrocarbyl group having 1 to 40 carbon atoms and optionally having a heteroatom. The hydrocarbyl group may be saturated or unsaturated, and may be linear, branched, or cyclic. Specific examples thereof are the same as described later for a hydrocarbyl group represented by R¹⁰⁷ in a formula (1A′).

The anion represented by the formula (1A) is preferably the one represented by the following formula (1A′).

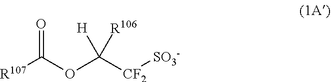

In the formula (1A′), R¹⁰⁶ represents a hydrogen atom or a trifluoromethyl group, preferably a trifluoromethyl group. R¹⁰⁷ represents a hydrocarbyl group having 1 to 38 carbon atoms and optionally having a heteroatom. The heteroatom is preferably an oxygen atom, a nitrogen atom, a sulfur atom, a halogen atom, or the like, and more preferably an oxygen atom. Particularly preferably, the hydrocarbyl group has 6 to 30 carbon atoms from the viewpoint of obtaining high resolution in fine pattern formation.

The hydrocarbyl group represented by R¹⁰⁷ may be saturated or unsaturated, and may be linear, branched, or cyclic. Specific examples thereof include: alkyl groups such as methyl group, ethyl group, propyl group, isopropyl group, butyl group, isobutyl group, sec-butyl group, tert-butyl group, pentyl group, neopentyl group, hexyl group, heptyl group, 2-ethylhexyl group, nonyl group, undecyl group, tridecyl group, pentadecyl group, heptadecyl group, and icosanyl group; cyclic saturated hydrocarbyl groups such as cyclopentyl group, cyclohexyl group, 1-adamantyl group, 2-adamantyl group, 1-adamantylmethyl group, norbornyl group, norbornylmethyl group, tricyclodecanyl group, tetracyclododecanyl group, tetracyclododecanylmethyl group, and dicyclohexylmethyl group; unsaturated hydrocarbyl groups such as allyl group and 3-cyclohexenyl group; aryl groups such as phenyl group, 1-naphthyl group, and 2-naphthyl group; aralkyl groups such as benzyl group and diphenylmethyl group; and the like.

Furthermore, some or all of hydrogen atoms of these groups may be substituted with a group containing a heteroatom such as an oxygen atom, a sulfur atom, a nitrogen atom, and a halogen atom, and some of carbon atoms of these groups may be substituted with a group containing a heteroatom such as an oxygen atom, a sulfur atom, and a nitrogen atom. As a result, these groups may contain a hydroxy group, a cyano group, a carbonyl group, an ether bond, an ester bond, a sulfonic acid ester bond, a carbonate group, a lactone ring, a sultone ring, a carboxylic anhydride, a haloalkyl group, and the like. Examples of the hydrocarbyl group having a heteroatom include tetrahydrofuryl group, methoxymethyl group, ethoxymethyl group, methylthiomethyl group, acetamidomethyl group, trifluoroethyl group, (2-methoxyethoxy)methyl group, acetoxymethyl group, 2-carboxy-1-cyclohexyl group, 2-oxopropyl group, 4-oxo-1-adamantyl group, 3-oxocyclohexyl group, and the like.

Synthesis of the sulfonium salt containing the anion represented by the formula (1A′) is described in detail in JP 2007-145797 A, JP 2008-106045 A, JP 2009-7327 A, JP 2009-258695 A, etc. Additionally, sulfonium salts described in JP 2010-215608 A, JP 2012-41320 A, JP 2012-106986 A, JP 2012-153644 A, etc. are also suitably used.

Examples of the anion represented by the formula (1A) include those exemplified for an anion represented by a formula (1A) in JP 2018-197853 A.

In the formula (1B), R^{fb1} and R^{fb2} each independently represents a fluorine atom, or a hydrocarbyl group having 1 to 40 carbon atoms and optionally having a heteroatom. The hydrocarbyl group may be saturated or unsaturated, and may be linear, branched, or cyclic. Specific examples thereof are the same as exemplified in the description of R¹⁰⁷ in the formula (1A′). R^{fb1} and R^{fb2} are preferably a fluorine atom or a linear fluorinated alkyl group having 1 to 4 carbon atoms. Furthermore, R^{fb1} and R^{fb2} may bond together to form a ring with a group (—CF₂—SO₂—N—SO₂—CF₂—) attached thereto, and in this case, the group obtained by bonding between R^{fb1} and R^{fb2} is preferably a fluorinated ethylene group or a fluorinated propylene group.

In the formula (1C), each of R^{f}° 1, R^{f}c2, and R^{f}c3 independently represents a fluorine atom, or a hydrocarbyl group having 1 to 40 carbon atoms and optionally having a heteroatom. The hydrocarbyl group may be saturated or unsaturated, and may be linear, branched, or cyclic. Specific examples thereof are the same as exemplified in the description of R¹⁰⁷ in the formula (1A′). R^{fc1}, R^{fc2}, and R^{fc3} are preferably a fluorine atom or a linear fluorinated alkyl group having 1 to 4 carbon atoms. Furthermore, R^{fc1} and R^{fc2} may bond together to form a ring with a group (—CF₂—SO₂—C—SO₂—CF₂—) attached thereto, and in this case, the group obtained by bonding between R^{f}c1 and R^{f}c² is preferably a fluorinated ethylene group or a fluorinated propylene group.

In the formula (1D), R^{fd} represents a hydrocarbyl group having 1 to 40 carbon atoms and optionally having a heteroatom. The hydrocarbyl group may be saturated or unsaturated, and may be linear, branched, or cyclic. Specific examples thereof are the same as exemplified in the description of R¹⁰⁷ in the formula (1A′).

Synthesis of the sulfonium salt containing the anion represented by the formula (1D) is described in detail in JP 2010-215608 A and JP 2014-133723 A.

Examples of the anion represented by the formula (1D) are the same as exemplified for an anion represented by a formula (1D) in JP 2018-197853 A.

Note that the photo-acid generator containing the anion represented by the formula (1D) does not have fluorine at α position of a sulfo group, but has two trifluoromethyl groups at β position, thereby having sufficient acidity to cut the acid labile group in the base polymer. Accordingly, it is usable as the photo-acid generator.

Furthermore, a compound represented by the following formula (2) can also be used suitably as the photo-acid generator.

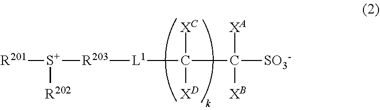

In the formula (2), each of R²⁰¹ and R²⁰² independently represents a hydrocarbyl group having 1 to 30 carbon atoms and optionally having a heteroatom. R²⁰³ represents a hydrocarbylene group having 1 to 30 carbon atoms and optionally having a heteroatom. Furthermore, R²⁰¹ and R²⁰² or R²⁰¹ and R²⁰³ may bond together to form a ring with a sulfur atom attached thereto. In this case, examples of the ring are the same as exemplified for the ring that can be formed by R¹⁰¹ and R¹⁰² bonded together with the sulfur atom attached thereto in the description of the formula (1-1).

The hydrocarbyl groups represented by R²⁰¹ and R²⁰² may be saturated or unsaturated, and may be linear, branched, or cyclic. Specific examples thereof include: alkyl groups such as methyl group, ethyl group, propyl group, isopropyl group, n-butyl group, sec-butyl group, tert-butyl group, n-pentyl group, tert-pentyl group, n-hexyl group, n-octyl group, 2-ethylhexyl group, n-nonyl group, and n-decyl group; cyclic saturated hydrocarbyl groups such as cyclopentyl group, cyclohexyl group, cyclopentylmethyl group, cyclopentylethyl group, cyclopentylbutyl group, cyclohexylmethyl group, cyclohexylethyl group, cyclohexylbutyl group, norbornyl group, tricyclo[5.2.1.0^{2,6}]decanyl group, and adamantyl group; aryl groups such as phenyl group, methylphenyl group, ethylphenyl group, n-propylphenyl group, isopropylphenyl group, n-butylphenyl group, isobutylphenyl group, sec-butylphenyl group, tert-butylphenyl group, naphthyl group, methylnaphthyl group, ethylnaphthyl group, n-propylnaphthyl group, isopropylnaphthyl group, n-butylnaphthyl group, isobutylnaphthyl group, sec-butylnaphthyl group, tert-butylnaphthyl group, and anthracenyl group; and the like. Additionally, some or all of hydrogen atoms of these groups may be substituted with a group containing a heteroatom such as an oxygen atom, a sulfur atom, a nitrogen atom, and a halogen atom, and some of carbon atoms of these groups may be substituted with a group containing a heteroatom such as an oxygen atom, a sulfur atom, and a nitrogen atom. As a result, these groups may contain a hydroxy group, a cyano group, a carbonyl group, an ether bond, an ester bond, a sulfonic acid ester bond, a carbonate group, a lactone ring, a sultone ring, a carboxylic anhydride, a haloalkyl group, or the like.

The hydrocarbylene group represented by R²⁰³ may be saturated or unsaturated, and may be linear, branched, or cyclic. Specific examples thereof include: alkanediyl groups such as methylene group, ethylene group, propane-1,3-diyl group, butane-1,4-diyl group, pentane-1,5-diyl group, hexane-1,6-diyl group, heptane-1,7-diyl group, octane-1,8-diyl group, nonane-1,9-diyl group, decane-1,10-diyl group, undecane-1,11-diyl group, dodecane-1,12-diyl group, tridecane-1,13-diyl group, tetradecane-1,14-diyl group, pentadecane-1,15-diyl group, hexadecane-1,16-diyl group, and heptadecane-1,17-diyl group; cyclic saturated hydrocarbylene groups such as cyclopentanediyl group, cyclohexanediyl group, norbornanediyl group, and adamantanediyl group; arylene groups such as phenylene group, methylphenylene group, ethylphenylene group, n-propylphenylene group, isopropylphenylene group, n-butylphenylene group, isobutylphenylene group, sec-butylphenylene group, tert-butylphenylene group, naphthylene group, methylnaphthylene group, ethylnaphthylene group, n-propylnaphthylene group, isopropylnaphthylene group, n-butylnaphthylene group, isobutylnaphthylene group, sec-butylnaphthylene group, and tert-butylnaphthylene group; and the like. Additionally, some or all of hydrogen atoms of these groups may be substituted with a group containing a heteroatom such as an oxygen atom, a sulfur atom, a nitrogen atom, and a halogen atom, and some of carbon atoms of these groups may be substituted with a group containing a heteroatom such as an oxygen atom, a sulfur atom, and a nitrogen atom. As a result, these groups may contain a hydroxy group, a cyano group, a carbonyl group, an ether bond, an ester bond, a sulfonic acid ester bond, a carbonate group, a lactone ring, a sultone ring, a carboxylic anhydride, a haloalkyl group, or the like. The heteroatom is preferably an oxygen atom.

In the formula (2), L¹ represents a single bond, an ether bond, or a hydrocarbylene group having 1 to 20 carbon atoms and optionally having a heteroatom. The hydrocarbylene group may be saturated or unsaturated, and may be linear, branched, or cyclic. Specific examples thereof are the same as exemplified for the hydrocarbylene group represented by R²⁰³.

In the formula (2), each of X^{A}, X^{B}, X^{C}, and X^{D} independently represents a hydrogen atom, a fluorine atom, or a trifluoromethyl group. However, at least one of X^{A}, X^{B}, X^{C}, and X^{D} represents a fluorine atom or a trifluoromethyl group.

In the formula (2), “k” represents an integer of 0 to 3.

The photo-acid generator represented by the formula (2) is preferably the one represented by the following formula (2′).

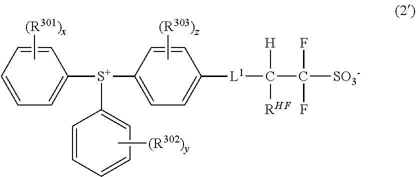

In the formula (2′), L¹ is as defined above. R^{HF} represents a hydrogen atom or a trifluoromethyl group, preferably a trifluoromethyl group. Each of R³⁰¹, R³⁰², and R³⁰³ independently represents a hydrogen atom or a hydrocarbyl group having 1 to 20 carbon atoms and optionally having a heteroatom. The hydrocarbyl group may be saturated or unsaturated, and may be linear, branched, or cyclic. Specific examples thereof are the same as exemplified in the description of R¹⁰⁷ in the formula (1A′). Each of “x” and “y” independently represents an integer of 0 to 5, and “z” represents an integer of 0 to 4.

Examples of the photo-acid generator represented by the formula (2) are the same as exemplified for a photo-acid generator represented by a formula (2) in JP 2017-026980 A.

Of the photo-acid generators, those containing the anion represented by the formula (1A′) or (1D) are particularly preferable because of small acid diffusion and excellent solubility in a resist solvent. Furthermore, the one represented by the formula (2′) is particularly preferable because of extremely small acid diffusion.

Furthermore, a sulfonium salt or an iodonium salt each having an anion containing an iodine atom- or bromine atom-substituted aromatic ring can also be used as the photo-acid generator. Examples of such salts include those represented by the following formulae (3-1) and (3-2).

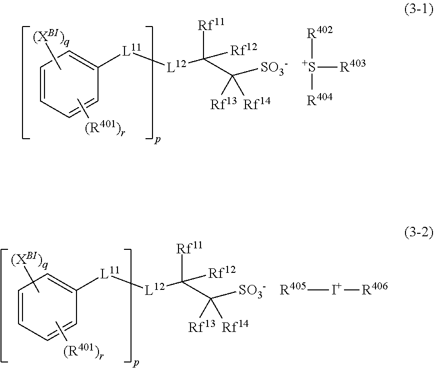

In the formulae (3-1) and (3-2), “p” represents an integer satisfying 1≤p≤3. “q” and “r” represent an integer satisfying 1≤q≤5, 0≤r≤3, and 1≤q+r≤5. “q” preferably represents an integer satisfying 1≤q≤3, more preferably 2 or 3. “r” preferably represents an integer satisfying 0 r 2.

In the formulae (3-1) and (3-2), X^{BI} represents an iodine atom or a bromine atom, and when “q” is equal to or greater than 2, they may be the same or different from each other.

In the formulae (3-1) and (3-2), L¹¹ represents a single bond, an ether bond, an ester bond, or a saturated hydrocarbylene group having 1 to 6 carbon atoms and optionally containing an ether bond or an ester bond. The saturated hydrocarbylene group may be linear, branched, or cyclic.

In the formulae (3-1) and (3-2), L¹² represents a single bond or a divalent linking group having 1 to 20 carbon atoms when “r” represents 1, and represents a trivalent or tetravalent linking group having 1 to 20 carbon atoms when “r” represents 2 or 3. The linking group may contain an oxygen atom, a sulfur atom, or a nitrogen atom.

In the formulae (3-1) and (3-2), R⁴⁰¹ represents: a hydroxy group, a carboxy group, a fluorine atom, a chlorine atom, a bromine atom, or an amino group; or a saturated hydrocarbyl group having 1 to 20 carbon atoms, a saturated hydrocarbyloxy group having 1 to 20 carbon atoms, a saturated hydrocarbyloxycarbonyl group having 2 to 10 carbon atoms, a saturated hydrocarbylcarbonyloxy group having 2 to 20 carbon atoms, or a saturated hydrocarbylsulfonyloxy group having 1 to 20 carbon atoms, each optionally containing a fluorine atom, a chlorine atom, a bromine atom, a hydroxy group, an amino group, or an ether bond; or —NR^{401A}—C(═O)—R^{401B} or —NR^{401A}—C(═O)—O—R^{401B}. R^{401A} represents a hydrogen atom or a saturated hydrocarbyl group having 1 to 6 carbon atoms, optionally containing a halogen atom, a hydroxy group, an alkoxy group having 1 to 6 carbon atoms, a saturated hydrocarbylcarbonyl group having 2 to 6 carbon atoms, or a saturated hydrocarbylcarbonyloxy group having 2 to 6 carbon atoms. R^{401B} represents an aliphatic hydrocarbyl group having 1 to 16 carbon atoms or an aryl group having 6 to 12 carbon atoms, optionally containing a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms. The aliphatic hydrocarbyl group may be saturated or unsaturated, and may be linear, branched, or cyclic. The saturated hydrocarbyl group, saturated hydrocarbyloxy group, saturated hydrocarbyloxycarbonyl group, saturated hydrocarbylcarbonyl group, and saturated hydrocarbylcarbonyloxy group may be linear, branched, or cyclic. When “p” and/or “r” is equal to or greater than 2, each R⁴⁰¹ may be the same or different from each other.

Among these, R⁴⁰¹ preferably represents a hydroxy group, —NR^{401A}—C(═O)—R^{401B}, —NR^{401A}—C(═O)—O—R^{401B}, a fluorine atom, a chlorine atom, a bromine atom, a methyl group, a methoxy group, or the like.

In the formulae (3-1) and (3-2), each of Rf¹¹ to Rf¹⁴ independently represents a hydrogen atom, a fluorine atom, or a trifluoromethyl group, provided that at least one of Rf¹¹ to Rf¹⁴ represents a fluorine atom or a trifluoromethyl group. Furthermore, Rf¹¹ and Rf¹² may be taken together to form a carbonyl group. Particularly, both of Rf¹³ and Rf¹⁴ preferably represent a fluorine atom.

In the formulae (3-1) and (3-2), each of R⁴⁰², R⁴⁰³, R⁴⁰⁴, R⁴⁰⁵, and R⁴⁰⁶ independently represents a hydrocarbyl group having 1 to 20 carbon atoms and optionally containing a fluorine atom, a chlorine atom, a bromine atom, an iodine atom, or a heteroatom. The hydrocarbyl group may be saturated or unsaturated, and may be linear, branched, or cyclic. Specific examples thereof are the same as exemplified for the hydrocarbyl groups represented by R¹⁰¹ to R¹⁰⁵ in the description of the formulae (1-1) and (1-2). Furthermore, some or all of hydrogen atoms of these groups may be substituted with a hydroxy group, a carboxy group, a halogen atom, a cyano group, a nitro group, a mercapto group, a sultone group, a sulfone group, or a sulfonium salt-containing group, and some of carbon atoms of these groups may be substituted with an ether bond, an ester bond, a carbonyl group, an amide bond, a carbonate group, or a sulfonic acid ester bond. Furthermore, R⁴⁰² and R⁴⁰³ may bond together to form a ring with a sulfur atom attached thereto. In this case, examples of the ring are the same as exemplified for the ring that can be formed by R¹⁰¹ and R¹⁰² bonded together with the sulfur atom attached thereto in the description of the formula (1-1)

Examples of the cation of the sulfonium salt represented by the formula (3-1) are the same as exemplified for the cation of the sulfonium salt represented by the formula (1-1). Furthermore, examples of the cation of the iodonium salt represented by the formula (3-2) are the same as exemplified for the cation of the iodonium salt represented by the formula (1-2).

Examples of the anion of the onium salt represented by the formula (3-1) or (3-2) are shown below, but not limited thereto. Note that in the following formulae, X^{BI} is as defined above.

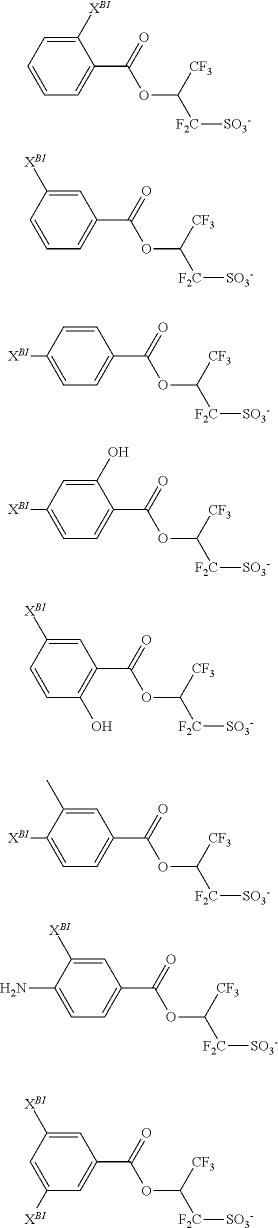

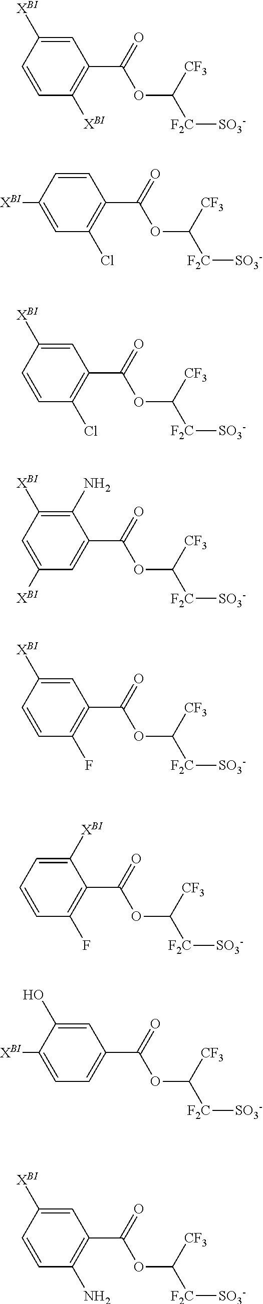

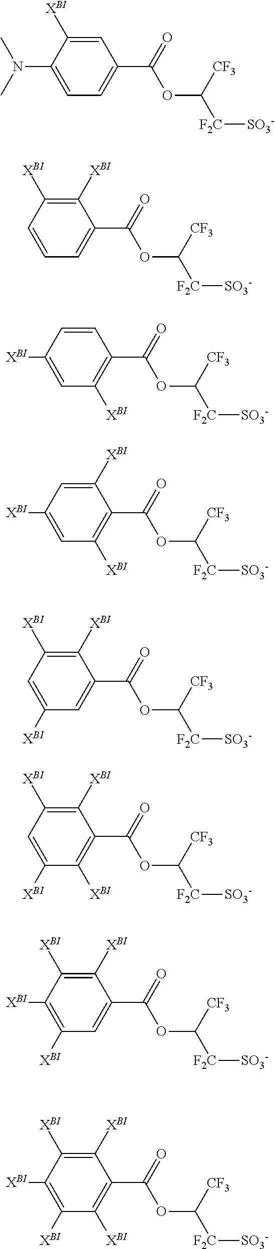

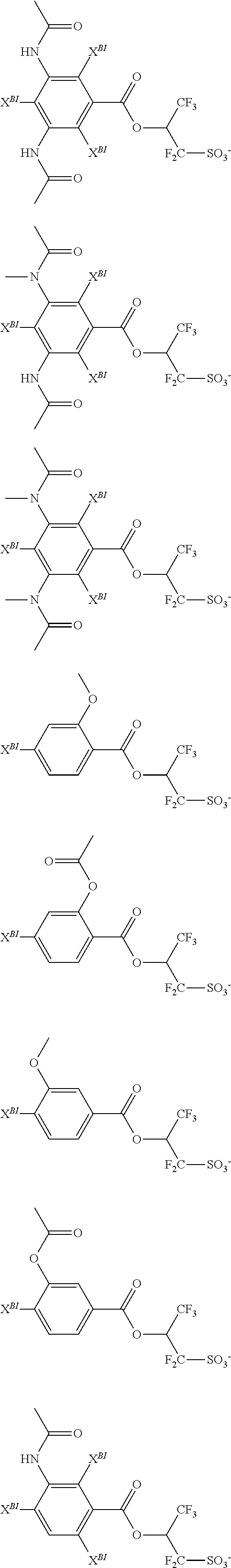

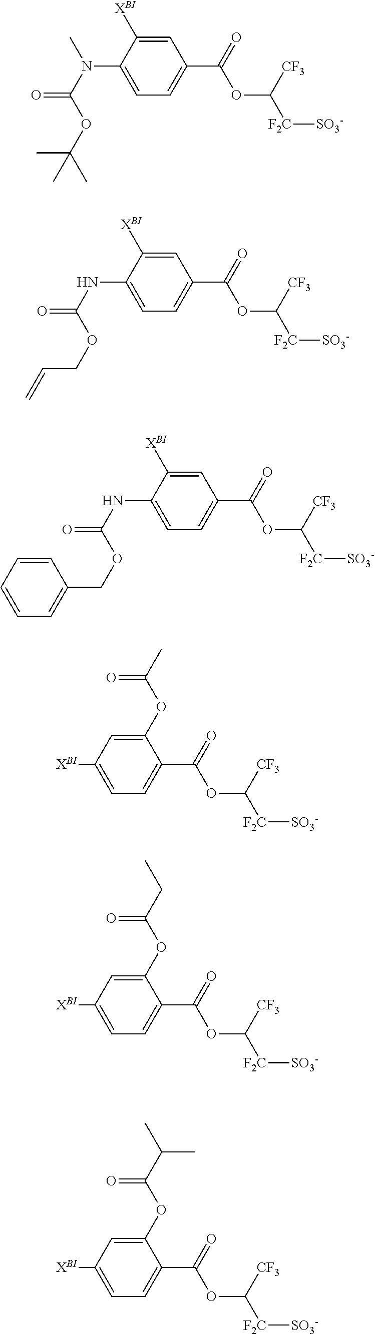

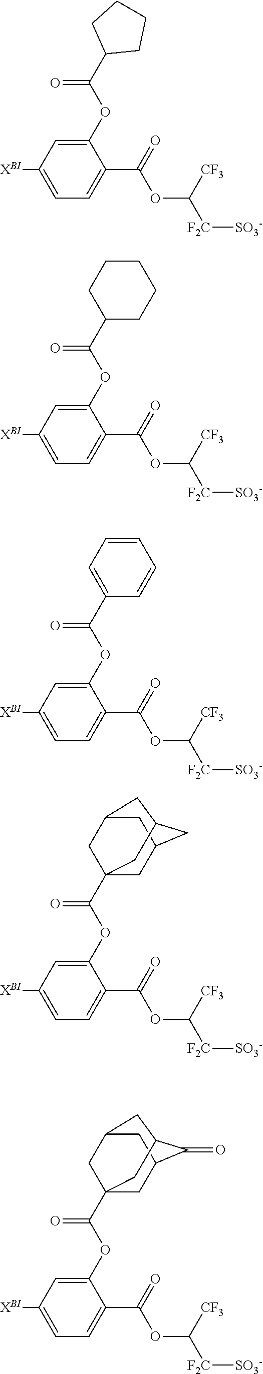

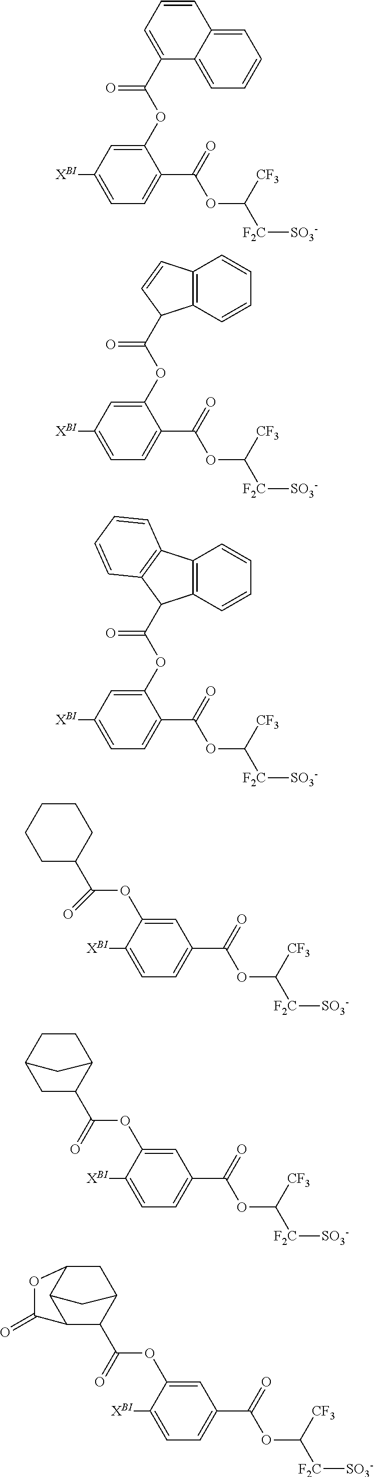

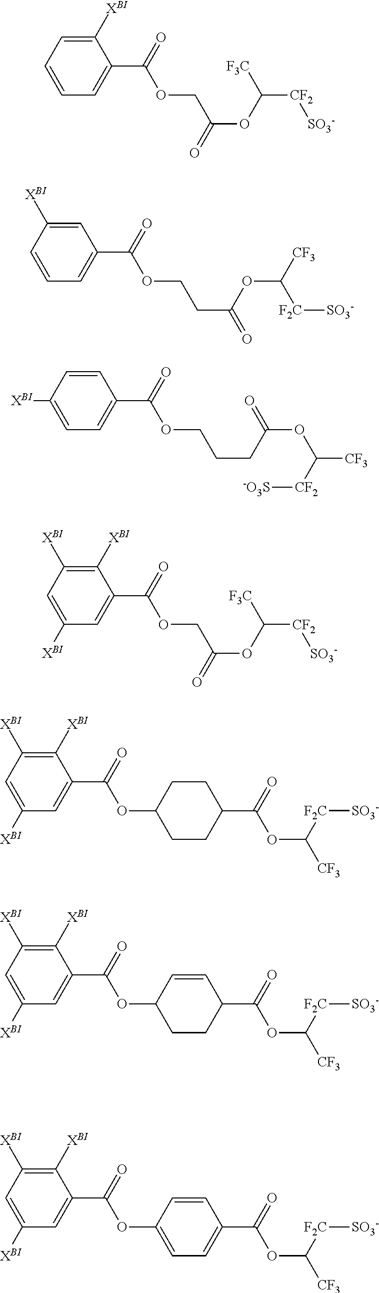

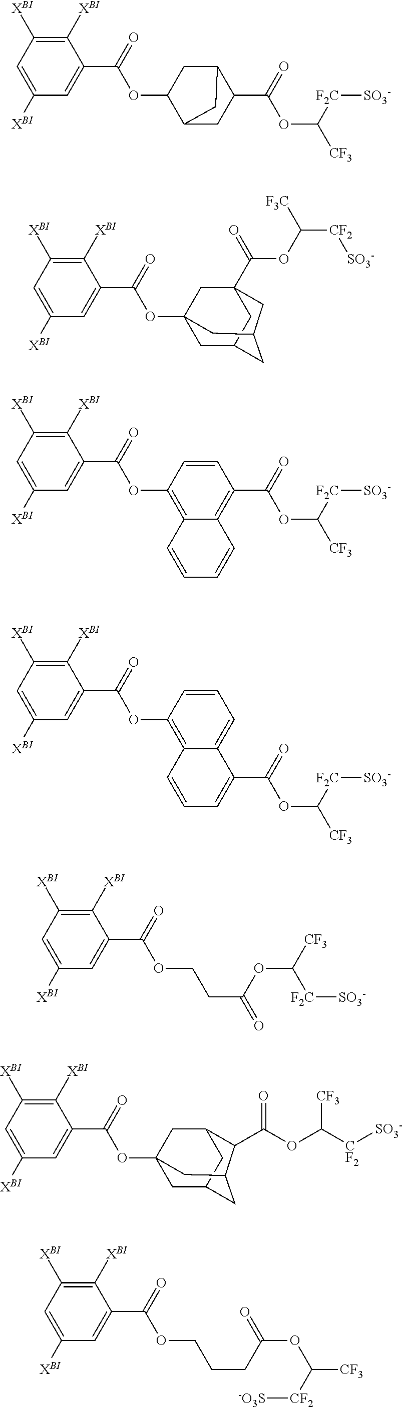

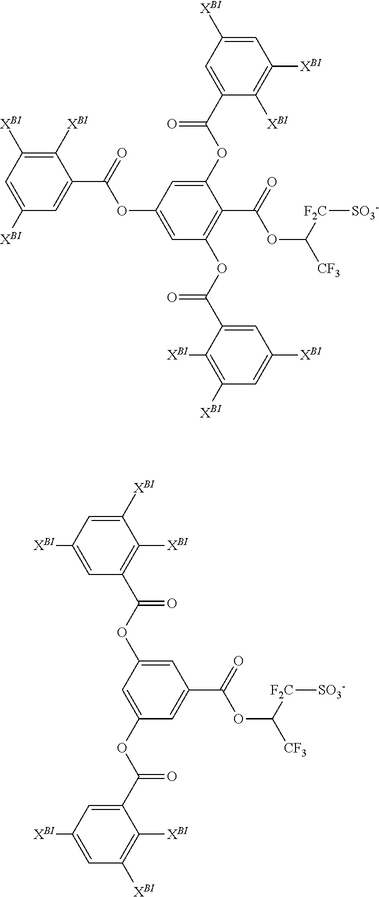

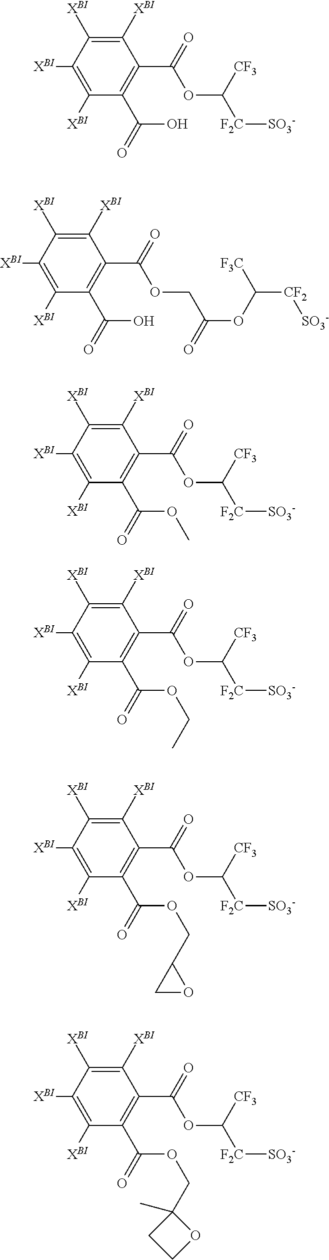

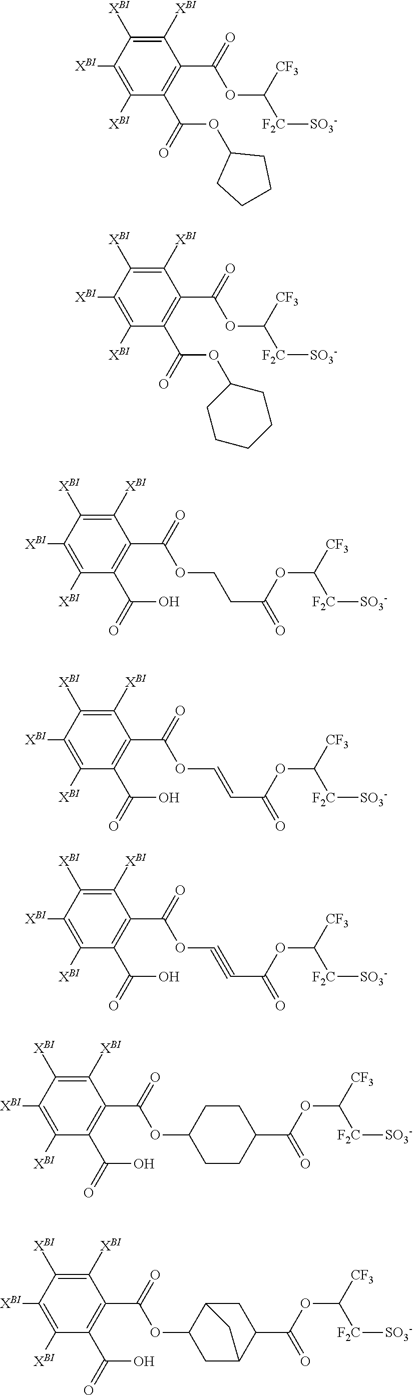

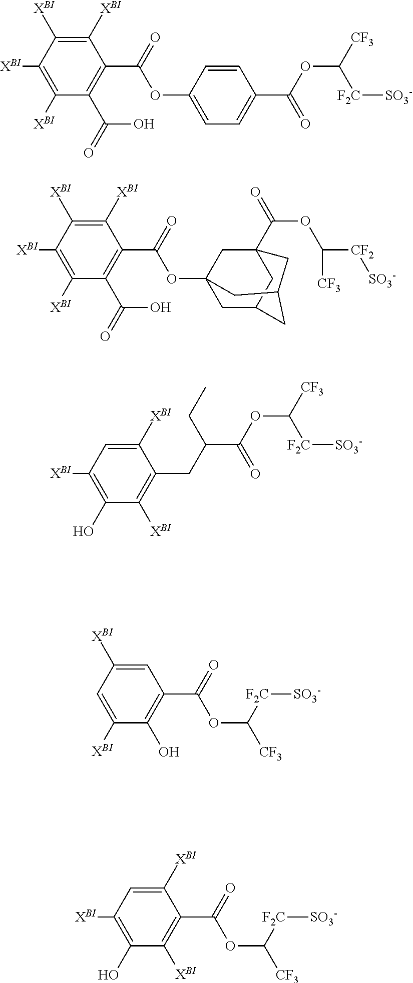

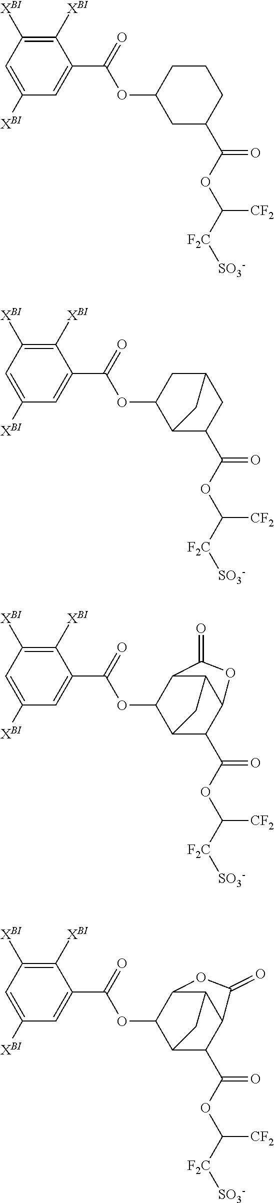

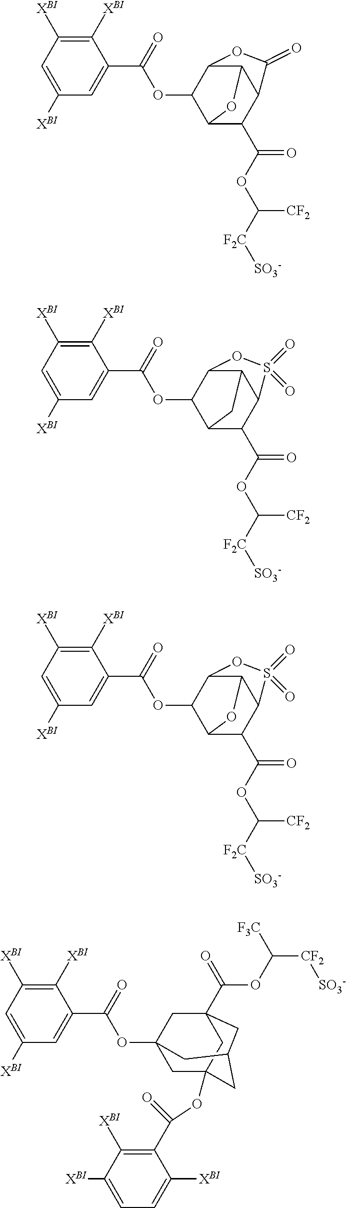

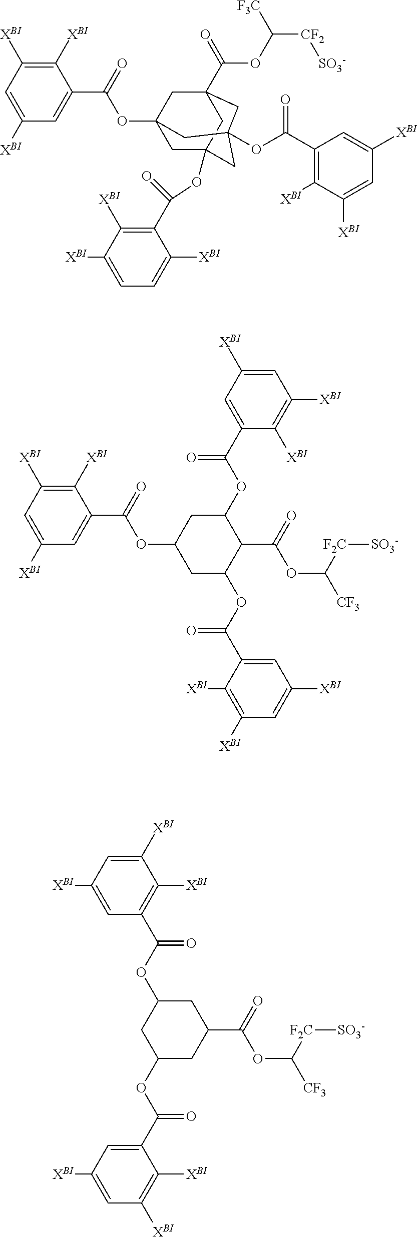

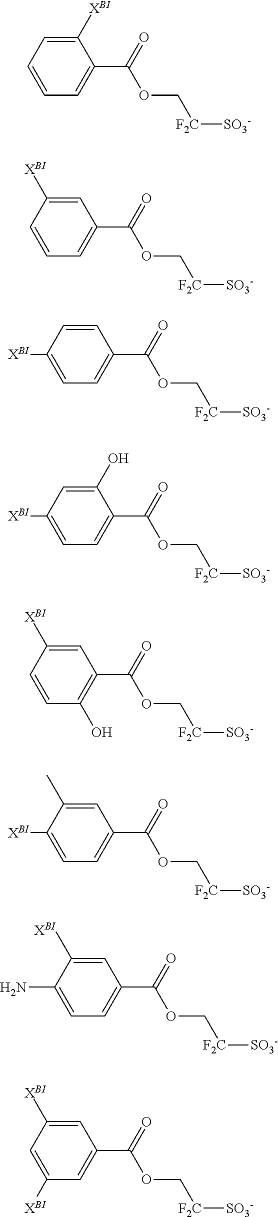

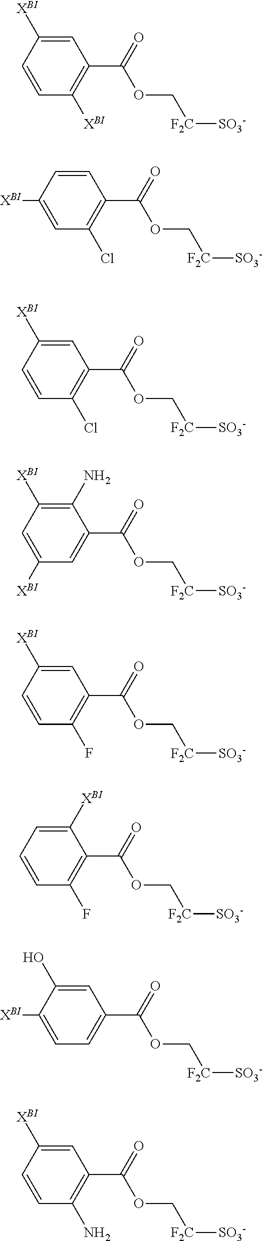

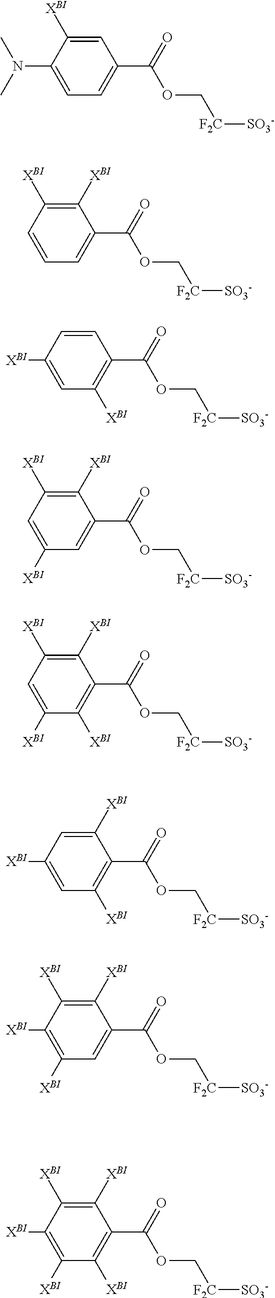

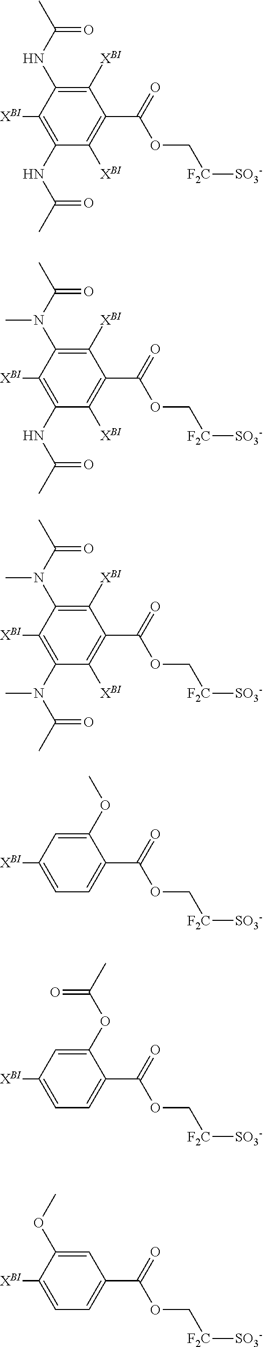

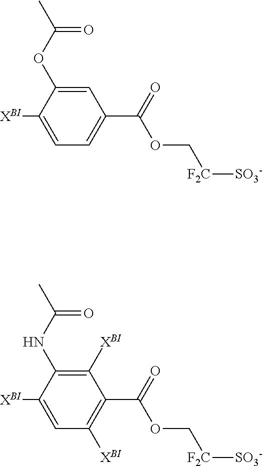

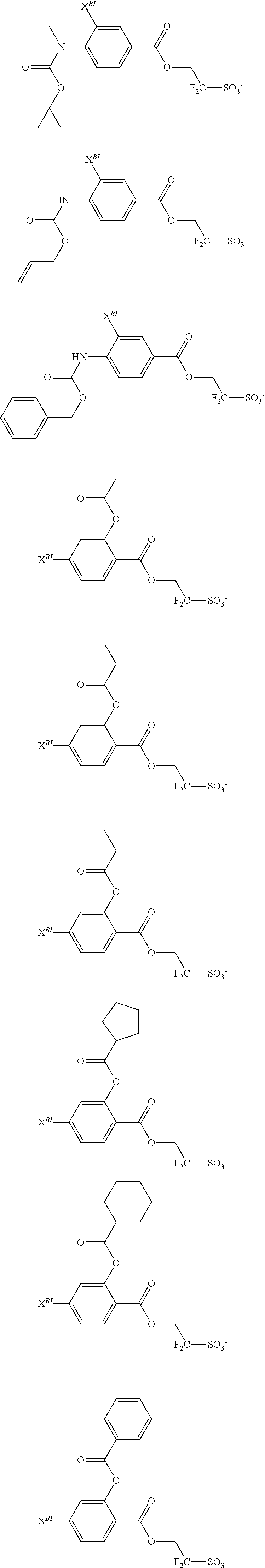

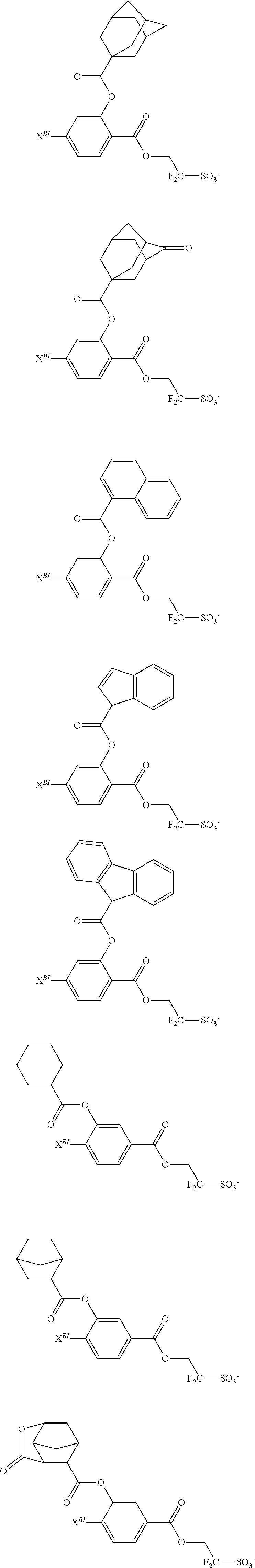

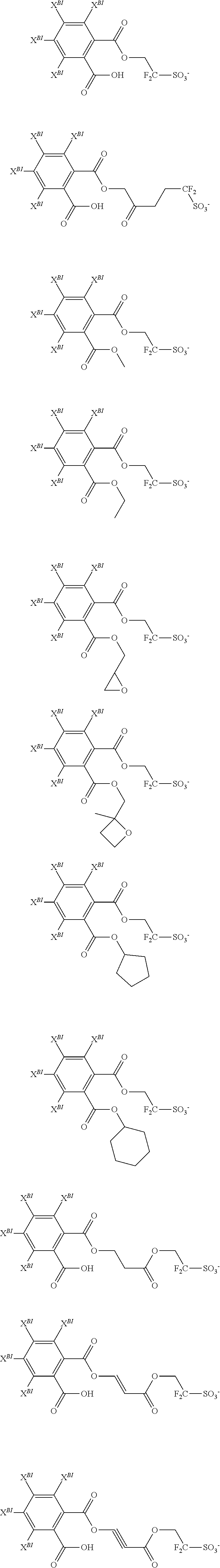

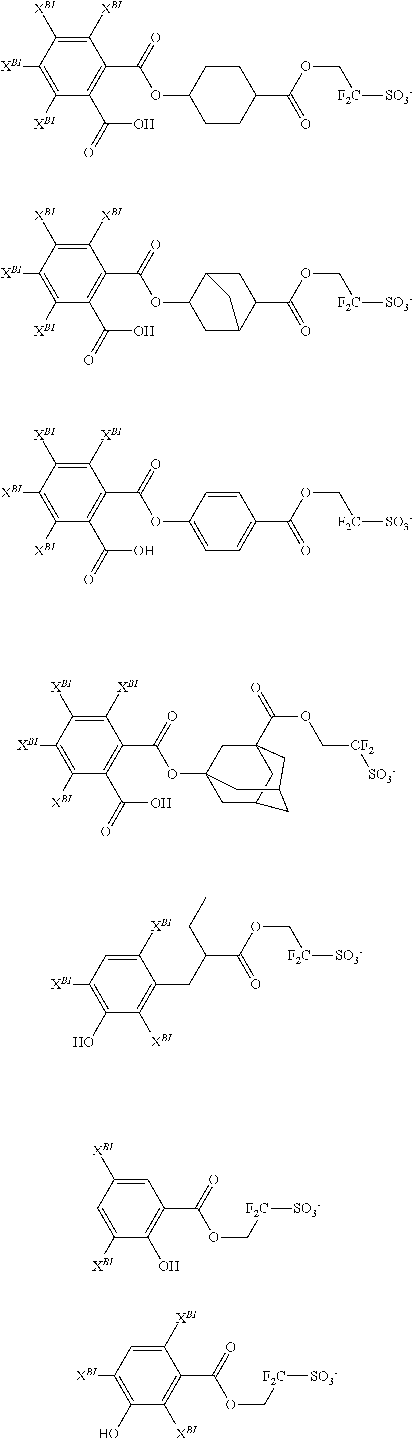

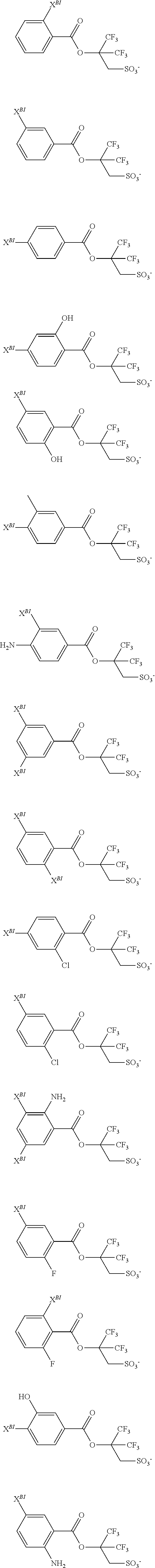

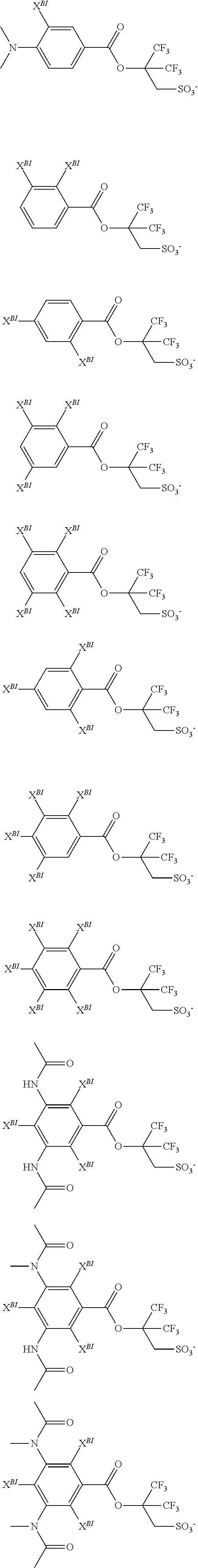

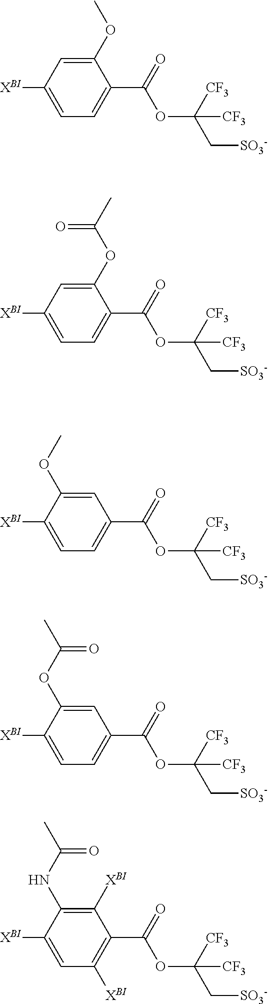

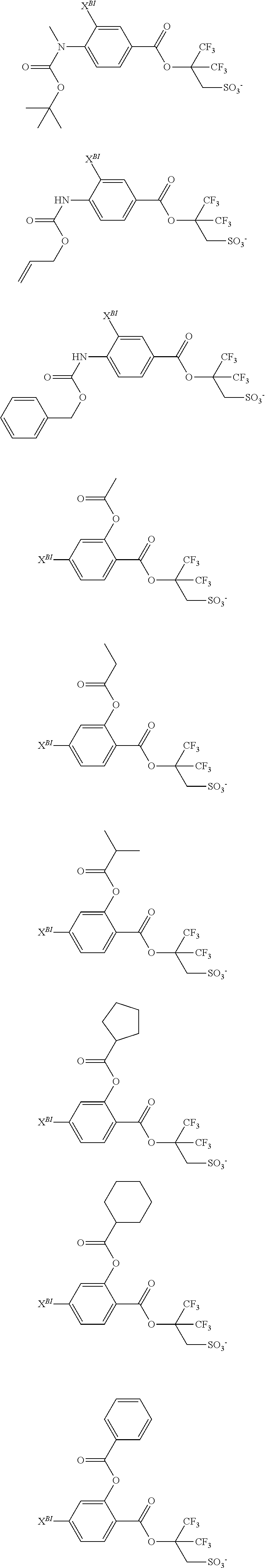

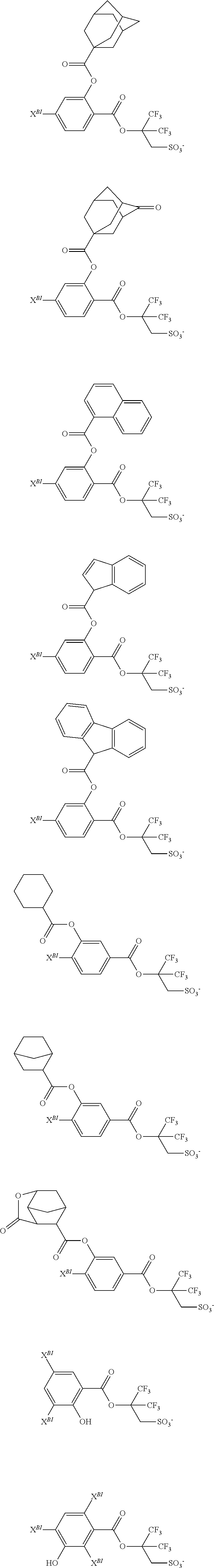

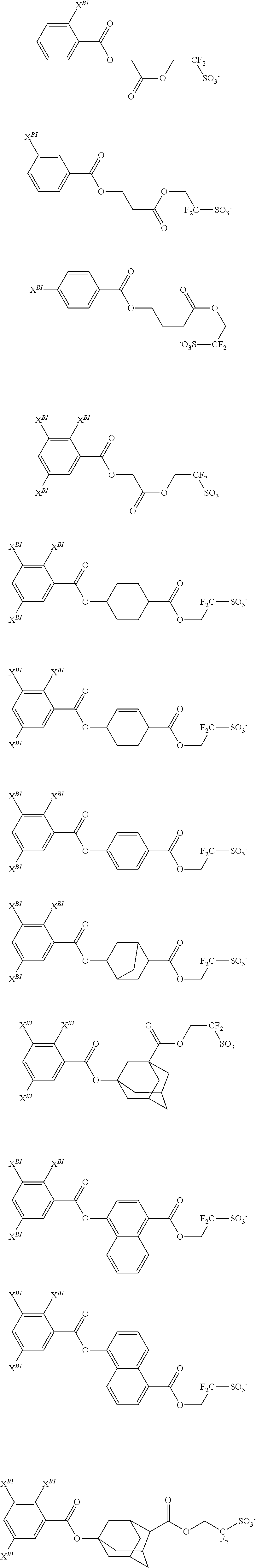

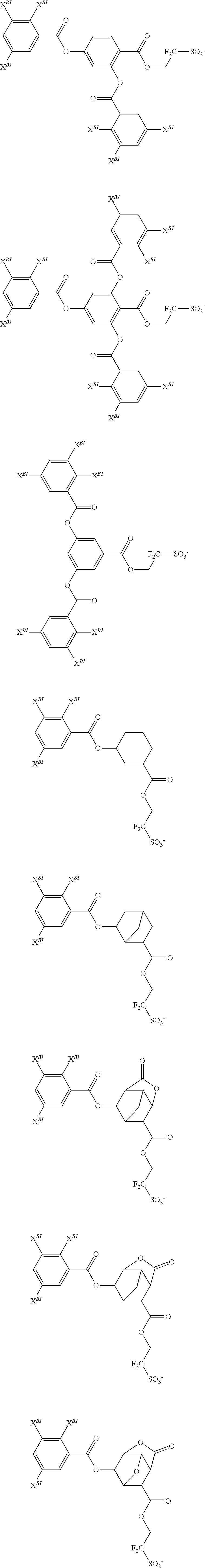

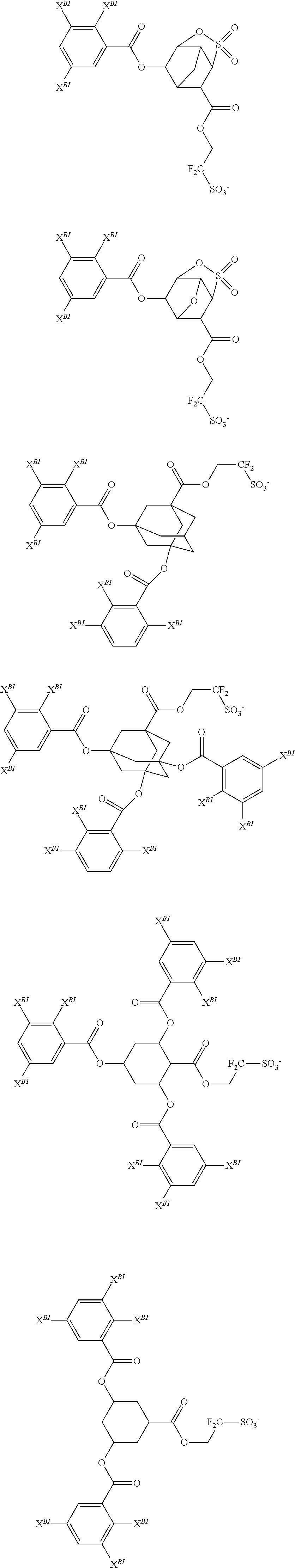

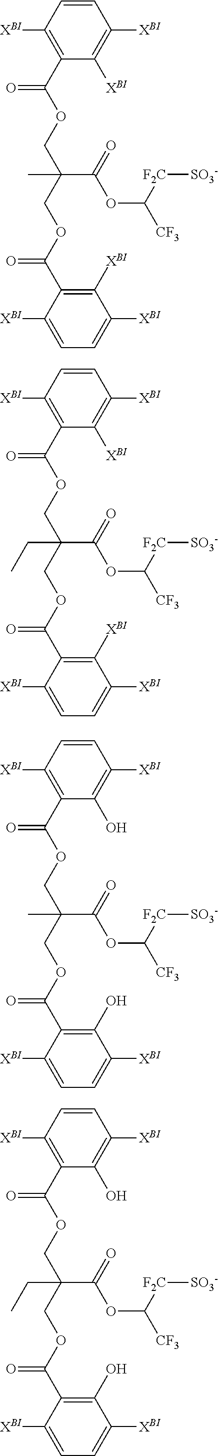

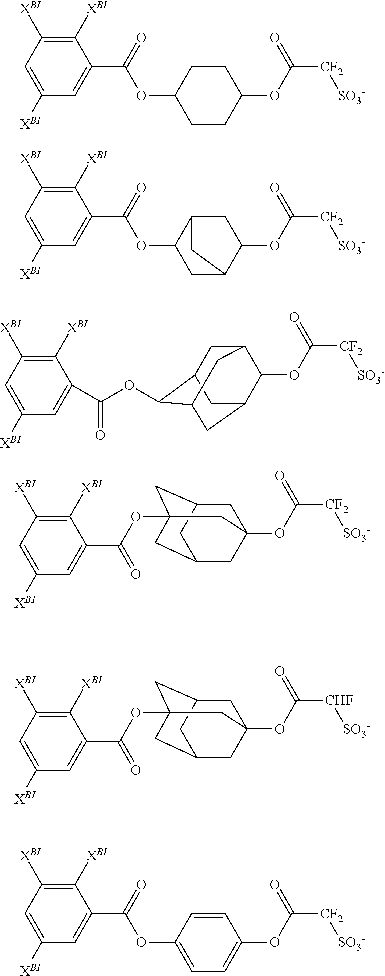

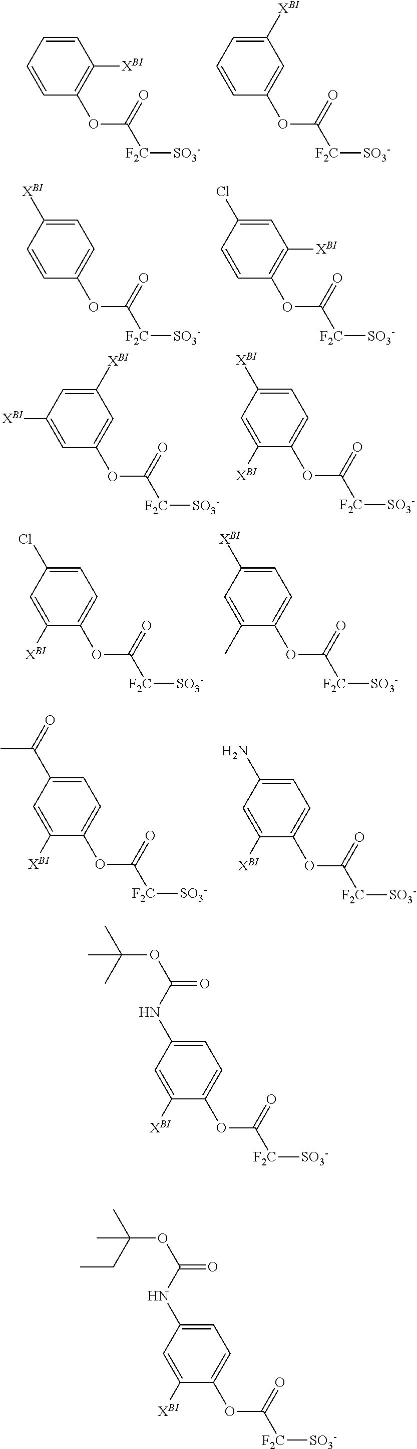

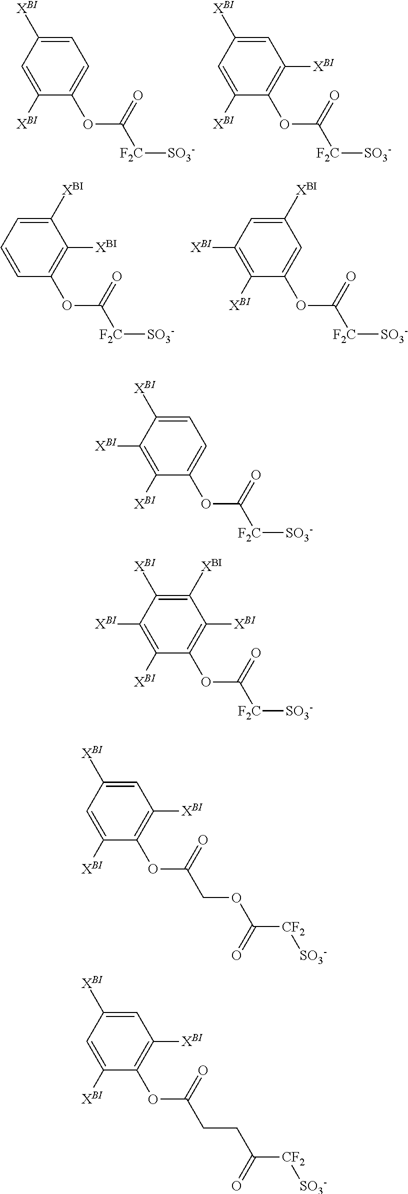

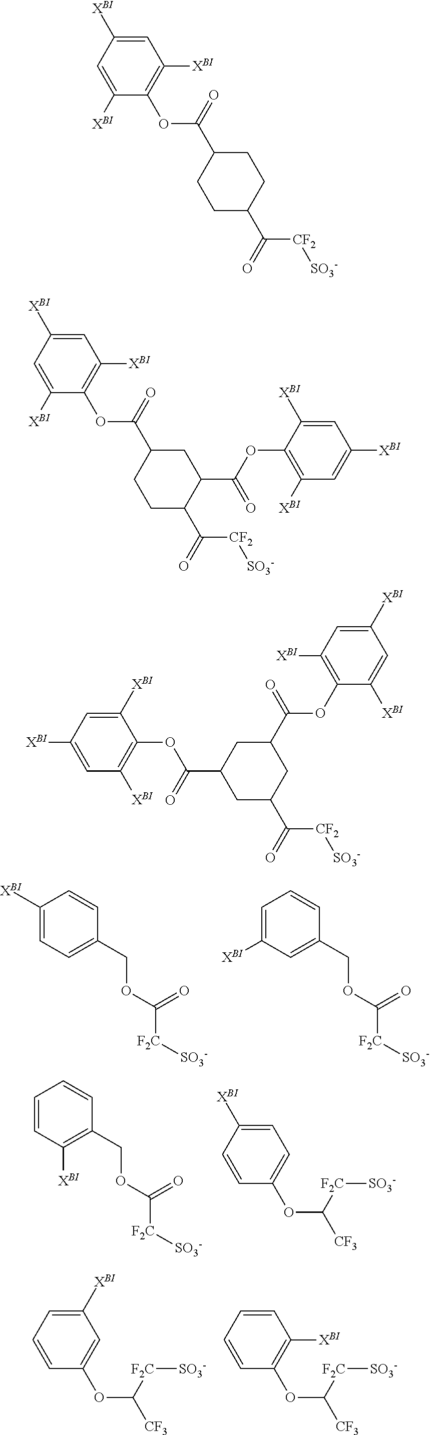

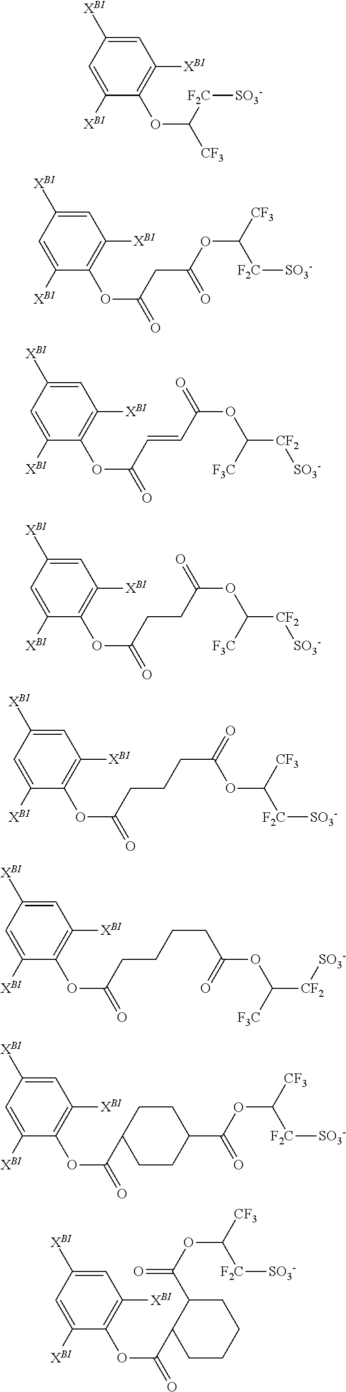

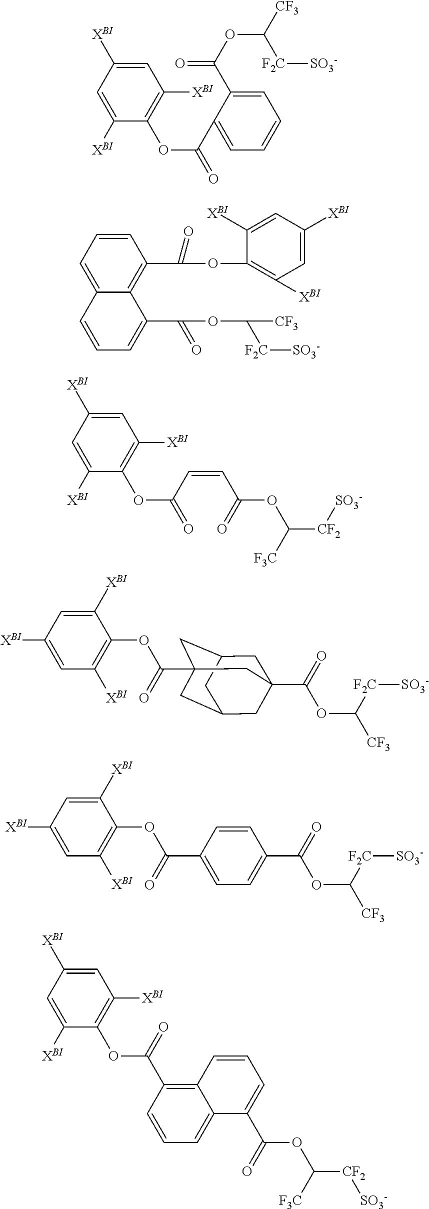

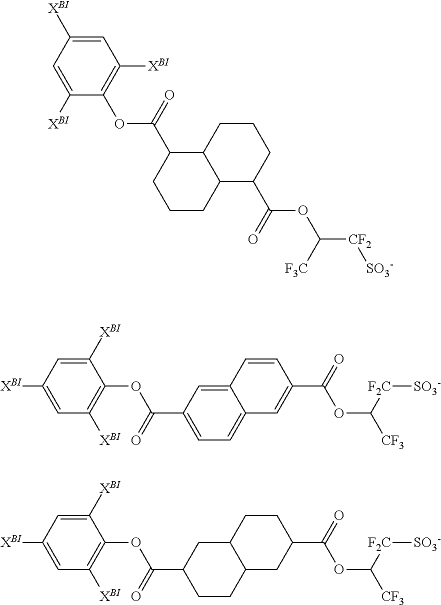

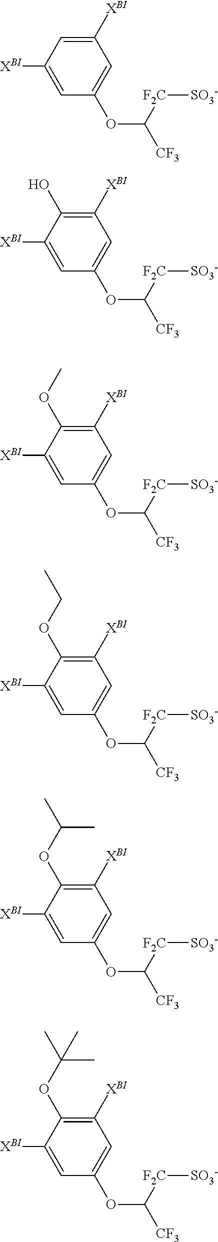

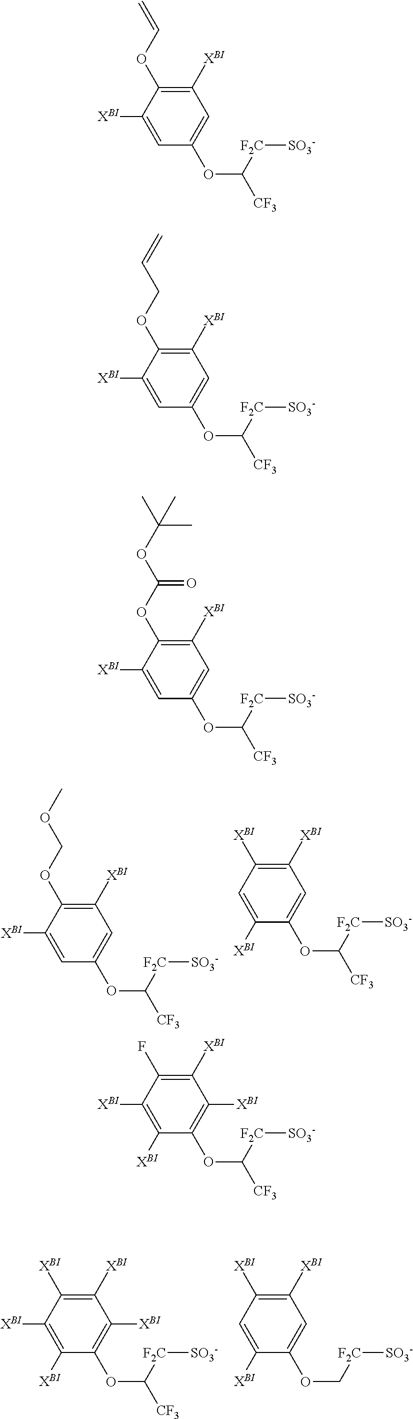

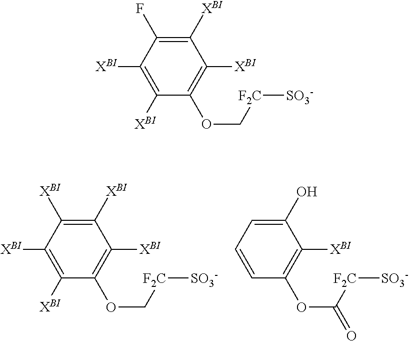

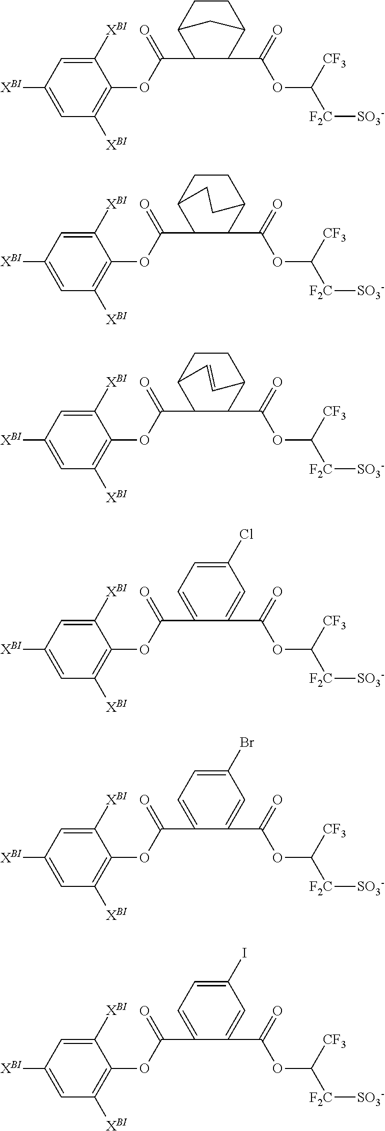

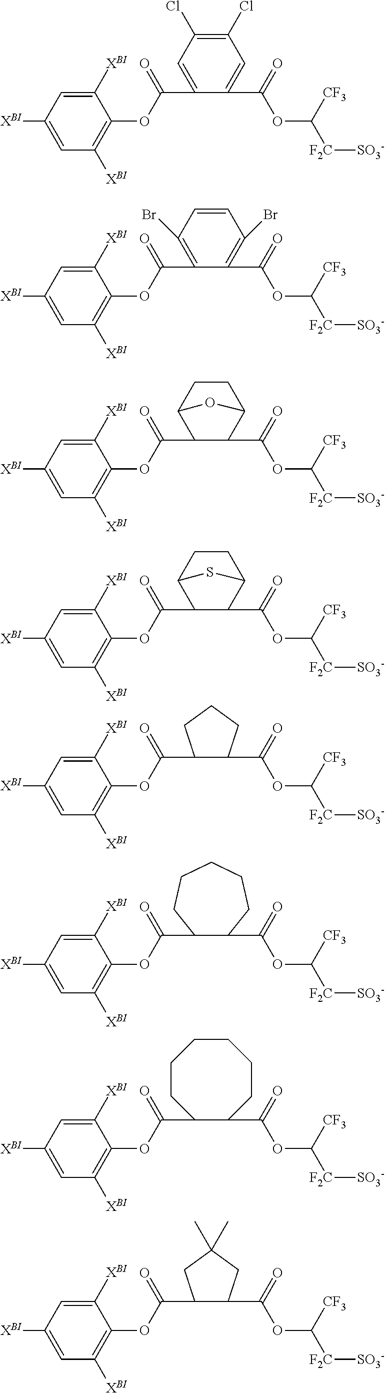

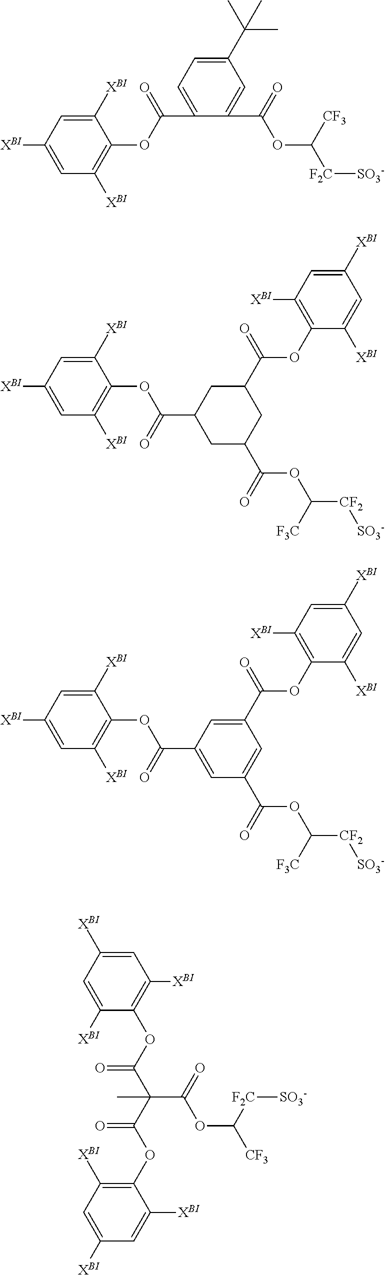

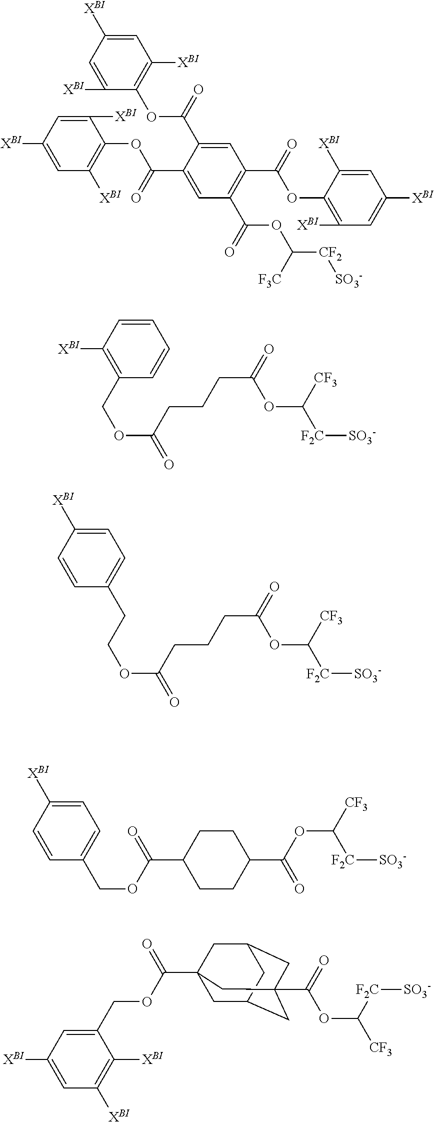

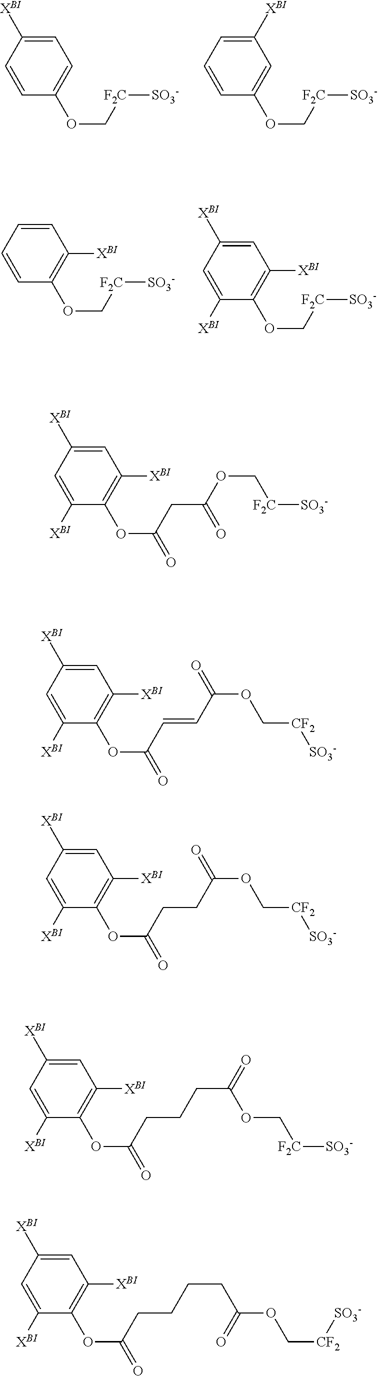

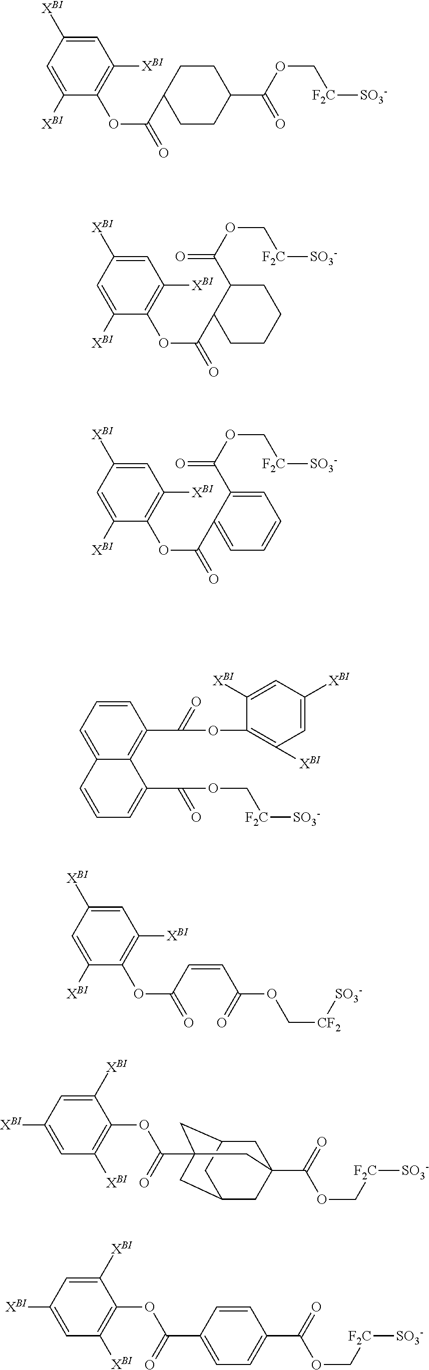

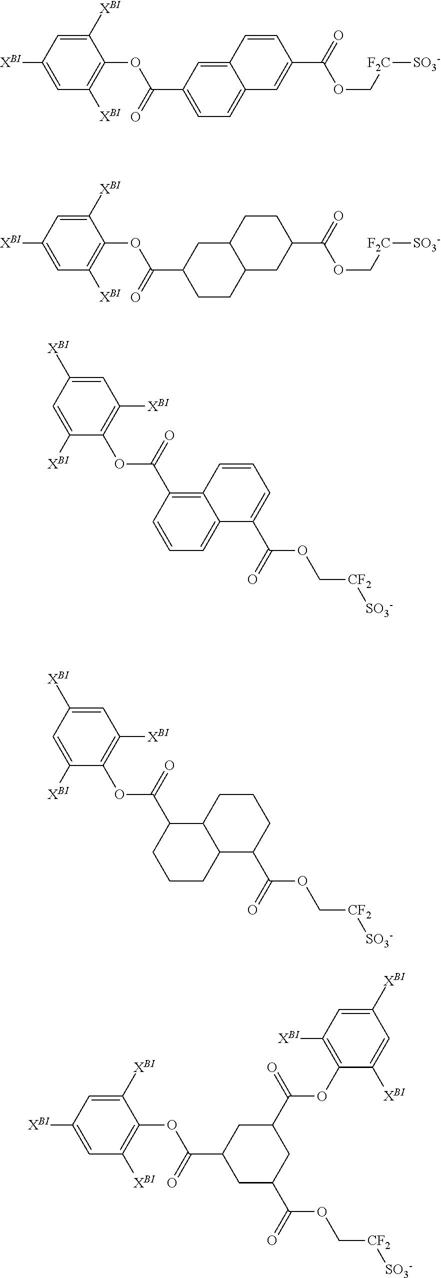

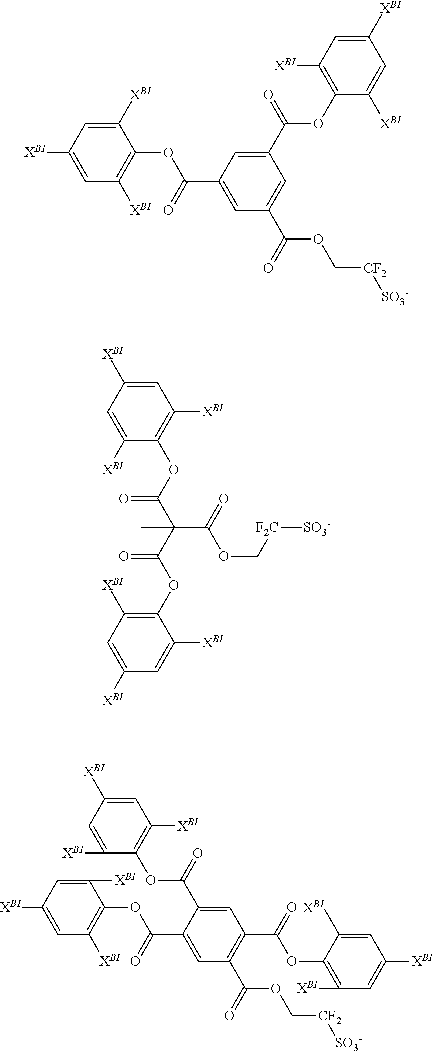

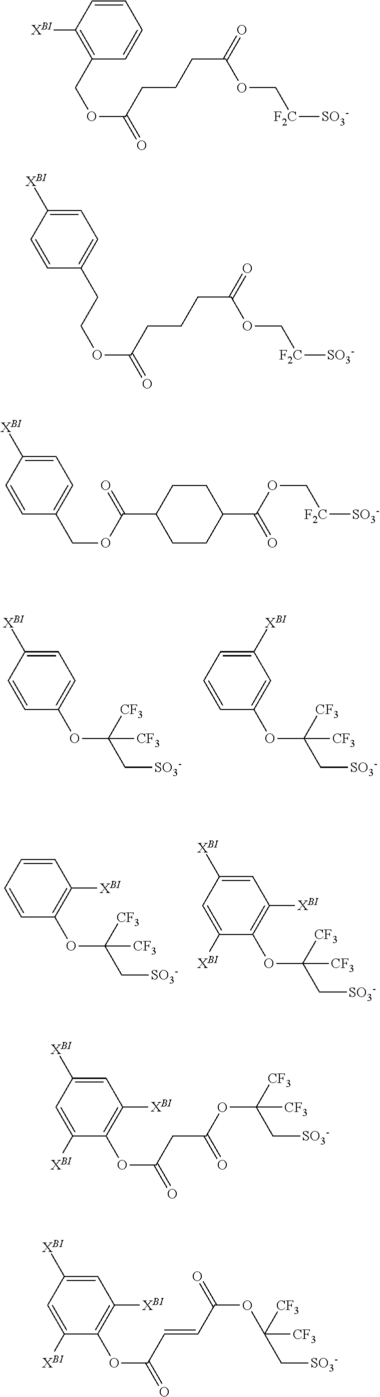

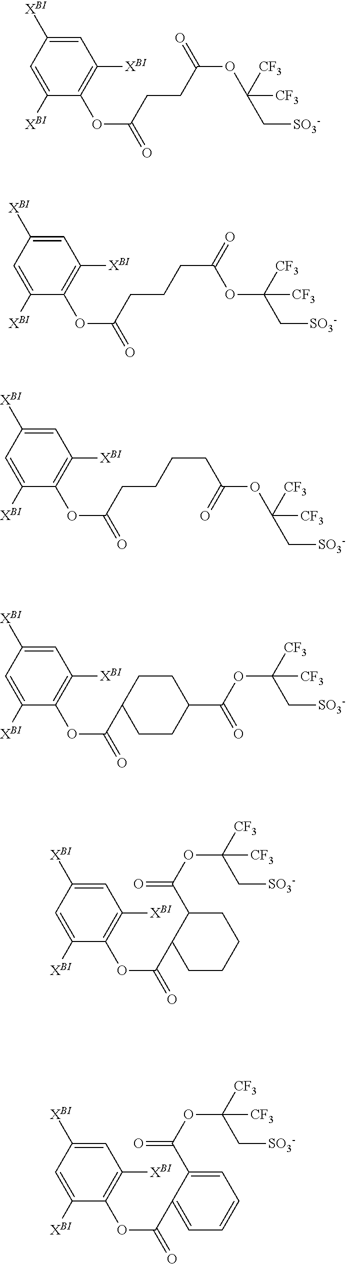

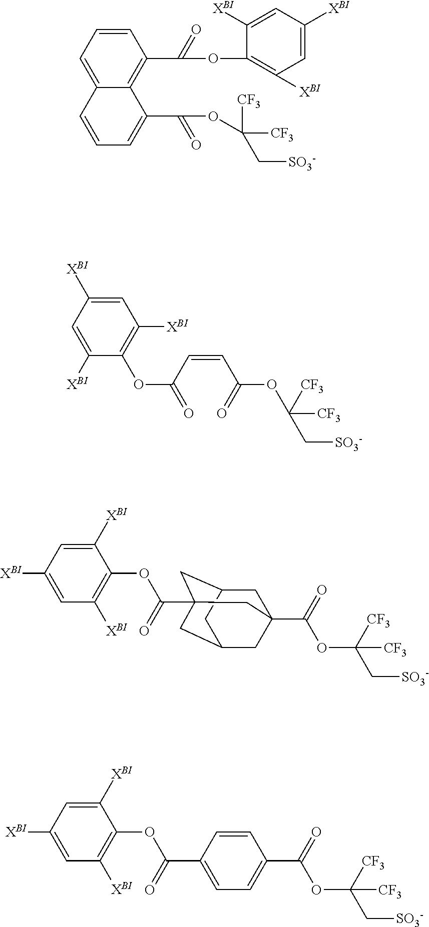

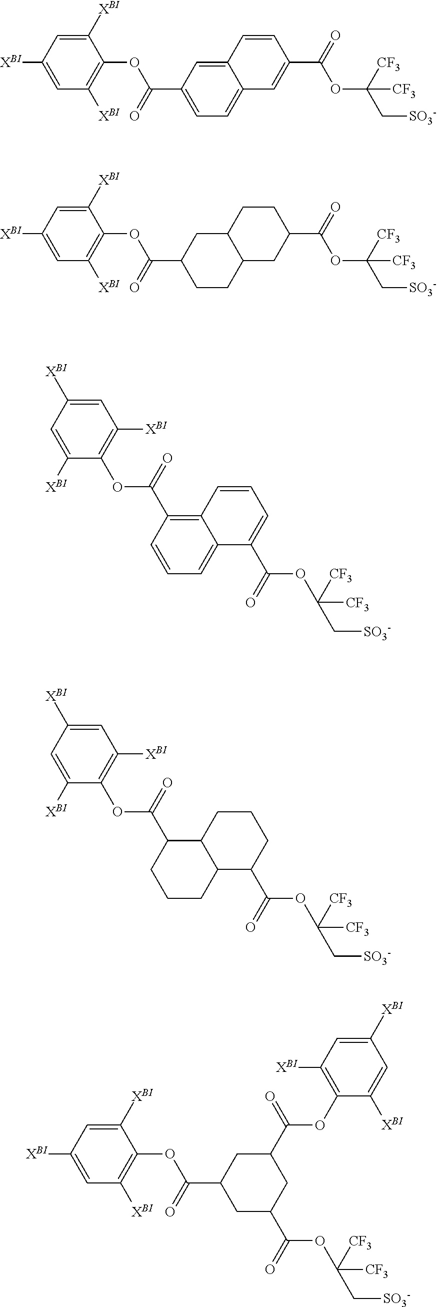

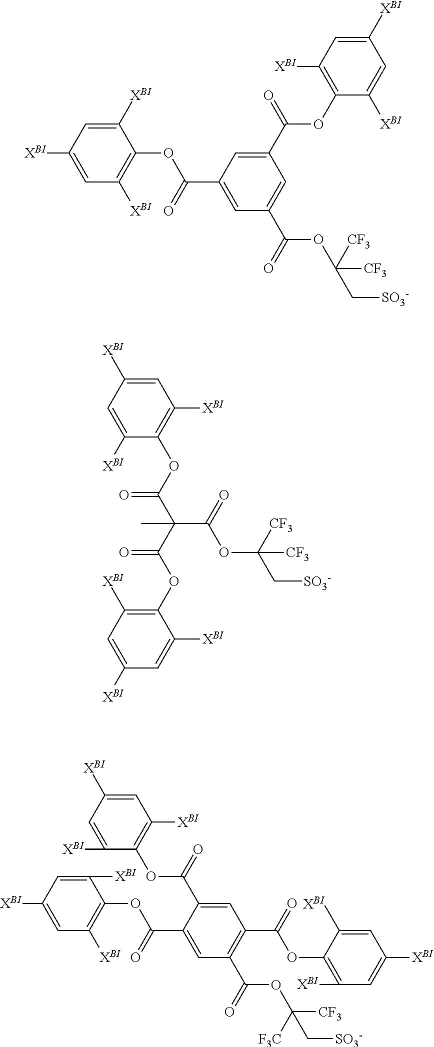

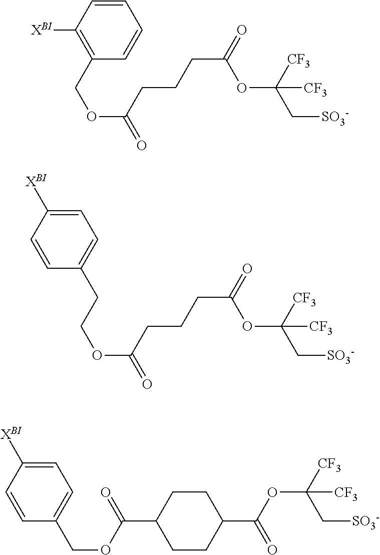

In the resist composition of the present invention, an amount of the addition-type acid generator is preferably 0.1 to 50 parts by mass, more preferably 1 to 40 parts by mass relative to 100 parts by mass of the base polymer. The base polymer contains the repeating units (b1) to (b4) and/or the addition-type acid generator, so that the positive resist composition of the present invention can function as a chemically amplified positive resist composition.

### Quencher

To the resist composition of the present invention, a quencher (hereinafter referred to as other quenchers) may be added. Examples of the quencher include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amides, imides, carbamates, and the like. Particularly, preferred are primary, secondary, and tertiary amine compounds described in paragraphs [0146] to [0164] of JP 2008-111103 A; especially preferred are amine compounds having a hydroxy group, an ether bond, an ester bond, a lactone ring, a cyano group, or a sulfonic acid ester bond, or compounds having a carbamate group described in JP 3790649 B, etc. By adding such basic compounds, for example, it is possible to further reduce a rate of acid diffusion in a resist film and correct the shape.

Additionally, examples of other quenchers include onium salts such as sulfonium salts, iodonium salts, and ammonium salts of sulfonic acid and carboxylic acid which are not fluorinated at a position as described in JP 2008-158339 A. While a-fluorinated sulfonic acid, imide acid, or methide acid is necessary to deprotect an acid labile group of carboxylic acid ester, carboxylic acid or sulfonic acid not fluorinated at a position is released by salt exchange with an onium salt not fluorinated at a position. The sulfonic acid and carboxylic acid not fluorinated at a position do not cause deprotection reaction, and thus function as quenchers. Additionally, examples of other quenchers include an onium salt of carboxylic acid fluorinated at a position described in JP 5904180 B. Since α-fluorocarboxylic acid has lower acidity than sulfonic acid, it has high quencher ability and enables to form a pattern with favorable roughness and resolution.

The examples of other quenchers further include a polymeric quencher described in JP 2008-239918 A. This is oriented on a resist surface after coating, thereby enhancing rectangularity of the resist after patterning. The polymeric quencher also has effect of preventing film thickness loss of a pattern and rounding of a pattern top when a top coat for immersion exposure is applied.

In the resist composition of the present invention, an amount of other quenchers is preferably 0 to 10 parts by mass, more preferably 0 to 7 parts by mass relative to 100 parts by mass of the base polymer. The quencher can be used alone or in combination of two or more.

### Organic Solvent

To the resist composition of the present invention, an organic solvent may be added. The organic solvent is not particularly limited as long as it is capable of dissolving each of the above-described components and components described later. Examples of such organic solvent include: ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as γ-butyrolactone; and mixed solvents thereof, as described in paragraphs [0144] to [0145] of JP 2008-111103 A.

In the resist composition of the present invention, an amount of the organic solvent is preferably 100 to 10,000 parts by mass, more preferably 200 to 8,000 parts by mass relative to 100 parts by mass of the base polymer.

### Other Components

In addition to the above-described components, a surfactant, a dissolution inhibitor, etc. can appropriately be added in combination depending on the purpose to formulate a positive resist composition. As a result, in an exposed area, a dissolution rate of the base polymer in a developer is accelerated by catalytic reaction, allowing the positive resist composition to have quite high sensitivity. In this case, the resist film has high dissolution contrast and resolution, exposure latitude, excellent process adaptability, and a favorable pattern profile after exposure, while acid diffusion can particularly be suppressed, resulting in a small dimensional difference in sparseness and density. These can make a highly practical and very effective resist material for Very LSI.

Examples of the surfactant include those described in paragraphs [0165] to [0166] of JP 2008-111103 A. By adding the surfactant, it is possible to further enhance or control applicability of the resist material. The surfactant can be used alone or in combination of two or more. In the resist composition of the present invention, an amount of the surfactant is preferably 0.0001 to 10 parts by mass relative to 100 parts by mass of the base polymer.

By adding the dissolution inhibitor, it is possible to further increase difference in the dissolution rates between an exposed area and an unexposed area, and further enhance the resolution.

Examples of the dissolution inhibitor include: a compound containing two or more phenolic hydroxy groups in a molecule, in which 0 to 100 mol % of all the hydrogen atoms of the phenolic hydroxy groups are substituted with acid labile groups, or a compound containing a carboxyl group in a molecule, in which an average ratio of 50 to 100 mol % of all the hydrogen atoms of the carboxyl group are substituted with acid labile groups, each compound having a molecular weight of preferably 100 to 1,000, more preferably 150 to 800. Specific examples thereof include compounds such as bisphenol A, trisphenol, phenolphthalein, cresol novolak, naphthalenecarboxylic acid, adamantanecarboxylic acid, and cholic acid, in which a hydrogen atom of a hydroxy group or carboxy group thereof is substituted with an acid labile group, as described in paragraphs [0155] to [0178] of JP 2008-122932 A, for example.

An amount of the dissolution inhibitor is preferably 0 to 50 parts by mass, more preferably 5 to 40 parts by mass relative to 100 parts by mass of the base polymer. The dissolution inhibitor can be used alone or in combination of two or more.

To the resist composition of the present invention, a water-repellency improver may be added to enhance water repellency on a resist surface after spin coating. The water-repellency improver can be used for immersion lithography with no top coat. The water-repellency improver is preferably a polymer compound containing a fluorinated alkyl group, a polymer compound containing a 1,1,1,3,3,3-hexafluoro-2-propanol residue with a particular structure, and the like, more preferably those exemplified in JP 2007-297590 A, JP 2008-111103 A, etc. The water-repellency improver needs to be dissolved in an organic solvent developer. The above-mentioned water-repellency improver having the specific 1,1,1,3,3,3-hexafluoro-2-propanol residue has favorable solubility in a developer. A polymer compound that contains a repeating unit containing an amino group or an amine salt as the water-repellency improver is highly effective in preventing acid evaporation during post exposure bake (PEB) to prevent opening failure of a hole pattern after development. The water-repellency improver can be used alone or in combination of two or more. In the resist composition of the present invention, an amount of the water-repellency improver is preferably 0 to 20 parts by mass, more preferably 0.5 to 10 parts by mass relative to 100 parts by mass of the base polymer.

To the resist composition of the present invention, acetylene alcohols can also be added. Examples of the acetylene alcohols include those described in paragraphs [0179] to [0182] of JP 2008-122932 A. In the resist composition of the present invention, an amount of the acetylene alcohols is preferably 0 to 5 parts by mass relative to 100 parts by mass of the base polymer.

### Patterning Process

When the resist composition of the present invention is used for producing various integrated circuits, known lithography techniques are applicable.

For example, the positive resist composition of the present invention is applied onto a substrate (such as Si, SiO₂, SiN, SiON, TiN, WSi, BPSG, SOG, and organic antireflective film) for producing an integrated circuit or a substrate (such as Cr, CrO, CrON, MoSi₂, and SiO₂) for producing a mask circuit by an appropriate coating method such as spin coating, roll coating, flow coating, dip coating, spray coating, or doctor coating to have applied film thickness of 0.01 to 2 μm. The resultant may be prebaked on a hot plate preferably at 60 to 150° C. for 10 seconds to 30 minutes, more preferably at 80 to 120° C. for 30 seconds to 20 minutes, thereby forming a resist film.

Next, the resist film is exposed using a high-energy beam. Examples of the high-energy beam include ultraviolet such as i-line, far ultraviolet, electron beam (EB), extreme ultraviolet (EUV) having a wavelength of 3 to 15 nm, X-ray, soft X-ray, excimer laser such as KrF and ArF, γ-ray, synchrotron radiation, and the like. When ultraviolet, far ultraviolet, EUV, X-ray, soft X-ray, excimer laser, γ-ray, synchrotron radiation, or the like is used as the high-energy beam, a mask for forming an intended pattern is used and irradiated with light exposure of preferably about 1 to 200 mJ/cm², more preferably about 10 to 100 mJ/cm². When EB is used as the high-energy beam, the light exposure is preferably about 0.1 to 100 ρC/cm², more preferably about 0.5 to 50 ρC/cm², and writing is performed directly or using a mask for forming an intended pattern. Note that the resist composition of the present invention is particularly suitable for fine patterning with i-line, KrF excimer laser, ArF excimer laser, EB, extreme ultraviolet EUV having a wavelength of 3 to 15 nm, X-ray, soft X-ray, y-ray, or synchrotron radiation among the high-energy beams, and is especially suitable for fine patterning with EB or EUV.

In the patterning process of the present invention, a beam at i-line, a KrF excimer laser beam, an ArF excimer laser beam, an electron beam, or extreme ultraviolet having a wavelength of 3 to 15 nm is usable as the high-energy beam.

After the exposure, PEB may be performed on a hot plate preferably at 50 to 150° C. for 10 seconds to 30 minutes, more preferably at 60 to 120° C. for 30 seconds to 20 minutes.

After the exposure or PEB, development is performed using a developer of an alkaline aqueous solution such as tetramethylammonium hydroxide (TMAH), tetraethylammonium hydroxide (TEAH), tetrapropylammonium hydroxide (TPAH), or tetrabutylammonium hydroxide (TBAH) in an amount of 0.1 to 10% by mass, preferably 2 to 5% by mass, for 3 seconds to 3 minutes, preferably 5 seconds to 2 minutes, in a usual manner such as a dip, puddle, or spray method. As a result, a portion irradiated with the light is dissolved by the developer, while an unexposed portion remains undissolved, thereby forming an intended positive pattern on the substrate.

It is also possible to use a positive resist composition that contains a base polymer containing an acid labile group to perform negative development, thereby obtaining a negative pattern by organic solvent development. Examples of the developer used in this case include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, benzyl formate, phenylethyl formate, methyl 3-phenylpropionate, benzyl propionate, phenylethyl acetate, 2-phenylethyl acetate, and the like. These organic solvents can be used alone or in combination of two or more.

After the development is completed, rinsing is performed. A rinse liquid is preferably a solvent that is miscible with a developer but does not dissolve a resist film. As such solvent, it is preferable to use an alcohol having 3 to 10 carbon atoms, an ether compound having 8 to 12 carbon atoms, alkane, alkene, or alkyne each having 6 to 12 carbon atoms, or an aromatic solvent.

Specific examples of the alcohol having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, 1-octanol, and the like.

Examples of the ether compound having 8 to 12 carbon atoms include di-n-butyl ether, diisobutyl ether, di-sec-butyl ether, di-n-pentyl ether, diisopentyl ether, di-sec-pentyl ether, di-tert-pentyl ether, di-n-hexyl ether, and the like.

Examples of the alkane having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, cyclononane, and the like. Examples of the alkene having 6 to 12 carbon atoms include hexene, heptene, octene, cyclohexene, methylcyclohexene, dimethylcyclohexene, cycloheptene, cyclooctene, and the like. Examples of the alkyne having 6 to 12 carbon atoms include hexyne, heptyne, octyne, and the like.

Examples of the aromatic solvent include toluene, xylene, ethylbenzene, isopropylbenzene, tert-butylbenzene, mesitylene, and the like.

The rinsing can reduce resist pattern collapse and defect formation. Furthermore, the rinsing is not always required, and the amount of the solvent to be used can be reduced by not performing the rinsing.

After the development, a hole pattern or trench pattern can be shrunk by thermal flow, RELACS process, or DSA process. A shrink agent is applied onto the hole pattern, and crosslinking reaction of the shrink agent occurs on the resist surface by diffusion of an acid catalyst from the resist layer during baking, so that the shrink agent is attached to sidewalls of the hole pattern. The baking temperature is preferably 70 to 180° C., more preferably 80 to 170° C., and the time is preferably 10 to 300 seconds. The extra shrink agent is removed to shrink the hole pattern.

### EXAMPLE

Hereinafter, the present invention will be specifically described with reference to Synthesis Examples, Examples, and Comparative Examples. However, the present invention is not limited thereto.

### (1) Synthesis of Monomer

### Synthesis Example 1

The following Monomers 1 to 8 and Comparative Monomer 1 were obtained by ion exchange between a sulfonium salt chloride and an iodine-containing carboxylic acid compound having a polymerizable double bond or a carboxylic acid compound.

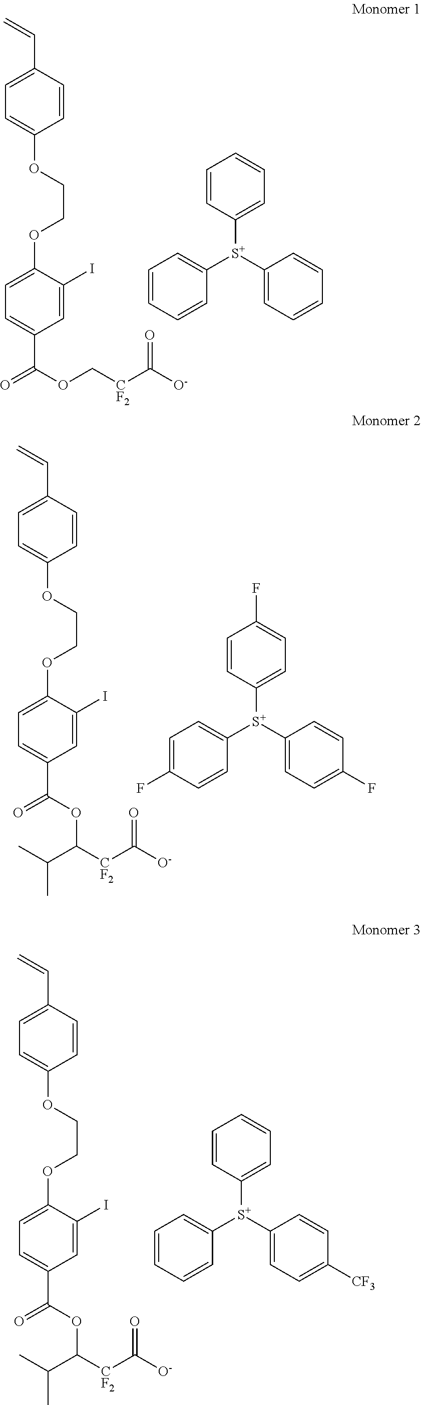 [SMILES: C=Cc1ccc(OCCOc2ccc(C(=O)OCC(F)(F)C(=O)[O-])cc2I)cc1 ; c1ccc([S+](c2ccccc2)c2ccccc2)cc1 ; C=Cc1ccc(OCCOc2ccc(C(=O)OC(C(C)C)C(F)(F)C(=O)[O-])cc2I)cc1 ; Fc1ccc([S+](c2ccc(F)cc2)c2ccc(F)cc2)cc1 ; C=Cc1ccc(OCCOc2ccc(C(=O)OC(C(C)C)C(F)(F)C(=O)[O-])cc2I)cc1 ; FC(F)(F)c1ccc([S+](c2ccccc2)c2ccccc2)cc1]

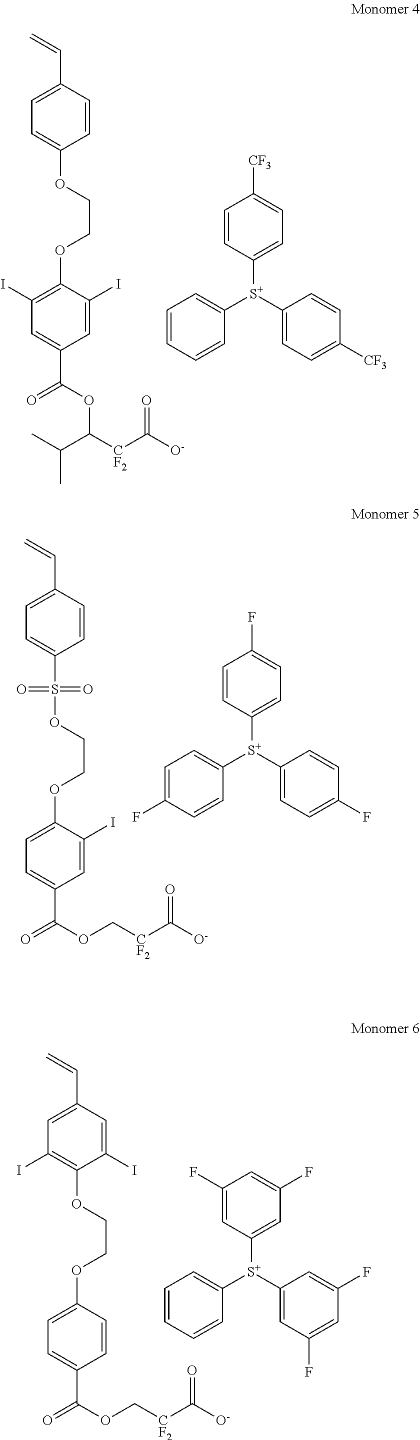 [SMILES: C=Cc1ccc(OCCOc2c(I)cc(C(=O)OC(C(C)C)C(F)(F)C(=O)[O-])cc2I)cc1 ; FC(F)(F)c1ccc([S+](c2ccccc2)c2ccc(C(F)(F)F)cc2)cc1 ; C=Cc1ccc(S(=O)(=O)OCCOc2ccc(C(=O)OCC(F)(F)C(=O)[O-])cc2I)cc1 ; Fc1ccc([S+](c2ccc(F)cc2)c2ccc(F)cc2)cc1 ; C=Cc1cc(I)c(OCCOc2ccc(C(=O)OCC(F)(F)C(=O)[O-])cc2)c(I)c1 ; Fc1cc(F)cc([S+](c2ccccc2)c2cc(F)cc(F)c2)c1]

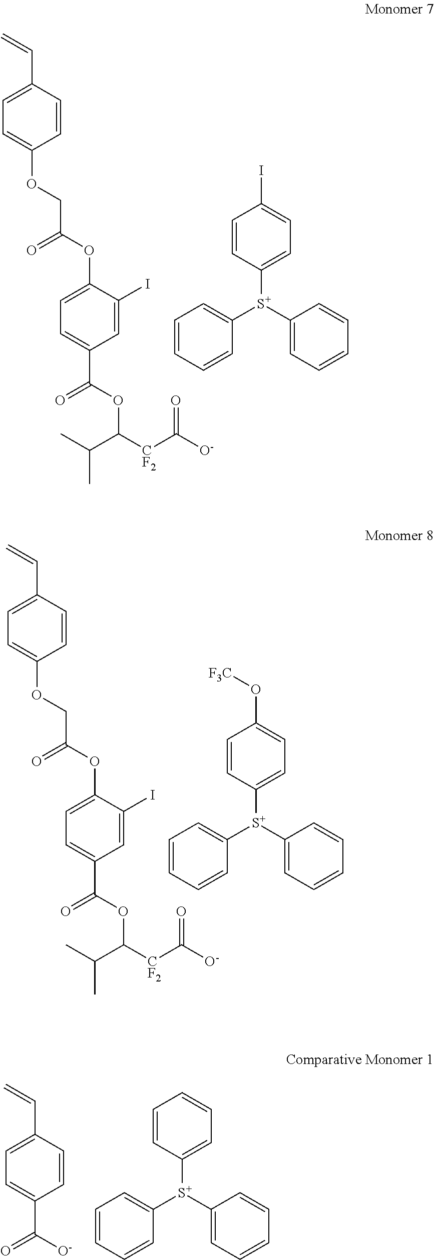 [SMILES: C=Cc1ccc(OCC(=O)Oc2ccc(C(=O)OC(C(C)C)C(F)(F)C(=O)[O-])cc2I)cc1 ; Ic1ccc([S+](c2ccccc2)c2ccccc2)cc1 ; C=Cc1ccc(OCC(=O)Oc2ccc(C(=O)OC(C(C)C)C(F)(F)C(=O)[O-])cc2I)cc1 ; FC(F)(F)Oc1ccc([S+](c2ccccc2)c2ccccc2)cc1 ; C=Cc1ccc(C(=O)[O-])cc1 ; c1ccc([S+](c2ccccc2)c2ccccc2)cc1]

### (2) Synthesis of Polymer

Acid labile group monomers (ALG Monomers 1 to 4) and PAG Monomers 1 to 6 used for synthesis of polymers are shown below. Furthermore, Mw of the polymer is a measured value in terms of polystyrene by GPC using THE as a solvent.

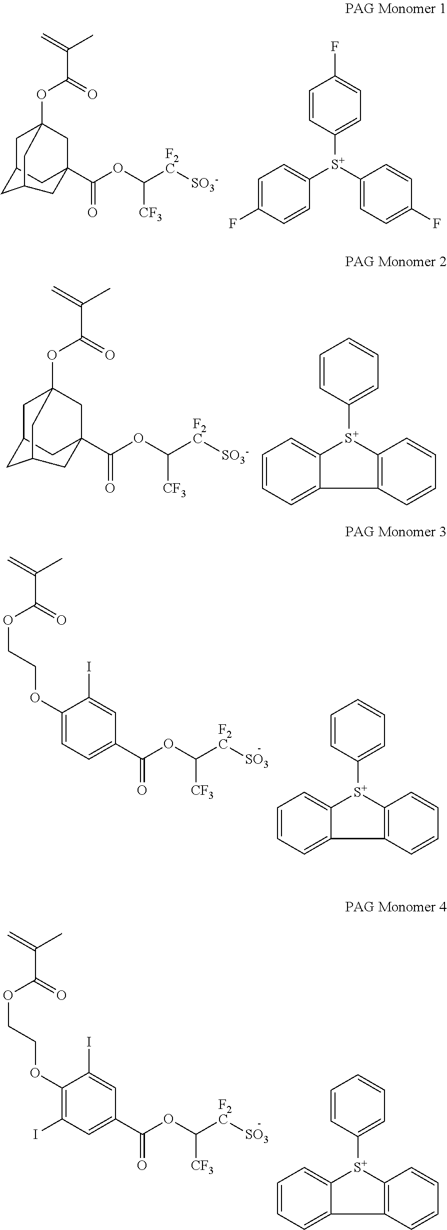

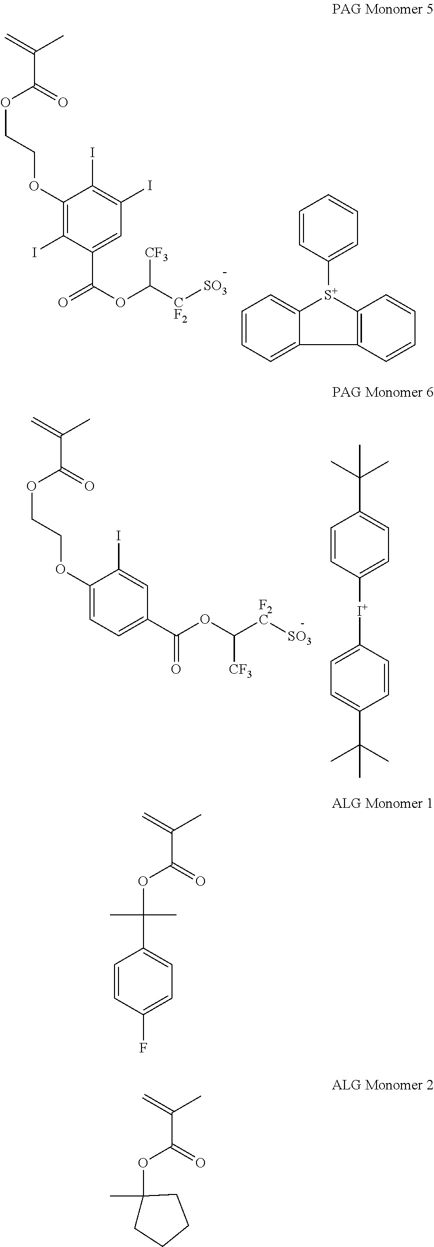

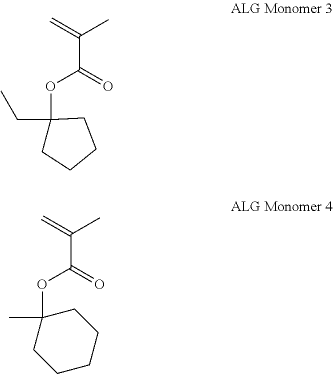

### Synthesis Example 2-1: Synthesis of Polymer 1

A 2 L flask was charged with 3.0 g of Monomer 1, 6.7 g of ALG Monomer 4, 3.3 g of 3-hydroxystyrene, 7.1 g of PAG Monomer 3, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 1. Polymer 1 was analyzed for composition by ¹³C-NMR and ¹H-NMR, and for Mw and Mw/Mn by GPC.

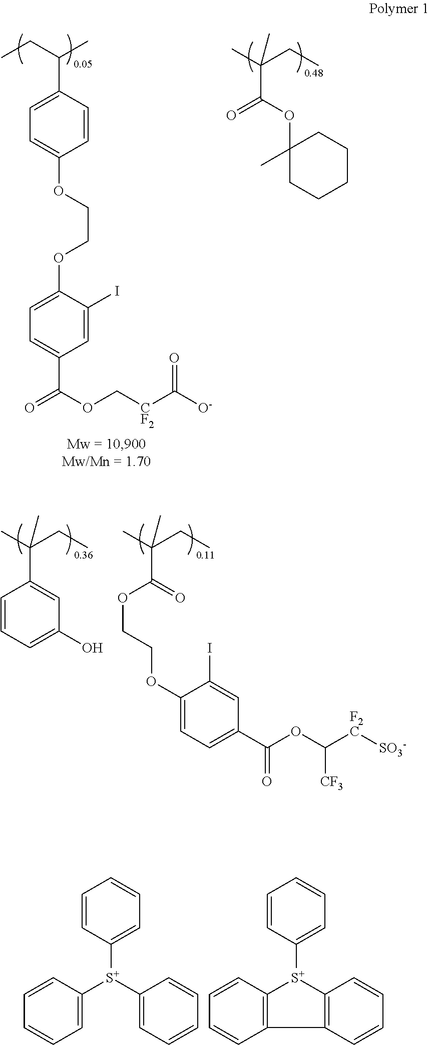

### Synthesis Example 2-2: Synthesis of Polymer 2

A 2 L flask was charged with 3.4 g of Monomer 2, 9.1 g of ALG Monomer 1, 3.3 g of 3-hydroxystyrene, 8.2 g of PAG Monomer 4, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 2. Polymer 2 was analyzed for composition by ¹³C-NMR and ¹H-NMR, and for Mw and Mw/Mn by GPC.

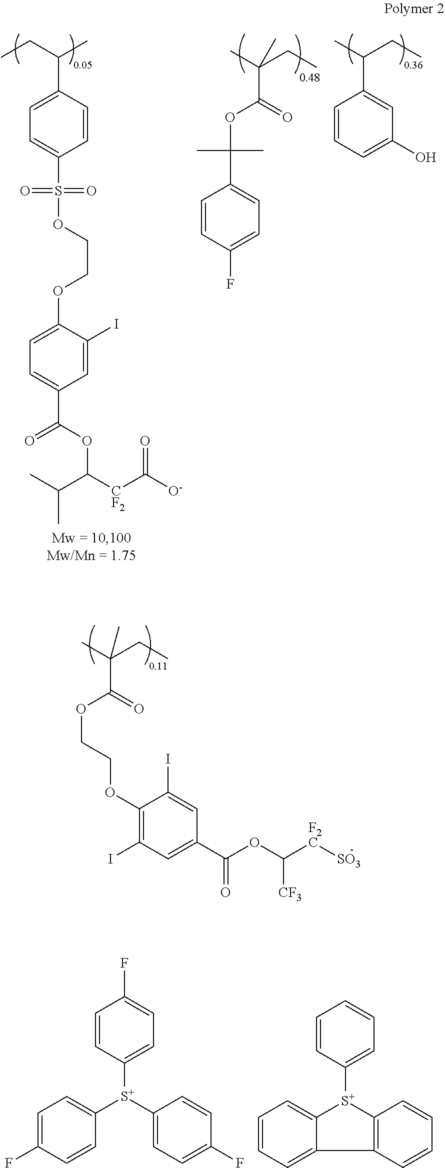

### Synthesis Example 2-3: Synthesis of Polymer 3

A 2 L flask was charged with 3.4 g of Monomer 3, 6.7 g of ALG Monomer 3, 3.7 g of 3-methyl-4-hydroxystyrene, 8.3 g of PAG Monomer 6, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 3. Polymer 3 was analyzed for composition by ¹³C-NMR and ¹H-NMR, and for Mw and Mw/Mn by GPC.

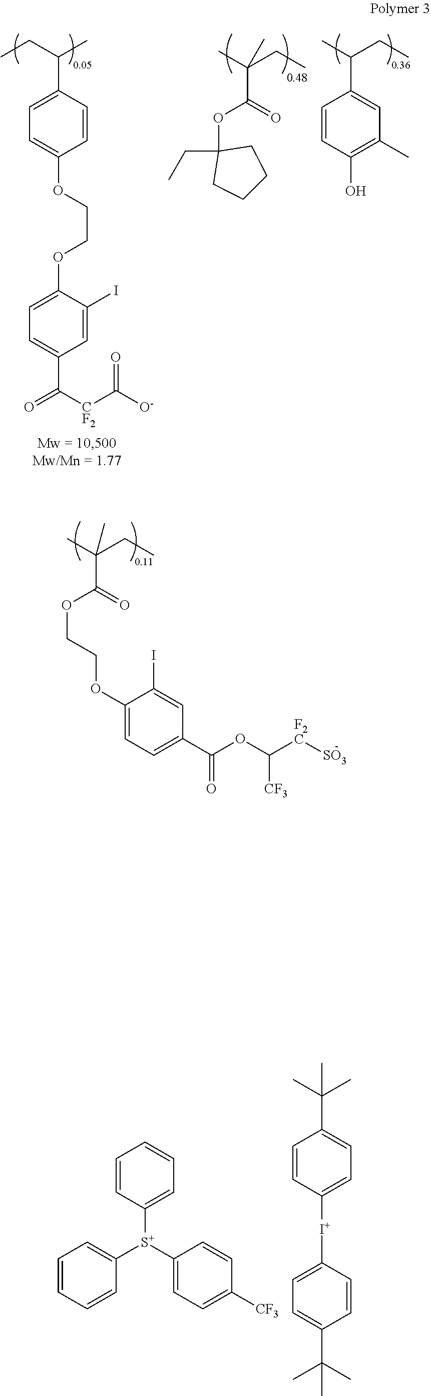

### Synthesis Example 2-4: Synthesis of Polymer 4

A 2 L flask was charged with 5.8 g of Monomer 4, 6.1 g of ALG Monomer 2, 3.3 g of 3-hydroxystyrene, 5.7 g of PAG Monomer 2, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 4. Polymer 4 was analyzed for composition by ¹³C-NMR and ¹H-NMR, and for Mw and Mw/Mn by GPC.

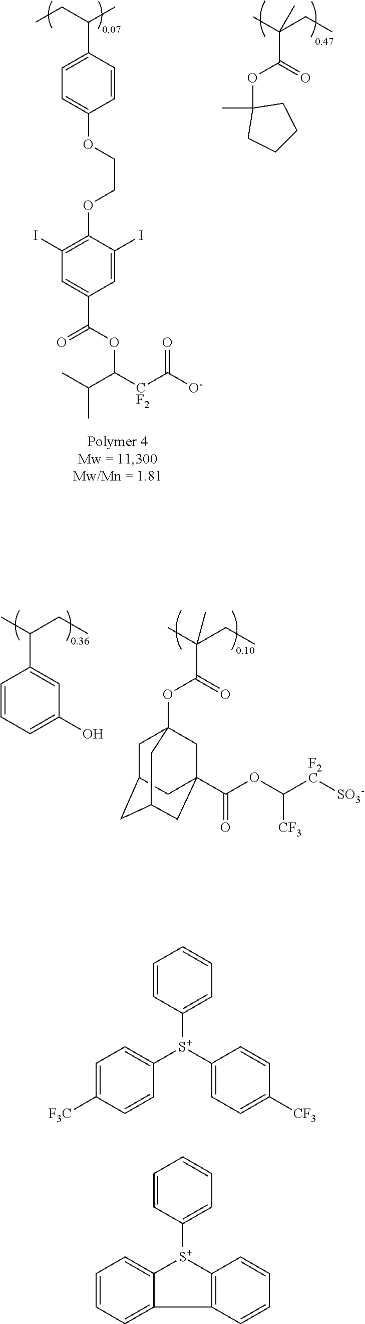

### Synthesis Example 2-5: Synthesis of Polymer 5

A 2 L flask was charged with 4.8 g of Monomer 5, 6.6 g of ALG Monomer 3, 3.3 g of 3-hydroxystyrene, 8.5 g of PAG Monomer 5, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 5. Polymer 5 was analyzed for composition by ¹³C-NMR and ¹H-NMR, and for Mw and Mw/Mn by GPC.

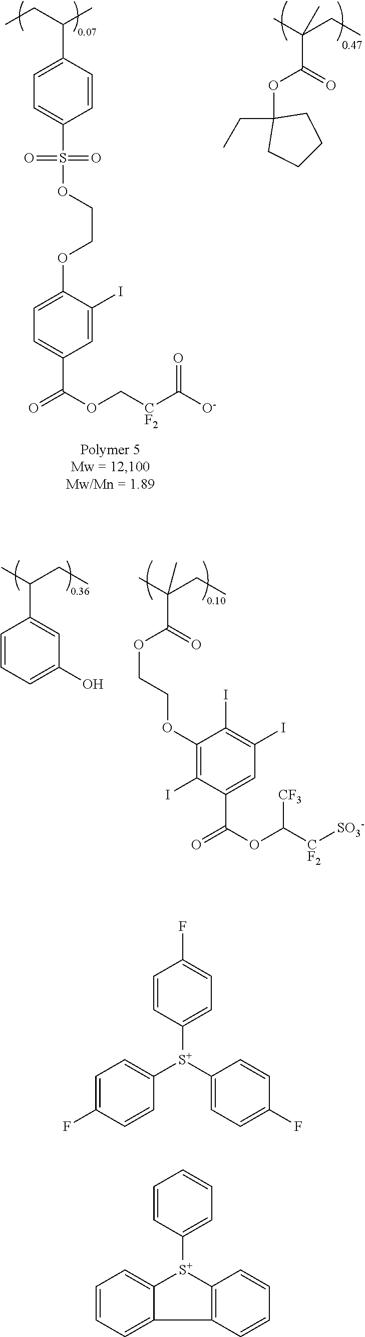

### Synthesis Example 2-6: Synthesis of Polymer 6

A 2 L flask was charged with 5.3 g of Monomer 6, 6.6 g of ALG Monomer 4, 3.3 g of 3-hydroxystyrene, 6.1 g of PAG Monomer 1, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 6. Polymer 6 was analyzed for composition by ¹³C-NMR and ¹H-NMR, and for Mw and Mw/Mn by GPC.

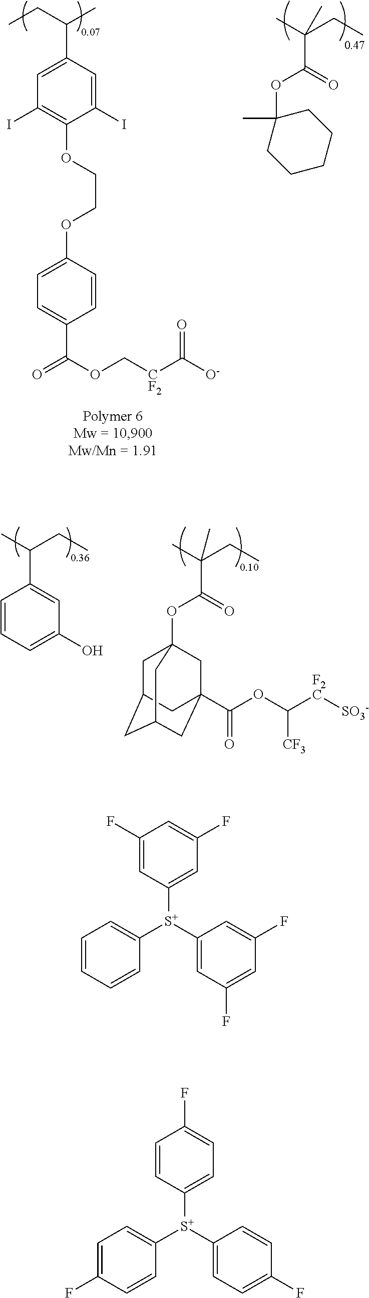

### Synthesis Example 2-7: Synthesis of Polymer 7

A 2 L flask was charged with 3.7 g of Monomer 7, 6.2 g of ALG Monomer 2, 3.3 g of 3-hydroxystyrene, 7.2 g of PAG Monomer 3, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 7. Polymer 7 was analyzed for composition by ¹³C-NMR and ¹H-NMR, and for Mw and Mw/Mn by GPC.

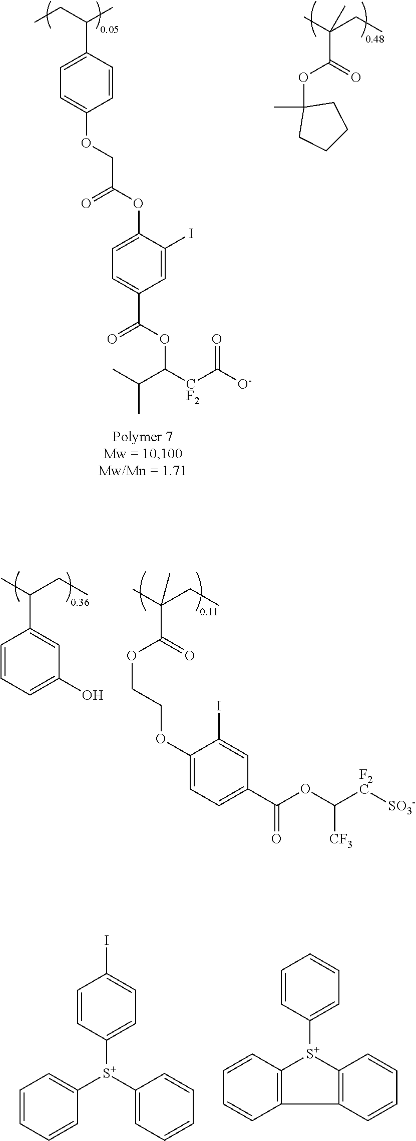

### Synthesis Example 2-8: Synthesis of Polymer 8

A 2 L flask was charged with 3.5 g of Monomer 8, 6.2 g of ALG Monomer 2, 3.3 g of 3-hydroxystyrene, 7.2 g of PAG Monomer 3, and 40 g of THF as a solvent. This reaction vessel was cooled to −70° C. under a nitrogen atmosphere, and deaeration under reduced pressure and nitrogen blow were repeated three times. After raising the temperature to a room temperature, 1.2 g of AIBN as a polymerization initiator was added, the temperature was raised to 60° C., and reaction was performed for 15 hours. This reaction solution was added to 1 L of isopropyl alcohol, and a precipitated white solid was separated by filtration. The white solid thus obtained was dried under reduced pressure at 60° C., thereby obtaining Polymer 8. Polymer 8 was analyzed for composition by ¹³C-NMR and ¹H-NMR, and for Mw and Mw/Mn by GPC.

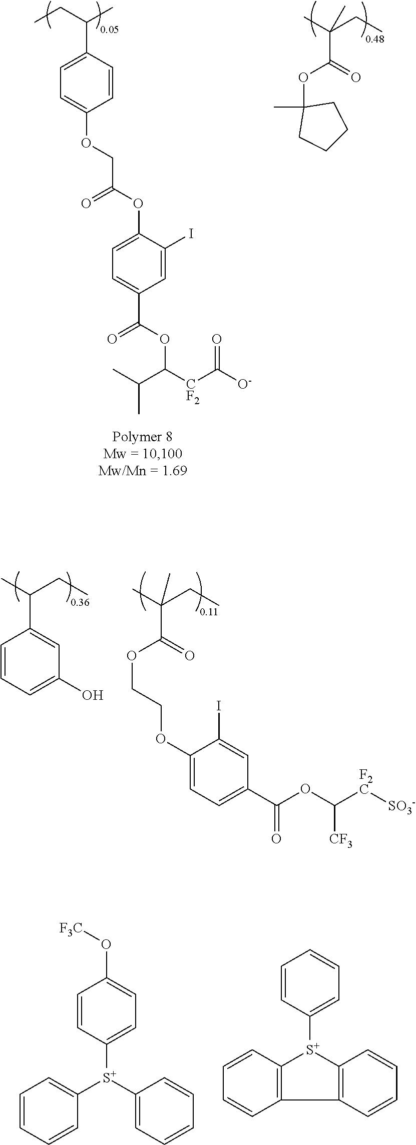

### Comparative Synthesis Example 1: Synthesis of Comparative Polymer 1

Comparative Polymer 1 was obtained in the same manner as in Synthesis Example 2-2 except that Monomer 2 was not used. Comparative Polymer 1 was analyzed for composition by ¹³C-NMR and ¹H-NMR, and for Mw and Mw/Mn by GPC.

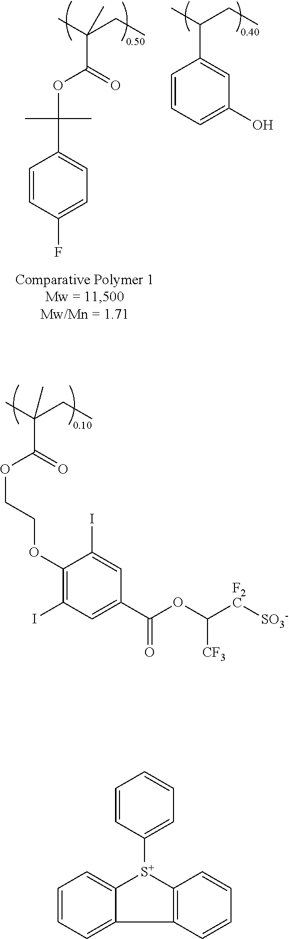

### Comparative Synthesis Example 2: Synthesis of Comparative Polymer 2

Comparative Polymer 2 was obtained in the same manner as in Synthesis Example 2-4 except that Comparative Monomer 1 was used instead of Monomer 4. Comparative Polymer 2 was analyzed for composition by ¹³C-NMR and ¹H-NMR, and for Mw and Mw/Mn by GPC.

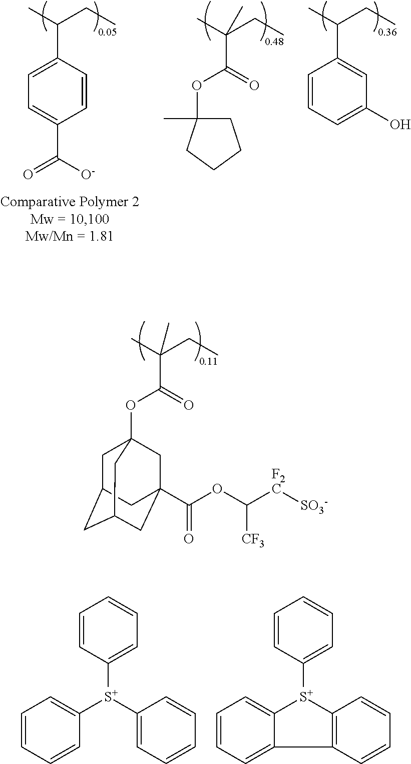

### Comparative Synthesis Example 3: Synthesis of Comparative Polymer 3

Comparative Polymer 3 was obtained in the same manner as in Synthesis Example 2-4 except that Monomer 4 and PAG monomer 2 were not used. Comparative Polymer 3 was analyzed for composition by ¹³C-NMR and ¹H-NMR, and for Mw and Mw/Mn by GPC.

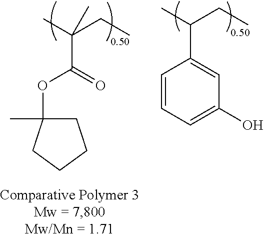

### Examples 1-17, Comparative Examples 1-3

In a solvent containing 50 ppm of a dissolved surfactant Polyfox 636 produced by Omnova Solutions Inc., respective components were dissolved in accordance with the compositions shown in Tables 1 and 2, and the resulting solution was filtered through a 0.2 μm size filter, thereby preparing a positive resist composition.

The respective components in Tables 1 and 2 are as follows.
Organic solvent: PGMEA (propylene glycol monomethyl ether acetate)
DAA (diacetone alcohol)
EL (ethyl lactate)

Shown in parentheses in the table is parts by mass of each solvent.
Acid generator: PAG-1 (see the following structural formula)
Quencher: Q-1 to Q-6

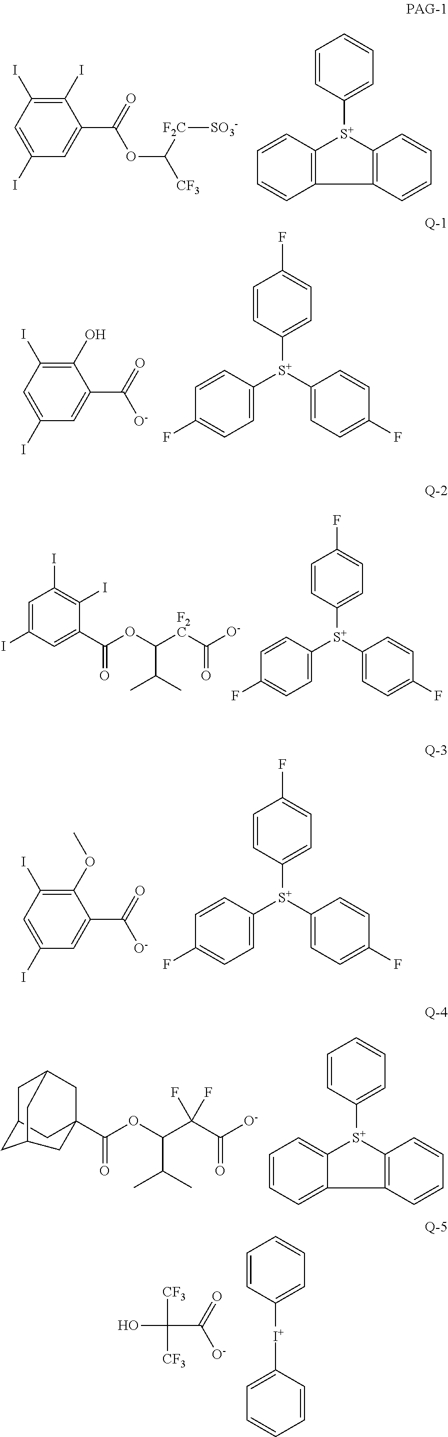

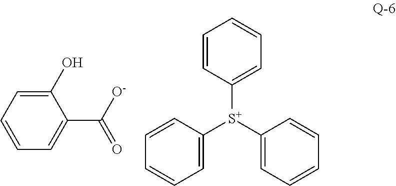 [SMILES: O=C([O-])c1ccccc1O ; c1ccc([S+](c2ccccc2)c2ccccc2)cc1]

### EUV Exposure Evaluation

Each of the resist compositions shown in Tables 1 and 2 was spin coated on a Si substrate, on which a silicon-containing spin-on hard mask SHB-A940 (silicon content of 43% by mass) was formed to have a film thickness of 20 nm, and prebaked on a hot plate at 105° C. for 60 seconds to form a resist film having a film thickness of 50 nm. This resist film was exposed using an EUV scanner NXE34000 produced by ASML Holding N.V. (NA 0.33, σ 0.9/0.6, quadrupole illumination, a mask bearing a hole pattern at a pitch 46 nm on-wafer size and +20% bias), subjected to PEB on a hot plate at the temperature shown in Tables 1 and 2 for 60 seconds, and developed in a 2.38% by mass of TMAH aqueous solution for 30 seconds, thereby obtaining a hole pattern having a dimension of 23 nm.

Light exposure at which each dimension of a formed hole was 23 nm was measured and reported as sensitivity. Additionally, using a CD-SEM (CG6300) produced by Hitachi Ltd., the dimensions of 50 holes were measured and CDU (dimensional variation 3σ) was determined. The results are shown in Tables 1 and 2.

TABLE 1

| | Polymer | Acid | | | | | |
|---|---|---|---|---|---|---|---|
| | (parts | generator | Quencher | | PEB | | |
| | by | (parts by | (parts | Organic | temperature | Sensitivity | CDU |
| | mass) | mass) | by mass) | solvent | (° C.) | (mJ/cm²) | (nm) |
| Example | Polymer | — | — | PGMEA (2000) | 80 | 30 | 2.6 |
| 1 | 1 | | | DAA (500) | | | |
| | (80) | | | EL (2500) | | | |
| Example | Polymer | — | — | PGMEA (2000) | 80 | 31 | 2.7 |
| 2 | 2 | | | DAA (500) | | | |
| | (80) | | | EL (2500) | | | |
| Example | Polymer | — | — | PGMEA (2000) | 80 | 32 | 2.8 |
| 3 | 3 | | | DAA (500) | | | |
| | (80) | | | EL (2500) | | | |
| Example | Polymer | — | — | PGMEA (2000) | 80 | 35 | 2.9 |
| 4 | 4 | | | DAA (500) | | | |
| | (80) | | | EL (2500) | | | |
| Example | Polymer | — | — | PGMEA (2000) | 80 | 35 | 2.7 |
| 5 | 5 | | | DAA (500) | | | |
| | (80) | | | EL (2500) | | | |
| Example | Polymer | — | — | PGMEA (2000) | 80 | 34 | 2.9 |
| 6 | 6 | | | DAA (500) | | | |
| | (80) | | | EL (2500) | | | |
| Example | Polymer | | | PGMEA (2000) | 80 | 32 | 2.5 |
| 7 | 7 | | | DAA (500) | | | |
| | (80) | | | EL (2500) | | | |
| Example | Polymer | | | PGMEA (2000) | 80 | 32 | 2.6 |
| 8 | 8 | | | DAA (500) | | | |
| | (80) | | | EL (2500) | | | |
| Example | Polymer | — | Q-1 | PGMEA (2000) | 80 | 36 | 2.6 |
| 9 | 1 | | (1) | DAA (500) | | | |
| | (80) | | | EL (2500) | | | |
| Example | Polymer | — | Q-2 | PGMEA (2000) | 80 | 35 | 2.5 |
| 10 | 2 | | (2) | DAA (500) | | | |
| | (80) | | | EL (2500) | | | |
| Example | Polymer | — | Q-3 | PGMEA (2000) | 80 | 37 | 2.7 |
| 11 | 3 | | (1.5) | DAA (500) | | | |
| | (80) | | | EL (2500) | | | |
| Example | Polymer | — | Q-4 | PGMEA (2000) | 95 | 38 | 2.9 |
| 12 | 4 | | (1.5) | DAA (500) | | | |
| | (80) | | | EL (2500) | | | |
| Example | Polymer | — | Q-5 | PGMEA (2000) | 95 | 37 | 2.8 |
| 13 | 5 | | (1) | DAA (500) | | | |
| | (80) | | | EL (2500) | | | |
| Example | Polymer | — | Q-6 | PGMEA (2000) | 95 | 38 | 2.9 |
| 14 | 6 | | (1) | DAA (500) | | | |
| | (80) | | | EL (2500) | | | |
| Example | Polymer | PAG-1 | Q-1 | PGMEA (2000) | 80 | 38 | 2.7 |
| 15 | 1 | (5) | (5) | DAA (500) | | | |
| | (80) | | | EL (2500) | | | |
| Example | Polymer | PAG-1 | Q-2 | PGMEA (2000) | 80 | 39 | 2.6 |
| 16 | 2 | (5) | (7) | DAA (500) | | | |
| | (80) | | | EL (2500) | | | |
| Example | Polymer | PAG-1 | Q-3 | PGMEA (2000) | 80 | 37 | 2.7 |
| 17 | 7 | (5) | (5) | DAA (500) | | | |
| | (80) | | | EL (2500) | | | |

TABLE 2

| | | Acid | | | | | |
|---|---|---|---|---|---|---|---|
| | Polymer | generator | Quencher | | PEB | | |
| | (parts by | (parts by | (parts | Organic | temperature | Sensitivity | CDU |
| | mass ) | mass) | by mass) | solvent | (° C.) | (mJ/cm²) | (nm) |
| Comp. | Comparative | — | Q-6 | PGMEA (2000) | 80 | 35 | 3.5 |
| Ex. 1 | Polymer 1 | | (8.0) | DAA (500) | | | |
| | (80) | | | EL (2500) | | | |
| Comp. | Comparative | — | — | PGMEA (2000) | 80 | 41 | 4.0 |
| Ex. 2 | Polymer 2 | | | DAA (500) | | | |
| | (80) | | | EL (2500) | | | |
| Comp. | Comparative | PAG-1 | Q-6 | PGMEA (2000) | 80 | 37 | 4.8 |
| Ex. 3 | Polymer 3 | (20.0) | (8.0) | DAA (500) | | | |
| | (80) | | | EL (2500) | | | |

According to the results in Tables 1 and 2, it was found that the resist compositions according to the present invention, including the base polymer containing the repeating unit having a structure of a sulfonium salt or an iodonium salt of carboxylic acid and containing an iodine atom and the repeating unit having a sulfonium salt or an iodonium salt of sulfonic acid achieved sufficient sensitivity as well as dimension uniformity. On the other hand, Comparative Examples 1 to 3 each using the resist composition containing no resist material (base polymer) according to the present invention resulted in poor dimension uniformity.

The present description includes the following embodiments.

[1]: A positive resist material comprising a base polymer with a sulfonium salt or an iodonium salt of carboxylic acid as a pendant group attached to a polymer backbone, wherein the base polymer comprises a repeating unit (a) containing one or more iodine atoms between the polymer backbone and carboxylate, the repeating unit (a) containing one or both of a repeating unit represented by the following general formula (a)-1 and a repeating unit represented by the following general formula (a)-2,

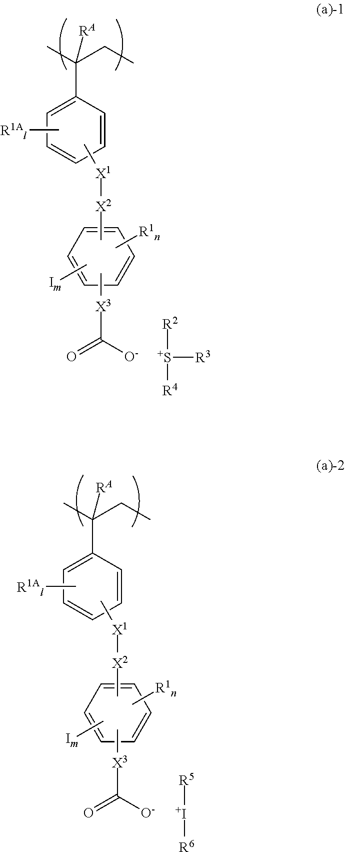

wherein R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{1A} each independently represents a halogen atom, a hydroxy group, or a linear or branched alkoxy group or acyloxy group each having 1 to 6 carbon atoms; “l” represents an integer of 0 to 3; “m” represents an integer of 0 to 4; “n” represents an integer of 0 to 4, provided that an anion moiety of the pendant group contains one or more iodine atoms; and R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto.

[2]: The positive resist material of the above [1], wherein the base polymer further comprises at least one selected from repeating units represented by the following formulae (b1) to (b4),

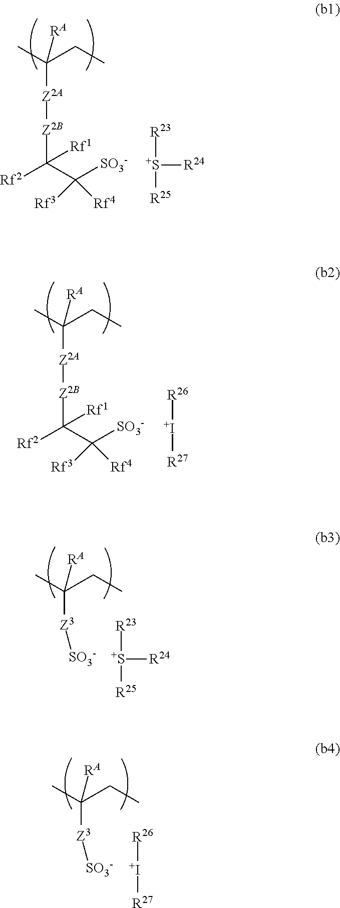

wherein R^{A} each independently represents a hydrogen atom or a methyl group; Z^{2B} represents a single bond or an ester bond; Z^{2B} represents a single bond or a divalent group having 1 to 12 carbon atoms, optionally containing an ester bond, an ether bond, a lactone ring, a bromine atom, or an iodine atom; Z³ represents a single bond, a methylene group, an ethylene group, a phenylene group, a fluorinated phenylene group, —O—Z³¹—, —C(═O)—O—Z³¹—, or —C(═O)—NH—Z³¹—, wherein Z³¹ represents an alkanediyl group having 1 to 6 carbon atoms, an alkenediyl group having 2 to 6 carbon atoms, or a phenylene group, optionally containing a carbonyl group, an ester bond, an ether bond, a halogen atom, or a hydroxy group; each of Rf¹ to Rf⁴ independently represents a hydrogen atom, a fluorine atom, or a trifluoromethyl group, provided that at least one of Rf¹ to Rf⁴ represents a fluorine atom; and each of R²³ to R²⁷ independently represents a monovalent hydrocarbon group having 1 to 20 carbon atoms and optionally having a heteroatom, and optionally any two of R²³, R²⁴, and R²⁵ bond together to form a ring with a sulfur atom attached thereto.

[3]: The positive resist material of the above [2], wherein the Z^{2B} comprises one or more iodine atoms.

[4]: The positive resist material of any one of the above [1] to [3], further comprising a repeating unit (c) in which a hydrogen atom of one or both of a carboxy group and a phenolic hydroxy group is substituted with an acid labile group.

[5]: The positive resist material of the above [4], wherein the repeating unit (c) is at least one selected from a repeating unit (c1) represented by the following formula (c1) and a repeating unit (c2) represented by the following formula (c2),

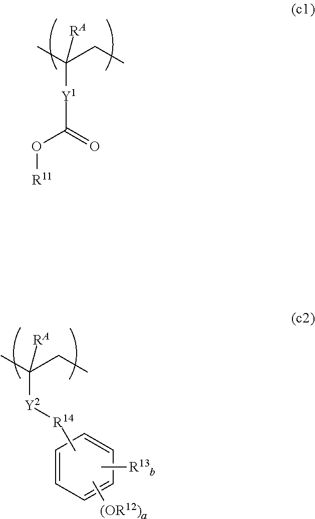

wherein R^{A} each independently represents a hydrogen atom or a methyl group; Y¹ represents a single bond, a phenylene group, a naphthylene group, or a linking group having 1 to 12 carbon atoms and having an ester bond, an ether bond, or a lactone ring; Y² represents a single bond, an ester bond, or an amide bond; R¹¹ and R¹² represent an acid labile group; R¹³ represents a fluorine atom, a trifluoromethyl group, a cyano group, or an alkyl group having 1 to 6 carbon atoms; R¹⁴ represents a single bond, or a linear or branched alkanediyl group having 1 to 6 carbon atoms, in which some of carbon atoms thereof are optionally substituted with an ether bond or an ester bond; “a” represents 1 or 2; and “b” represents an integer of 0 to 4.

[6]: The positive resist material of any one of the above [1] to [5], wherein the base polymer further comprises a repeating unit (d) comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester bond, a cyano group, an amide group, —O—C(═O)—S—, and —O—C(═O)—NH—.

[7]: The positive resist material of any one of the above [1] to [6], wherein the base polymer has a weight average molecular weight in a range of 1000 to 100000.

[8]: A positive resist composition comprising the positive resist material of any one of the above [1] to [7].

[9]: The positive resist composition of the above [8], further comprising one or more selected from an acid generator, an organic solvent, a quencher, and a surfactant.

[10]: A patterning process comprising steps of: forming a resist film on a substrate using the positive resist composition of the above [8] or [9]; exposing the resist film to a high-energy beam; and developing the exposed resist film using a developer.

[11]: The patterning process of the above [10], wherein the high-energy beam is a beam at i-line, a KrF excimer laser beam, an ArF excimer laser beam, an electron beam, or extreme ultraviolet having a wavelength of 3 to 15 nm. [12]: A polymer compound having a weight average molecular weight in a range of 1000 to 100000, comprising a copolymer containing one or both of a repeating unit represented by the following general formula (a)-1 and a repeating unit represented by the following general formula (a)-2, and one or more repeating units selected from the following general formulae (b1) to (b4),

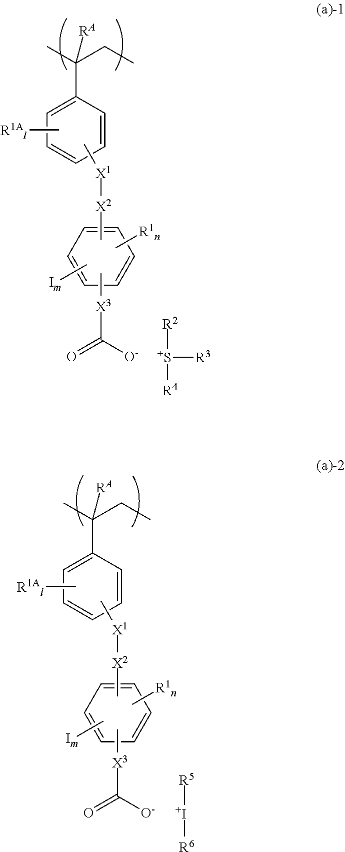

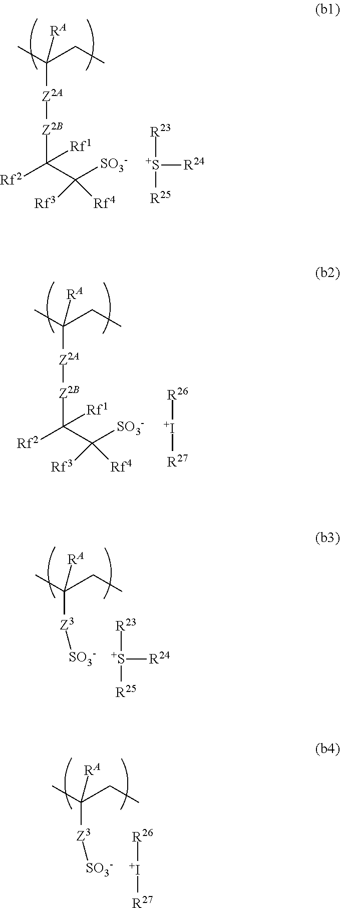

wherein R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{1A} each independently represents a halogen atom, a hydroxy group, or a linear or branched alkoxy group or acyloxy group each having 1 to 6 carbon atoms; “l” represents an integer of 0 to 3; “m” represents an integer of 0 to 4; “n” represents an integer of 0 to 4, provided that an anion moiety of the pendant group contains one or more iodine atoms; R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto; Z^{2A} represents a single bond or an ester bond; Z^{2B} represents a single bond or a divalent group having 1 to 12 carbon atoms, optionally containing an ester bond, an ether bond, a lactone ring, a bromine atom, or an iodine atom; Z³ represents a single bond, a methylene group, an ethylene group, a phenylene group, a fluorinated phenylene group, —O—Z³¹—, —C(═O)—O—Z³¹—, or —C(═O)—NH—Z³¹—, wherein Z³¹ represents an alkanediyl group having 1 to 6 carbon atoms, an alkenediyl group having 2 to 6 carbon atoms, or a phenylene group, optionally containing a carbonyl group, an ester bond, an ether bond, a halogen atom, or a hydroxy group; each of Rf¹ to Rf⁴ independently represents a hydrogen atom, a fluorine atom, or a trifluoromethyl group, provided that at least one of Rf¹ to Rf⁴ represents a fluorine atom; and each of R²³ to R²⁷ independently represents a monovalent hydrocarbon group having 1 to 20 carbon atoms and optionally having a heteroatom, and optionally any two of R²³, R²⁴, and R²⁵ bond together to form a ring with a sulfur atom attached thereto.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A positive resist material comprising a base polymer with a sulfonium salt or an iodonium salt of carboxylic acid as a pendant group attached to a polymer backbone, wherein the base polymer comprises a repeating unit (a) containing one or more iodine atoms between the polymer backbone and carboxylate, the repeating unit (a) containing one or both of a repeating unit represented by the following general formula (a)-1 and a repeating unit represented by the following general formula (a)-2, 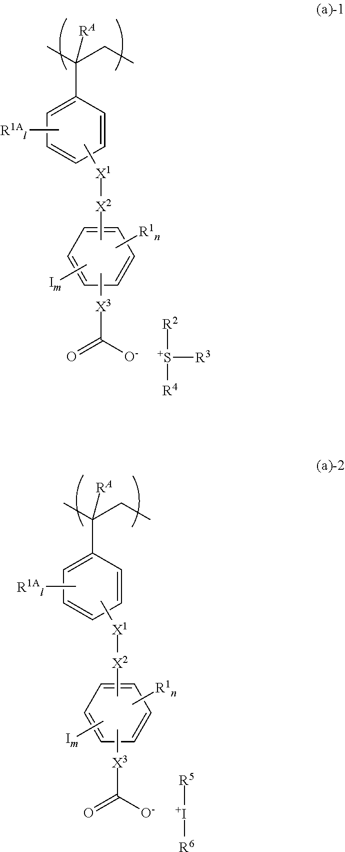
wherein R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{1A} each independently represents a halogen atom, a hydroxy group, or a linear or branched alkoxy group or acyloxy group each having 1 to 6 carbon atoms;
“l” represents an integer of 0 to 3; “m” represents an integer of 0 to 4; “n” represents an integer of 0 to 4, provided that an anion moiety of the pendant group contains one or more iodine atoms; and R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto.

2. The positive resist material according to claim 1, wherein the base polymer further comprises at least one selected from repeating units represented by the following formulae (b1) to (b4), 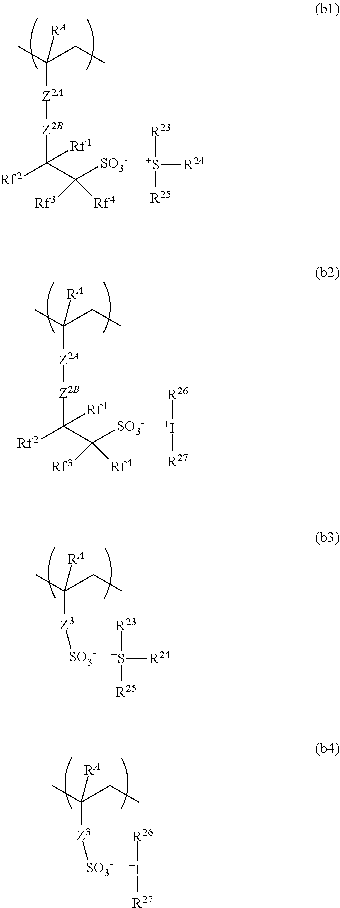
wherein R^{A} each independently represents a hydrogen atom or a methyl group; Z^{2A} represents a single bond or an ester bond; Z^{2B} represents a single bond or a divalent group having 1 to 12 carbon atoms, optionally containing an ester bond, an ether bond, a lactone ring, a bromine atom, or an iodine atom; Z³ represents a single bond, a methylene group, an ethylene group, a phenylene group, a fluorinated phenylene group, —O—Z³¹—, —C(═O)—O—Z³¹—, or —C(═O)—NH—Z³¹—, wherein Z³¹ represents an alkanediyl group having 1 to 6 carbon atoms, an alkenediyl group having 2 to 6 carbon atoms, or a phenylene group, optionally containing a carbonyl group, an ester bond, an ether bond, a halogen atom, or a hydroxy group; each of Rf¹ to Rf⁴ independently represents a hydrogen atom, a fluorine atom, or a trifluoromethyl group, provided that at least one of Rf¹ to Rf⁴ represents a fluorine atom; and each of R²³ to R²⁷ independently represents a monovalent hydrocarbon group having 1 to 20 carbon atoms and optionally having a heteroatom, and optionally any two of R²³, R²⁴, and R²⁵ bond together to form a ring with a sulfur atom attached thereto.

3. The positive resist material according to claim 2, wherein the Z^{2B} comprises one or more iodine atoms.

4. The positive resist material according to claim 1, further comprising a repeating unit (c) in which a hydrogen atom of one or both of a carboxy group and a phenolic hydroxy group is substituted with an acid labile group.

5. The positive resist material according to claim 4, wherein the repeating unit (c) is at least one selected from a repeating unit (c1) represented by the following formula (c1) and a repeating unit (c2) represented by the following formula (c2), 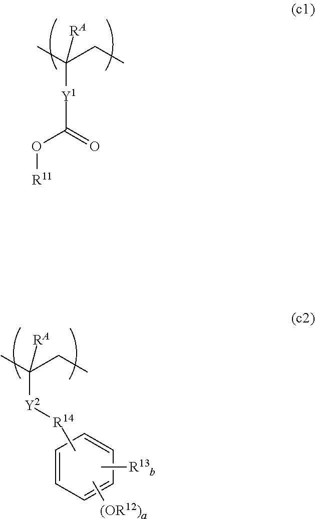
wherein R^{A} each independently represents a hydrogen atom or a methyl group; Y¹ represents a single bond, a phenylene group, a naphthylene group, or a linking group having 1 to 12 carbon atoms and having an ester bond, an ether bond, or a lactone ring; Y² represents a single bond, an ester bond, or an amide bond; R¹¹ and R¹² represent an acid labile group; R¹³ represents a fluorine atom, a trifluoromethyl group, a cyano group, or an alkyl group having 1 to 6 carbon atoms; R¹⁴ represents a single bond, or a linear or branched alkanediyl group having 1 to 6 carbon atoms, in which some of carbon atoms thereof are optionally substituted with an ether bond or an ester bond; “a” represents 1 or 2; and “b” represents an integer of 0 to 4.

6. The positive resist material according to claim 5, wherein the base polymer further comprises a repeating unit (d) comprising an adhesive group selected from a hydroxy group, a carboxy group, a lactone ring, a carbonate group, a thiocarbonate group, a carbonyl group, a cyclic acetal group, an ether bond, an ester bond, a sulfonic acid ester bond, a cyano group, an amide group, —O—C(═O)—S—, and —O—C(═O)—NH—.

7. The positive resist material according to claim 1, wherein the base polymer has a weight average molecular weight in a range of 1000 to 100000.

8. A positive resist composition comprising the positive resist material according to claim 1.

9. The positive resist composition according to claim 8, further comprising one or more selected from an acid generator, an organic solvent, a quencher, and a surfactant.

10. A patterning process comprising steps of: forming a resist film on a substrate using the positive resist composition according to claim 8; exposing the resist film to a high-energy beam; and developing the exposed resist film using a developer.

11. A patterning process comprising steps of: forming a resist film on a substrate using the positive resist composition according to claim 9; exposing the resist film to a high-energy beam; and developing the exposed resist film using a developer.

12. The patterning process according to claim 10, wherein the high-energy beam is a beam at i-line, a KrF excimer laser beam, an ArF excimer laser beam, an electron beam, or extreme ultraviolet having a wavelength of 3 to 15 nm.

13. A polymer compound having a weight average molecular weight in a range of 1000 to 100000, comprising a copolymer containing one or both of a repeating unit represented by the following general formula (a)-1 and a repeating unit represented by the following general formula (a)-2, and one or more repeating units selected from the following general formulae (b1) to (b4), 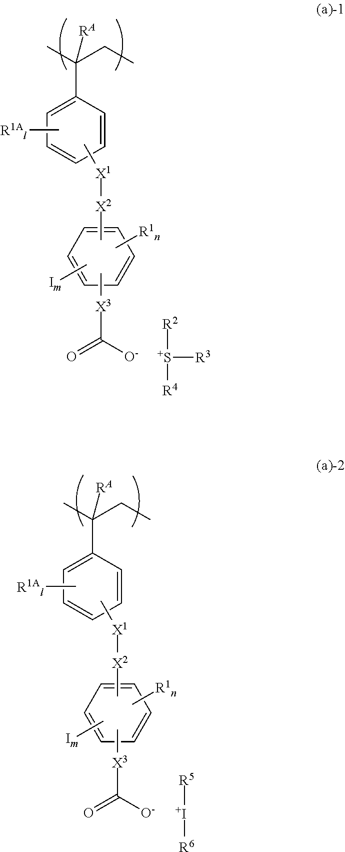 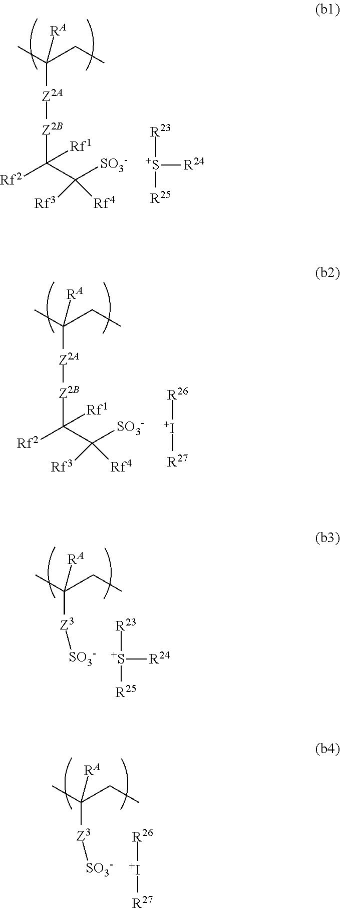
wherein R^{A} represents a hydrogen atom or a methyl group; X¹ represents a single bond, an ester group, an ether group, or a sulfonic acid ester group; X² represents a single bond, or a linear, branched, or cyclic alkyl group having 1 to 12 carbon atoms and optionally containing one or more selected from an ester group, an ether group, an amide group, a lactone ring, a sultone ring, and a halogen atom; X³ represents a linear or branched alkylene group having 1 to 10 carbon atoms and having 1 to 4 fluorine atoms, optionally containing one or more selected from an ether group, an ester group, an aromatic group, a double bond, and a triple bond; R¹ each independently represents a hydroxy group, a linear or branched alkyl group, alkoxy group, or acyloxy group each having 1 to 4 carbon atoms, or a halogen atom other than iodine; R^{1A} each independently represents a halogen atom, a hydroxy group, or a linear or branched alkoxy group or acyloxy group each having 1 to 6 carbon atoms; “l” represents an integer of 0 to 3; “m” represents an integer of 0 to 4; “n” represents an integer of 0 to 4, provided that an anion moiety of the pendant group contains one or more iodine atoms; R² to R⁶ each independently represents a monovalent hydrocarbon group having 1 to 25 carbon atoms and optionally having a heteroatom, and optionally any two of R², R³, and R⁴ bond together to form a ring with a sulfur atom attached thereto; Z^{2A} represents a single bond or an ester bond;
Z^{2B} represents a single bond or a divalent group having 1 to 12 carbon atoms, optionally containing an ester bond, an ether bond, a lactone ring, a bromine atom, or an iodine atom; Z³ represents a single bond, a methylene group, an ethylene group, a phenylene group, a fluorinated phenylene group, —O—Z³¹—, —C(═O)—O—Z³¹—, or —C(═O)—NH—Z³¹—, wherein Z³1 represents an alkanediyl group having 1 to 6 carbon atoms, an alkenediyl group having 2 to 6 carbon atoms, or a phenylene group, optionally containing a carbonyl group, an ester bond, an ether bond, a halogen atom, or a hydroxy group; each of Rf¹ to Rf⁴ independently represents a hydrogen atom, a fluorine atom, or a trifluoromethyl group, provided that at least one of Rf¹ to Rf⁴ represents a fluorine atom; and each of R²³ to R²⁷ independently represents a monovalent hydrocarbon group having 1 to 20 carbon atoms and optionally having a heteroatom, and optionally any two of R²³, R²⁴, and R²⁵ bond together to form a ring with a sulfur atom attached thereto.
